(19) United States
(12) Patent Application Publication
(10) Pub. No.: US 2019/0196325 A1
(43) Pub. Date: Jun. 27, 2019

(54) PHOTOSENSITIVE COMPOSITION, CURED FILM, OPTICAL FILTER, LAMINATE, PATTERN FORMING METHOD, SOLID IMAGE PICKUP ELEMENT, IMAGE DISPLAY DEVICE, AND INFRARED SENSOR

(71) Applicant: FUJIFILM Corporation, Tokyo (JP)

(72) Inventors: Tetsushi Miyata, Haibara-gun (JP); Kazutaka Takahashi, Haibara-gun (JP); Takahiro Okawara, Haibara-gun (JP)

(73) Assignee: FUJIFILM Corporation, Tokyo (JP)

(21) Appl. No.: 16/286,251

(22) Filed: Feb. 26, 2019

Related U.S. Application Data
(63) Continuation of application No. PCT/JP2017/030001, filed on Aug. 23, 2017.

(30) Foreign Application Priority Data
Aug. 30, 2016 (JP) 2016-167945

(51) Int. Cl. G03F 7/00; G03F 7/004; G03F 7/031; G03F 7/16; G03F 7/20; G03F 7/32; G03F 7/40; G02B 5/20

(52) U.S. Cl. CPC G03F 7/0007; G03F 7/0045; G03F 7/031; G03F 7/162; G02B 5/208; G03F 7/2039; G03F 7/322; G03F 7/40; G03F 7/168

(57) ABSTRACT

A photosensitive composition with which a cured film that includes a pattern having excellent rectangularity and suppressed thermal shrinkage can be formed is provided. A cured film formed of the photosensitive composition, an optical filter, a laminate, a pattern forming method, a solid image pickup element, an image display device, and an infrared sensor are provided. The photosensitive composition includes a near infrared absorber, a curable compound, a photoinitiator, and an ultraviolet absorber, in which in thermogravimetry, the ultraviolet absorber has a mass loss percentage of 5% or lower at 150° C. and has a mass loss percentage of 40% or higher at 220° C.

### CROSS-REFERENCE TO RELATED APPLICATIONS

This application is a Continuation of PCT International Application No. PCT/JP2017/030001 filed on Aug. 23, 2017, which claims priority under 35 U.S.C § 119(a) to Japanese Patent Application No. 2016-167945 filed on Aug. 30, 2016. Each of the above application(s) is hereby expressly incorporated by reference, in its entirety, into the present application.

### BACKGROUND OF THE INVENTION

### 1. Field of the Invention

The present invention relates to a photosensitive composition, a cured film, an optical filter, a laminate, a pattern forming method, a solid image pickup element, an image display device, and an infrared sensor.

### 2. Description of the Related Art

In a video camera, a digital still camera, a mobile phone with a camera function, or the like, a charge coupled device (CCD) or a complementary metal-oxide semiconductor (CMOS), which is a solid image pickup element for a color image, is used. In a light receiving section of this solid image pickup element, a silicon photodiode having sensitivity to infrared light is used. Therefore, visibility may be corrected using a near infrared cut filter.

On the other hand, JP2014-194508A describes that a pixel of a color filter is formed using a photosensitive resin composition including an ultraviolet absorber having a predetermined structure, a photopolymerization initiator, and a polymerizable monomer. JP2014-194508A describes that development residue during the formation of the pixel can be suppressed by using the photosensitive composition. In addition, paragraph “0009” describes that, by adding the predetermined ultraviolet absorber in a case where the photosensitive resin composition is exposed to light having a wavelength of 365 nm to form a pattern, ultraviolet light is likely to be absorbed, resolution can be improved, and development residue can be reduced.

### SUMMARY OF THE INVENTION

In the related art, a near infrared cut filter has been used as a flat film. Recently, it has also been considered to form a pattern on a near infrared cut filter. For example, the use of a laminate in which each pixel (for example, a red pixel, a blue pixel, or a green pixel) of a color filter is formed on a pattern of a near infrared cut filter has been considered. In a case where this laminate is manufactured, it is desirable that the pattern of the near infrared cut filter has excellent rectangularity. In a case where the rectangularity of the pattern of the near infrared cut filter is excellent, when the laminate is formed by forming each pixel of a color filter on the pattern of the near infrared cut filter, formation of voids, mixing of colors, or the like can be suppressed.

However, according to an investigation by the present inventors, it was found that, in a case where a pattern is formed with a photolithography method using a photosensitive composition including an near infrared absorber, a curable compound, and a photoinitiator, the rectangularity of the obtained pattern is likely to deteriorate.

As a result of the investigation on the photosensitive composition, it was found that, by using a near infrared absorber and an ultraviolet absorber in combination, a pattern having excellent rectangularity tends to be obtained using a photolithography method. However, as a result of further investigation by the present inventors, it was found that a cured film (pixel) having a pattern that is formed using a near infrared absorber and an ultraviolet absorber in combination tends to shrink in case of being exposed to a high temperature.

JP2014-194508A neither describes nor implies formation of a pattern using a photosensitive composition including a near infrared absorber.

Accordingly, an object of the present invention is to provide a photosensitive composition with which a cured film that includes a pattern having excellent rectangularity and having suppressed thermal shrinkage can be formed. In addition, another object of the present invention is to provide a cured film formed of the photosensitive composition, an optical filter, a laminate, a pattern forming method, a solid image pickup element, an image display device, and an infrared sensor.

According to the investigation, the present inventors found that the objects can be achieved using a photosensitive composition described below, thereby completing the present invention. The present invention provides the following.

<1> A photosensitive composition comprising:

a near infrared absorber;

a curable compound;

a photoinitiator; and

an ultraviolet absorber,

in which in thermogravimetry, the ultraviolet absorber has a mass loss percentage of 5% or lower at 150° C. and has a mass loss percentage of 40% or higher at 220° C.

<2> The photosensitive composition according to <1>,

in which a ratio A365/A400 of an absorbance A365 of the ultraviolet absorber at a wavelength of 365 nm to an absorbance A400 of the ultraviolet absorber at a wavelength of 400 nm is 0.5 or lower.

<3> The photosensitive composition according to <1>,

in which a ratio A365/A400 of an absorbance A365 of the ultraviolet absorber at a wavelength of 365 nm to an absorbance A400 of the ultraviolet absorber at a wavelength of 400 nm is 0.1 or lower.

<4> The photosensitive composition according to any one of <1> to <3>,

in which the ultraviolet absorber is a compound having an absorption maximum in a wavelength range of 300 to 400 nm.

<5> The photosensitive composition according to any one of <1> to <4>,

in which a molar absorption coefficient of the ultraviolet absorber at a wavelength of 365 nm is 4.0×10⁴ to 1.0×10⁵ L·mol⁻¹·cm⁻¹.

<6> The photosensitive composition according to any one of <1> to <5>,

in which the ultraviolet absorber is at least one selected from the group consisting of an aminobutadiene compound and a methyldibenzoyl compound.

<7> The photosensitive composition according to any one of <1> to <6>,

in which the ultraviolet absorber is a compound represented by the following Formula (UV-1);

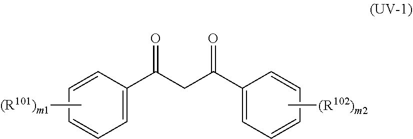

in Formula (UV-1), R¹⁰¹ and R¹⁰² each independently represent a substituent, and m1 and m2 each independently represent 0 to 4.

<8> The photosensitive composition according to any one of <1> to <7>,

in which the curable compound is a radically polymerizable compound, and the photoinitiator is a photoradical polymerization initiator.

<9> The photosensitive composition according to any one of <1> to <8>, further comprising:

an alkali-soluble resin.

<10> A cured film which is formed using the photosensitive composition according to any one of <1> to <9>.

<11> An optical filter which is obtained using the photosensitive composition according to any one of <1> to <9>.

<12> The optical filter according to <11>,

in which the optical filter is a near infrared cut filter or an infrared transmitting filter.

<13> A laminate comprising:

the cured film according to <10>; and

a color filter that includes a chromatic colorant.

<14> A pattern forming method comprising:

a step of forming a composition layer on a support using the photosensitive composition according to any one of <1> to <9>; and

a step of forming a pattern on the composition layer using a photolithography method.

<15> The pattern forming method according to <14> further comprising:

a step of forming a photosensitive coloring composition layer on the pattern using a photosensitive coloring composition including a chromatic colorant; and

a step of forming a pattern by exposing the photosensitive coloring composition layer from the photosensitive coloring composition layer side and subsequently developing the exposed photosensitive coloring composition layer.

<16> A solid image pickup element comprising:

the cured film according to <10>.

<17> An image display device comprising:

the cured film according to <10>.

<18> An infrared sensor comprising:

the cured film according to <10>.

According to the present invention, it is possible to provide a photosensitive composition with which a cured film that includes a pattern having excellent rectangularity and suppressed thermal shrinkage can be formed. In addition, it is also possible to provide a cured film formed of the photosensitive composition, an optical filter, a laminate, a pattern forming method, a solid image pickup element, an image display device, and an infrared sensor.

### BRIEF DESCRIPTION OF THE DRAWINGS

FIG. 1 is a schematic diagram showing an embodiment of an infrared sensor.

FIG. 2 is a schematic diagram showing another embodiment of the infrared sensor.

### DESCRIPTION OF THE PREFERRED EMBODIMENTS

Hereinafter, the details of the present invention will be described.

In this specification, numerical ranges represented by “to” include numerical values before and after “to” as lower limit values and upper limit values.

In this specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In this specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by excimer laser, an extreme ultraviolet ray (EUV ray), an X-ray, or an electron beam.

In this specification, “(meth)allyl group” denotes either or both of allyl and methallyl, “(meth)acrylate” denotes either or both of acrylate or methacrylate, “(meth)acryl” denotes either or both of acryl and methacryl, and “(meth)acryloyl” denotes either or both of acryloyl and methacryloyl.

In this specification, a weight-average molecular weight and a number-average molecular weight are defined as values in terms of polystyrene obtained by gel permeation chromatography (GPC). In this specification, an weight-average molecular weight (Mw) and a number-average molecular weight (Mn) can be obtained by using HLC-8220 (manufactured by Tosoh Corporation), using TSKgel Super AWM-H (manufactured by Tosoh Corporation; 6.0 mm ID (inner diameter)×15.0 cm) as a column, and using a 10 mmol/L lithium bromide N-methylpyrrolidinone (NMP) solution as an eluent.

In this specification, “near infrared light” denotes light (electromagnetic wave) in a wavelength range of 700 to 2500 nm.

In this specification, a total solid content denotes the total mass of all the components of the composition excluding a solvent.

In this specification, the term “step” denotes not only an individual step but also a step which is not clearly distinguishable from another step as long as an effect expected from the step can be achieved.

<Photosensitive Composition>

A photosensitive composition according to an embodiment of the present invention (hereinafter, also referred to as “composition according to the embodiment of the present invention”) includes a near infrared absorber, a curable compound, a photoinitiator, and an ultraviolet absorber, in which, in thermogravimetry, the ultraviolet absorber has a mass loss percentage of 5% or lower at 150° C. and has a mass loss percentage of 50% or higher at 200° C.

With the composition according to the embodiment of the present invention, a cured film that includes a pattern having excellent rectangularity and having suppressed thermal shrinkage can be formed using a photolithography method. The reason why this effect is obtained is presumed to be as follows.

A near infrared absorber has high transparency with respect to light such as an i-ray used for exposure. Therefore, in a case where a composition including a near infrared absorber, a curable compound, and a photoinitiator is exposed through a mask, a non-exposed portion of a mask edge is likely to be exposed to reflected light or scattered light from a support or the like, and the rectangularity of the pattern tends to easily deteriorate. However, by further adding an ultraviolet absorber to the composition, the reflected light, the scattered light, or the like in the non-exposed portion of the mask edge can be absorbed. As a result, a pattern having excellent rectangularity can be formed.

In addition, in general, an ultraviolet absorber is desired to be a material having high heat stability. However, according to an investigation by the present inventors, it was found that a cured film that is formed by further adding an ultraviolet absorber having a high heat stability to a composition including a near infrared absorber, a curable compound, and a photoinitiator tends to be easily thermally shrink in case of being exposed to a high temperature. It is presumed that the thermal shrinkage of the cured film occurs because the ultraviolet absorber included in the cured film is removed when the cured film is heated at a high temperature. As a result of various investigations on the ultraviolet absorber used for the composition, it was found that, by using the ultraviolet absorber having the above-described properties, a cured film that includes a pattern having excellent rectangularity and having suppressed thermal shrinkage can be formed. It is presumed that, by using the ultraviolet absorber having the above-described properties, the ultraviolet absorber can be made to be present in the film during development and can be sufficiently removed from the film by a heating treatment or the like after development.

Here, in steps of manufacturing various devices including a near infrared cut filter or the like, various treatments such as dicing or packaging may be performed after formation of a cured film such as a near infrared cut filter. In many cases, the treatments after the formation of the cured film are performed at a higher temperature than that during the formation of the cured film. Therefore, in the steps of manufacturing various devices including a near infrared cut filter or the like, the cured film such as a near infrared cut filter is exposed to a high temperature after the formation. At this time, in a case where the cured film shrinks, voids or the like are formed such that product properties may deteriorate. Therefore, it is desired to reduce the thermal shrinkage of the cured film from the viewpoint of improving the product properties of the cured film.

In addition, in a case where the cured film (cured film including a pattern) is formed using the composition according to the embodiment of the present invention and a coloring cured film such as a color filter is further formed on the cured film using a photosensitive coloring composition including a chromatic colorant, the sensitivity of the photosensitive coloring composition can be improved. In the cured film that is formed using the composition according to the embodiment of the present invention, the residual amount of the ultraviolet absorber is small. Therefore, reflected light or scattered light from a support or the cured film can also be used for exposure during the formation of the coloring cured film, and the sensitivity during the formation of the coloring cured film can be improved.

In addition, the ultraviolet absorber can be sufficiently removed from the cured film. Therefore, brown derived from the ultraviolet absorber can be suppressed, and the visible transparency of the cured film can be further improved.

Hereinafter, each component of the composition according to the embodiment of the present invention will be described.

<<Near Infrared Absorber>>

The composition according to the embodiment of the present invention includes a near infrared absorber. In the present invention, the near infrared absorber refers to a material having an absorption in a near infrared range (preferably in a wavelength range of 700 to 1300 nm and more preferably in a wavelength range of 700 to 1000 nm).

The near infrared absorber may be a pigment or a dye. It is preferable that the other near infrared absorbing compound is a pigment because a pattern having excellent rectangularity can be easily formed. In addition, the pigment may be an organic pigment or an inorganic pigment. From the viewpoint of spectral characteristics, it is preferable that the pigment is an organic pigment. Examples of the near infrared absorber include a pyrrolopyrrole compound, a cyanine compound, a squarylium compound, a phthalocyanine compound, a naphthalocyanine compound, a rylene compound, a merocyanine compound, a croconium compound, an oxonol compound, a diimmonium compound, a dithiol compound, a triarylmethane compound, a pyrromethene compound, an azomethine compound, an anthraquinone compound, a dibenzofuranone compound, and a copper compound. Examples of the diimmonium compound include a compound described in JP2008-528706A, the content of which is incorporated herein by reference. Examples of the phthalocyanine compound include a compound described in paragraph “0093” of JP2012-077153A, oxytitaniumphthalocyanine described in JP2006-343631A, and a compound described in paragraphs “0013” to “0029” of JP2013-195480A, the contents of which are incorporated herein by reference. Examples of the naphthalocyanine compound include a compound described in paragraph “0093” of JP2012-077153A, the content of which is incorporated herein by reference. In addition, as the cyanine compound, the phthalocyanine compound, the naphthalocyanine compound, the diimmonium compound, or the squarylium compound, for example, one of the a compound described in paragraphs “0010” to “0081” of JP2010-111750A may be used, the content of which are incorporated in this specification. In addition, the details of the cyanine compound can be found in, for example, “Functional Colorants by Makoto Okawara, Masaru Matsuoka, Teijiro Kitao, and Tsuneoka Hirashima, published by Kodansha Scientific Ltd.”, the content of which is incorporated herein by reference. Examples of the copper compound include copper complexes described in paragraphs “0009” to “0049” of WO2016/068037A, copper phosphate complexes described in paragraphs “0022” to “0042” of JP2014-041318A, and copper sulfate complexes described in paragraphs “0021” to “0039” of JP2015-043063A, the contents of which are incorporated herein by reference.

As the pyrrolopyrrole compound, a compound represented by the following Formula (PP) is preferable. According to this aspect, a cured film having excellent heat resistance and light fastness can be easily obtained.

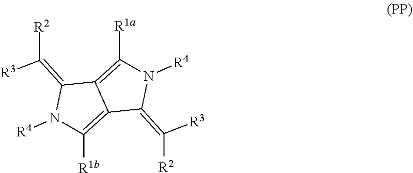

In the formula, R^{1a} and R^{1b} each independently represent an alkyl group, an aryl group, or a heteroaryl group, R² and R³ each independently represent a hydrogen atom or a substituent, R² and R³ may be bonded to each other to form a ring, R⁴'s each independently represent a hydrogen atom, an alkyl group, an aryl group, a heteroaryl group, —BR^{4A}R^{4B}, or a metal atom, R⁴ may form a covalent bond or a coordinate bond with at least one selected from the group consisting of R^{1a}, R^{1b}, and R³, and R^{4A} and R^{4B} each independently represent a substituent. The details of Formula (PP) can be found in paragraphs “0017” to “0047” of JP2009-263614A, paragraphs “0011” to “0036” of JP2011-068731A, and paragraphs “0010” to “0024” of WO2015/166873A, the contents of which are incorporated herein by reference.

R^{1a} and R^{1b} each independently represent preferably an aryl group or a heteroaryl group, and more preferably an aryl group. In addition, the alkyl group, the aryl group, and the heteroaryl group represented by R^{1a} and R^{1b} may have a substituent or may be unsubstituted. Examples of the substituent include substituents described in paragraphs “0020” to “0022” of 2009-263614A. Among these, an alkoxy group or a hydroxy group is preferable. The alkoxy group is preferably an alkoxy group having a branched alkyl group. The group represented by R^{1a} and R^{1b} is preferably an aryl group which has an alkoxy group having a branched alkyl group as a substituent, or an aryl group which has a hydroxy group as a substituent. The number of carbon atoms in the branched alkyl group is preferably 3 to 30 and more preferably 3 to 20.

It is preferable that at least one of R² or R³ represents an electron-withdrawing group, and it is more preferable that R² represents an electron-withdrawing group (preferably a cyano group) and R³ represents a heteroaryl group. It is preferable that the heteroaryl group is a 5-membered or 6-membered ring. In addition, the heteroaryl group is preferably a monocycle or a fused ring, more preferably a monocycle or a fused ring composed of 2 to 8 rings, and still more preferably a monocycle or a fused ring composed of 2 to 4 rings. The number of heteroatoms constituting the heteroaryl group is preferably 1 to 3 and more preferably 1 or 2. Examples of the heteroatom include a nitrogen atom, an oxygen atom, and a sulfur atom. It is preferable that the heteroaryl group has one or more nitrogen atoms.

It is preferable that R⁴ represents a hydrogen atom or a group represented by —BR^{4A}R^{4B}. As the substituent represented by R^{4A} and R^{4B}, a halogen atom, an alkyl group, an alkoxy group, an aryl group, or a heteroaryl group is preferable, an alkyl group, an aryl group, or a heteroaryl group is more preferable, and an aryl group is still more preferable. Specific examples of the group represented by —BR^{4A}R^{4B} include a difluoroboron group, a diphenylboron group, a dibutylboron group, a dinaphthylboron group, and a catecholboron group. In particular, a diphenylboron group is preferable.

Specific examples of the compound represented by Formula (PP) include the following compounds. In the following structural formulae, Me represents a methyl group, and Ph represents a phenyl group. In addition, Examples of the pyrrolopyrrole compound include compounds described in paragraphs “0016” to “0058” of JP2009-263614A, compounds described in paragraphs “0037” to “0052” of JP2011-068731A, compounds described in paragraphs “0010” to “0033” of WO2015/166873A, the contents of which are incorporated herein by reference.

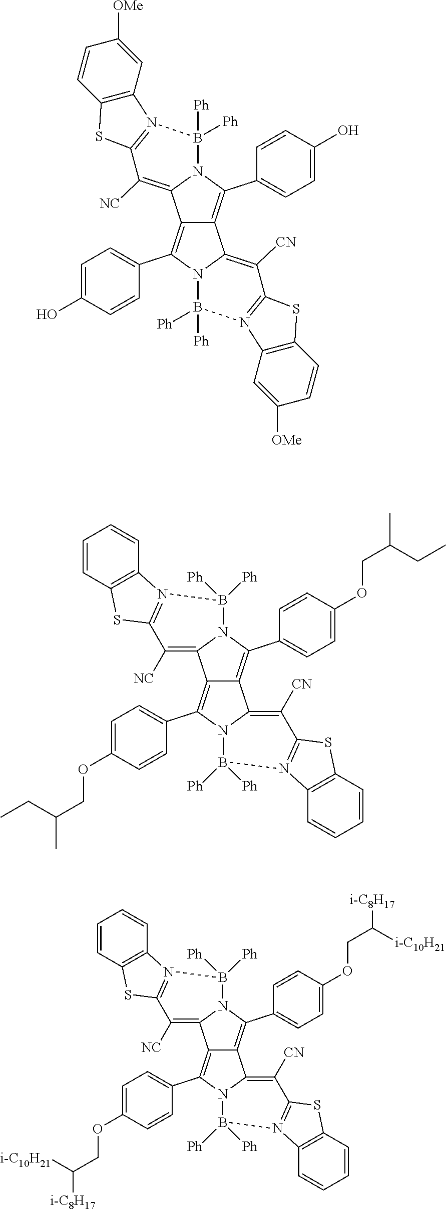

As the squarylium compound, a compound represented by the following Formula (SQ) is preferable.

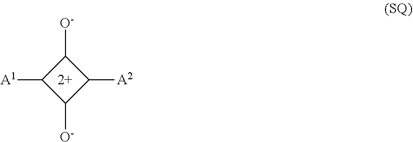

In Formula (SQ), A¹ and A² each independently represent an aryl group, a heteroaryl group, or a group represented by the following Formula (A-1).

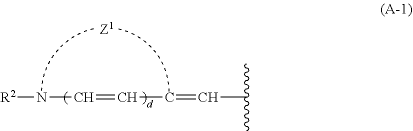

In Formula (A-1), Z¹ represents a non-metal atomic group for forming a nitrogen-containing heterocycle, R² represents an alkyl group, an alkenyl group, or an aralkyl group, d represents 0 or 1, and a wave line represents a direct bond.

The details of Formula (SQ) can be found in paragraphs “0020” to “0049” of JP2011-208101A, the content of which is incorporated herein by reference.

As shown below, cations in Formula (SQ) are present without being localized.

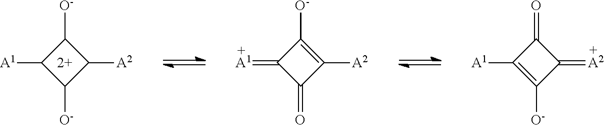

It is preferable that the squarylium compound is a compound represented by the following Formula (SQ-1). This compound has excellent heat resistance. Formula (SQ-1)

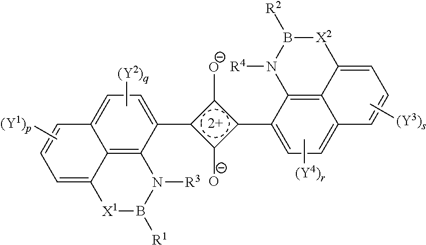

In the formula, R¹ and R² each independently represent a substituent.

R³ and R⁴ each independently represent a hydrogen atom or an alkyl group.

X¹ and X² each independently —O— or —N(R⁵)—.

R⁵ represents a hydrogen atom, an alkyl group, an aryl group, or a heteroaryl group.

Y¹ to Y⁴ each independently represent a substituent, and Y¹ and Y², or Y³ and Y⁴ may be bonded to each other to form a ring.

In a case where a plurality of Y¹'s, a plurality of Y²'s, a plurality of Y³'s, and a plurality of Y⁴'s are present, Y¹'s, Y²'s, Y³'s, or Y⁴'s may be bonded to each other to form a ring.

p and s each independently represent an integer of 0 to 3.

q and r each independently represent an integer of 0 to 2.

The details of Formula (SQ-1) can be found in paragraphs “0020” to “0040” of JP2011-208101A, the content of which is incorporated herein by reference. Specific examples of the squarylium compound include the following compounds. In the following structural formula, EH represents an ethylhexyl group. Examples of the squarylium compound include a compound described in paragraphs “0044” to “0049” of JP2011-208101A, the content of which is incorporated herein by reference.

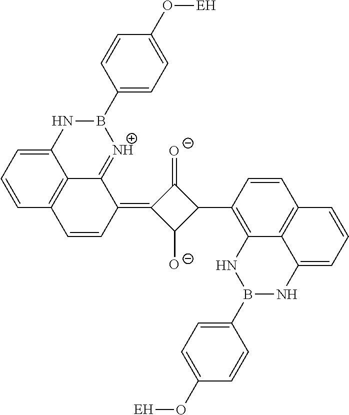

As the cyanine compound, a compound represented by Formula (C) is preferable. Formula (C)

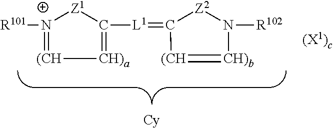

In the formula, Z¹ and Z² each independently represent a non-metal atomic group for forming a 5- or 6-membered nitrogen-containing heterocycle which may be fused.

R101 and R¹⁰² each independently represent an alkyl group, an alkenyl group, an alkynyl group, an aralkyl group, or an aryl group.

L¹ represents a methine chain including an odd number of methine groups.

a and b each independently represent 0 or 1.

In a case where a represents 0, a carbon atom and a nitrogen atom are bonded through a double bond. In a case where b represents 0, a carbon atom and a nitrogen atom are bonded through a single bond.

In a case where a site represented by Cy in the formula is a cation site, X¹ represents an anion, and c represents the number of X¹'s for balancing charge. In a case where a site represented by Cy in the formula is an anion site, X¹ represents a cation, and c represents the number of X¹'s for balancing charge. In a case where charge of a site represented by Cy in the formula is neutralized in a molecule, c represents 0.

Specific examples of the cyanine compound include the following compounds. In the following structural formulae, Me represents a methyl group. In addition, examples of the cyanine compound include a compound described in paragraphs “0044” and “0045” of JP2009-108267A, a compound described in paragraphs “0026” to “0030” of JP2002-194040, a compound described in JP2015-172004A, and a compound described in JP2015-172102A, the contents of which are incorporated herein by reference.

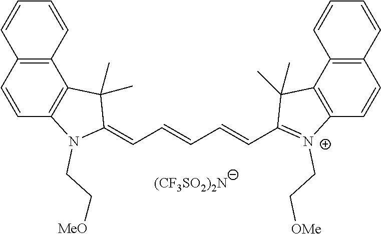

In the present invention, as the near infrared absorber, an inorganic pigment (inorganic particles) may also be used. As the inorganic pigment, metal oxide particles or metal particles are preferable from the viewpoint of further improving infrared shielding properties. Examples of the metal oxide particles include indium tin oxide (ITO) particles, antimony tin oxide (ATO) particles, zinc oxide (ZnO) particles, Al-doped zinc oxide (Al-doped ZnO) particles, fluorine-doped tin dioxide (F-doped SnO2) particles, and niobium-doped titanium dioxide (Nb-doped TiO₂) particles. Examples of the metal particles include silver (Ag) particles, gold (Au) particles, copper (Cu) particles, and nickel (Ni) particles. In addition, as the inorganic pigment, a tungsten oxide compound can also be used. As the tungsten oxide compound, cesium tungsten oxide is preferable. The details of the tungsten oxide compound can be found in paragraph “0080” of JP2016-006476A, the content of which is incorporated herein by reference. The shape of the inorganic pigment is not particularly limited and may have a sheet shape, a wire shape, or a tube shape irrespective of whether or not the shape is spherical or non-spherical.

In the present invention, as the near infrared absorber, a commercially available product can also be used. Examples of the commercially available product include IRA828, IRA842, IRA848, IRA850, IRA851, IRA866, IRA870, and IRA884 (manufactured by Exiton, Inc.); SDO-C33 (manufactured by Arimoto Chemical Co., Ltd.); EXCOLOR IR-14, EXCOLOR IR-10A, EXCOLOR TX-EX-801B, EXCOLOR TX-EX-805K, and EXCOLOR TX-EX-815K (manufactured by Nippon Shokubai Co., Ltd.); Shigenox NIA-8041, Shigenox NIA-8042, Shigenox NIA-814, Shigenox NIA-820, and Shigenox NIA-839 (manufactured by Hakkol Chemical Co., Ltd.); Epolite V-63, Epolight 3801, and Epolight3036 (manufactured by Epolin Inc.); PRO-JET 825LDI (manufactured by Fujifilm Corporation); NK-3027, NKX-113, NKX-1199, SMP-363, SMP-387, SMP-388, and SMP-389 (manufactured by Hayashibara Co., Ltd.); and YKR-3070 (manufactured by Mitsui Chemicals, Inc.).

In the composition according to the embodiment of the present invention, the content of the near infrared absorber is preferably 1 to 50 mass % with respect to the total solid content of the composition according to the embodiment of the present invention. The lower limit is preferably 5 mass % or higher and more preferably 10 mass % or higher. The upper limit is preferably 40 mass % or lower and more preferably 30 mass % or lower. In a case where the content of the near infrared absorber is in the above-described range, a cured film that includes a pattern having excellent infrared shielding properties, having excellent rectangularity, and having suppressed thermal shrinkage can be formed. In the present invention, as the near infrared absorber one kind may be used alone, or two or more kinds may be used. In a case where two or near infrared absorbers are used in combination, it is preferable that the total content of the two or more near infrared absorbers is in the above-described range.

<<Ultraviolet Absorber>>

The composition according to the embodiment of the present invention includes an ultraviolet absorber. In the present invention, the ultraviolet absorber refers to a material having an absorption in an ultraviolet range (preferably in a wavelength range of 200 to 500 nm and more preferably in a wavelength range of 250 to 450 nm).

In thermogravimetry, the ultraviolet absorber according to the embodiment of the present invention has a mass loss percentage of 5% or lower at 150° C. and has a mass loss percentage of 40% or higher at 220° C. This ultraviolet absorber has a mass loss percentage of 5% or lower at 150° C. Therefore, in a case where a pattern is formed with a photolithography method using the composition according to the embodiment of the present invention, the loss of the ultraviolet absorber during the drying or the like of a composition layer applied to a support can be suppressed. Therefore, the ultraviolet absorber can be made to be stably present in the film until development. In addition, this ultraviolet absorber has a mass loss percentage of 40% or higher at 220° C. In a case where the developed film is heated, the ultraviolet absorber can be sufficiently removed from the cured film. A residual rate of the ultraviolet absorber in the cured film ((Amount of Ultraviolet Absorber in Cured Film/Amount of Ultraviolet Absorber in Composition)x100) is preferably 0.5% to 50%, more preferably 1% to 30%, and still more preferably 2% to 10%. In a case where the residual rate of the ultraviolet absorber in the cured film is in the above-described range, thermal shrinkage can be effectively reduced. Further, excellent light fastness can be obtained. By using the ultraviolet absorber having the above-described thermal decomposition properties, the residual rate of the ultraviolet absorber in the cured film can be made to be 0.5% or higher.

In the present invention, the mass loss percentage of the ultraviolet absorber at 150° C. is preferably 4% or lower, more preferably 3% or lower, and still more preferably 1% or lower. According to this aspect, the loss of the ultraviolet absorber caused by a treatment such as drying before exposure can be effectively suppressed. In addition, the mass loss percentage of the ultraviolet absorber at 220° C. is preferably 50% or higher, more preferably 70% or higher, and still more preferably 90% or higher. According to this aspect, the ultraviolet absorber can be effectively removed from the developed film.

In the present invention, the values of the mass loss percentage of the ultraviolet absorber at 150° C. and 220° C. are values measured using the following method. That is, nitrogen gas is caused to flow at a flow rate of 60 mL/min. In a nitrogen gas atmosphere, the ultraviolet absorber is heated from 25° C. to 100° C. at a temperature increase rate of 10° C./min. The ultraviolet absorber is held at 100° C. for 30 minute, is heated to 220° C. at a temperature increase rate of 10° C./min, and then is held at 220° C. for 30 minutes. In a case where the ultraviolet absorber is held at 100° C. for 30 minutes, the average value of the mass of the ultraviolet absorber in a period from the start of the holding to 24 to 29 minutes is set as a reference value of the mass of the ultraviolet absorber, the mass of the ultraviolet absorber at 150° C. and the mass of the ultraviolet absorber after heating at 220° C. for 30 minutes are measured, and the mass loss percentage is calculated based on the following expression.

Mass Loss Percentage (%) at 150° C.=100−(Mass of Ultraviolet Absorber at 150° C./Reference Value of Mass of Ultraviolet Absorber)×100

Mass Loss Percentage (%) at 220° C.=100−(Mass of Ultraviolet Absorber after heating for 30 Minutes at 220° C./Reference Value of Mass of Ultraviolet Absorber)×100

In the present invention, a ratio A365/A400 of an absorbance A365 of the ultraviolet absorber at a wavelength of 365 nm to an absorbance A400 of the ultraviolet absorber at a wavelength of 400 nm is preferably 0.5 or lower and more preferably 0.1 or lower. In a case where A365/A400 is 0.5 or lower, a cured film having high transparency with respect to visible light in the vicinity of an ultraviolet range can be formed. The cured film has excellent visible transparency and can be preferably used as a near infrared cut filter.

In the present invention, the ultraviolet absorber is preferably a compound having an absorption maximum in a wavelength range of 300 to 400 nm and more preferably a compound having an absorption maximum in a wavelength range of 325 to 475 nm. By using the compound, a pattern having excellent rectangularity can be easily formed.

In the present invention, a molar absorption coefficient of the ultraviolet absorber at a wavelength of 365 nm is preferably 4.0×10⁴ L·mol⁻¹·cm⁻¹ or higher, more preferably 4.5 L·mol⁻¹cm⁻¹ or higher, and still more preferably 5.0 L·mol⁻¹·cm⁻¹ or higher. For example, the upper limit is preferably 1.0×10⁵ L·mol⁻·cm⁻¹ or lower. By using the compound, a pattern having excellent rectangularity can be easily formed.

In the present invention, the kind of the ultraviolet absorber is not particularly limited as long as it has the above-described properties. For example, an aminobutadiene compound, a methyldibenzoyl compound, a coumarin compound, a salicylate compound, a benzophenone compound, a benzotriazole compound, an acrylonitrile compound, or a hydroxyphenyltriazine compound can be used. Among these, from the viewpoint of obtaining high visible transparency after film formation, an aminobutadiene compound or a methyldibenzoyl compound is preferable, and a methyldibenzoyl compound is more preferable.

In the present invention, as the ultraviolet absorber, a compound represented by any one of Formulae (UV-1) to (UV-3) is preferable, a compound represented by any one of Formula (UV-1) or (UV-3) is more preferable, and a compound represented by Formula (UV-1) is still more preferable.

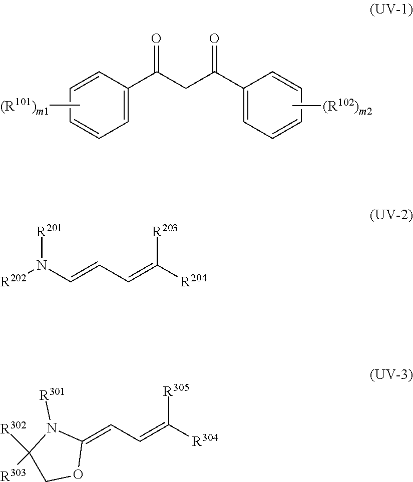

In Formula (UV-1), R¹⁰¹ and R¹⁰² each independently represent a substituent, and m1 and m2 each independently represent 0 to 4.

In Formula (UV-2), R²⁰¹ and R²⁰² each independently represent a hydrogen atom or an alkyl group, and R²⁰³ and R²⁰⁴ each independently represent a substituent.

In Formula (UV-3), R³⁰¹ to R³⁰³ each independently represent a hydrogen atom or an alkyl group, and R³⁰⁴ and R³⁰⁵ each independently represent a substituent.

Examples of the substituent represented by R¹⁰¹ and R¹⁰² include a halogen atom, a cyano group, a nitro group, an alkyl group, an aryl group, a heteroaryl group, an alkoxy group, an aryloxy group, a heteroaryloxy group, an alkylthio group, an arylthio group, a heteroarylthio group, —NR^{U1}R^{U2}, —COR^{U3}, —COOR^{U4}, —OCOR^{U5}, —NHCOR^{U6}, —CONR^{U7}R^{U8}, —NHCONR^{U9}R^{U10}, —NHCOOR^{U11}, —SO₂R^{U12}, —SO₂OR^{U13}, —NHSO₂R^{U14}, and —SO₂NR^{U15}R^{U16}, R^{U1} to R^{U16} each independently represent a hydrogen atom, an alkyl group having 1 to 8 carbon atoms, or an aryl group.

It is preferable that the substituents represented by R¹⁰¹ and R¹⁰² are each independently an alkyl group or an alkoxy group.

The number of carbon atoms in the alkyl group is preferably 1 to 20 and more preferably 1 to 10. The alkyl group is, for example, linear, branched, or cyclic, and is preferably linear or branched and more preferably branched.

The number of carbon atoms in the alkoxy group is preferably 1 to 20 and more preferably 1 to 10. The alkoxy group is preferably linear or branched and more preferably branched.

In Formula (UV-1), it is preferable that one of R¹⁰¹ and R¹⁰² represents an alkyl group and the other one of R¹⁰¹ and R¹⁰² represent an alkoxy group.

m1 and m2 each independently represent 0 to 4. m1 and m2 each independently represent preferably an integer of 0 to 2, more preferably 0 or 1, and still more preferably 1.

Examples of the compound represented by Formula (UV-1) include the following compound.

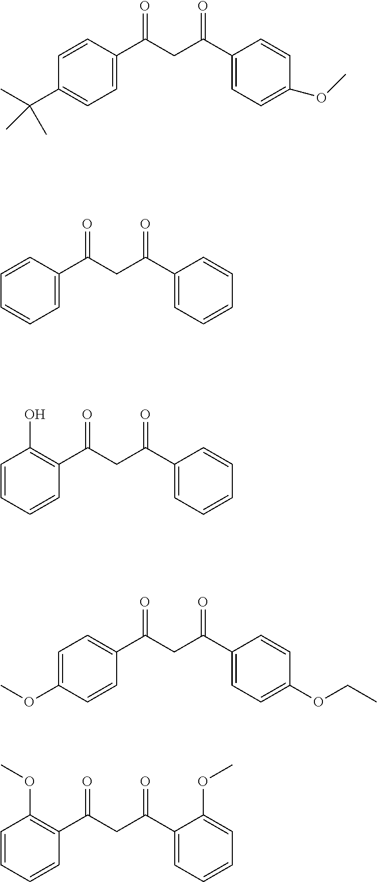

In Formula (UV-2), it is preferable that R²⁰¹ and R²⁰² each independently represent an alkyl group. The number of carbon atoms in the alkyl group is preferably 1 to 20 and more preferably 1 to 10. The alkyl group is, for example, linear, branched, or cyclic, and is preferably linear or branched and more preferably linear. The alkyl group represented by R²⁰¹ and R²⁰² may have a substituent. Examples of the substituent include the substituents described above regarding R¹⁰¹ and R¹⁰².

Examples of the substituent represented by R²⁰³ and R²⁰⁴ in Formula (UV-2) include the substituents described above regarding R¹⁰¹ and R¹⁰². It is preferable that at least one of R²⁰³ or R²⁰⁴ represents an electron-withdrawing group, and it is more preferable one of R²⁰³ and R²⁰⁴ represents an electron-withdrawing group and the other one of R²⁰³ and R²⁰⁴ represents a cyano group, —COR^{U3}, —COOR^{U4}, —CONR^{U7}R^{U8}, or —SO₂R^{U12}. In addition, it is still more preferable one of R²⁰³ and R²⁰⁴ represents —COOR^{U4} and the other one of R²⁰³ and R²⁰⁴ represents —COOR^{U4} or —SO₂R^{U12}. R^{U3}, R^{U4}, R^{U7}, R^{U8}, and R^{U12} each independently represent a hydrogen atom, an alkyl group having 1 to 8 carbon atoms, or an aryl group.

Here, the electron-withdrawing group is an electron-withdrawing group having a Hammett substituent constant σₚ value (hereinafter, simply referred to as “σₚ value”) of 0.20 to 1.0. The σₚ value in the electron-withdrawing group is preferably 0.30 to 0.8.

Examples of the compound represented by Formula (UV-2) include the following compound. In the following structural formulae, Et represents an ethyl group.

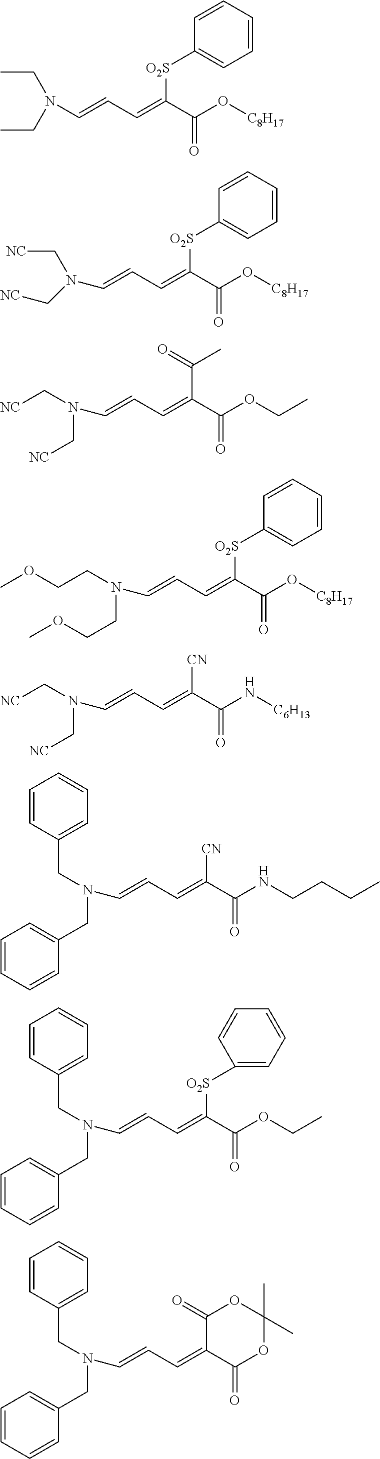

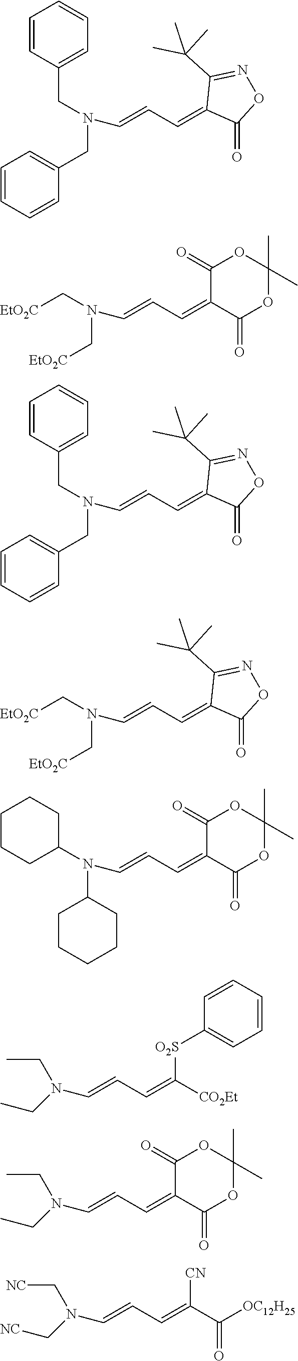

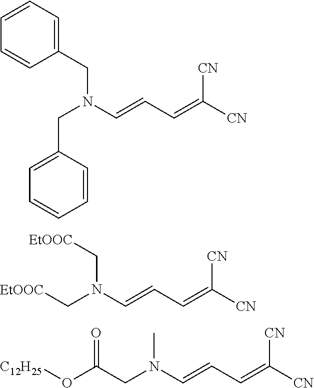

In Formula (UV-3), it is preferable that R³⁰¹ to R³⁰³ each independently represent an alkyl group. The number of carbon atoms in the alkyl group is preferably 1 to 20 and more preferably 1 to 10. The alkyl group is, for example, linear, branched, or cyclic, and is preferably linear or branched and more preferably linear. The alkyl group represented by R³⁰¹ to R³⁰³ may have a substituent. Examples of the substituent include the substituents described above regarding R¹⁰¹ and R¹⁰².

Examples of the substituent represented by R³⁰⁴ and R³⁰⁵ in Formula (UV-3) include the substituents described above regarding R¹⁰¹ and R¹⁰². It is preferable that at least one of R³⁰⁴ or R³⁰⁵ represents an electron-withdrawing group, and it is more preferable one of R³⁰⁴ and R³⁰⁵ represents an electron-withdrawing group and the other one of R³⁰⁴ and R³⁰⁵ represents a cyano group, —COR^{U3}, —COOR^{U4}, —CONR^{U7}R^{U8}, or —SO₂ R^{U12}. In addition, it is still more preferable one of R³⁰⁴ and R³⁰⁵ represents —COOR^{U4} and the other one of R³⁰⁴ and R³⁰⁵ represents —COOR^{U4} or —SO₂R^{U12}. R^{U3}, R^{U4}, R^{U7}, R^{U12} each independently represent a hydrogen atom, an alkyl group having 1 to 8 carbon atoms, or an aryl group.

Examples of the compound represented by Formula (UV-3) include the following compounds.

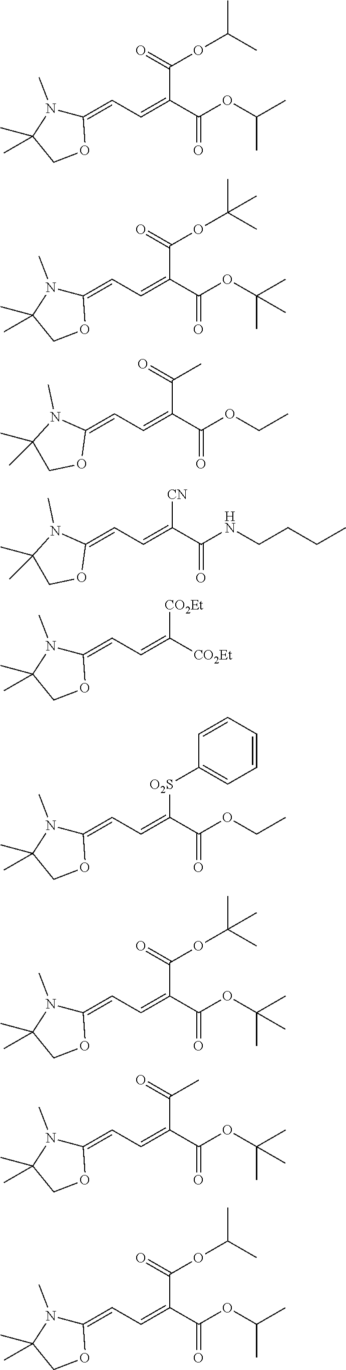

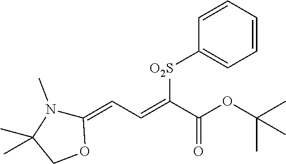 [SMILES: CN1/C(=C/C=C(/C(=O)OC(C)(C)C)S(=O)(=O)c2ccccc2)OCC1(C)C]

In the composition according to the embodiment of the present invention, the content of the ultraviolet absorber is preferably 2 to 9 mass % with respect to the total solid content of the composition according to the embodiment of the present invention. The lower limit is preferably 3 mass % or higher and more preferably 4 mass % or higher. The upper limit is more preferably 8 mass % or lower. In the present invention, as the ultraviolet absorber, one kind may be used alone, or two or more kinds may be used. In a case where two or ultraviolet absorbers are used in combination, it is preferable that the total content of the two or more ultraviolet absorbers is in the above-described range.

<<Curable Compound>>

The composition according to the embodiment of the present invention includes a curable compound. As the curable compound, a well-known compound which is crosslinkable by a radical, an acid, or heat can be used. Examples of the crosslinking compound include a compound which has a group having an ethylenically unsaturated bond and a compound having a cyclic ether group. Examples of the group having an ethylenically unsaturated bond include a vinyl group, a (meth)allyl group, and a (meth)acryloyl group. Examples of the cyclic ether group include an epoxy group and an oxetanyl group. In the present invention, as the curable compound, a radically polymerizable compound or a cationically polymerizable compound is preferable, and a radically polymerizable compound is more preferable.

The content of the curable compound is preferably 0.1 to 40 mass % with respect to the total solid content of the composition. For example, the lower limit is preferably 0.5 mass % or higher and more preferably 1 mass % or higher. For example, the upper limit is more preferably 30 mass % or lower and still more preferably 20 mass % or lower. As the curable compound, one kind may be used alone, or two or more kinds may be used in combination. In a case where two or more polymerizable compounds are used in combination, it is preferable that the total content of the two or more polymerizable compounds is in the above-described range.

(Radically Polymerizable Compound)

The radically polymerizable compound is not particularly limited as long as it is a compound that is polymerizable by the action of a radical. As the radically polymerizable compound, a compound having one or more groups having an ethylenically unsaturated bond is preferable, a compound having two or more groups having an ethylenically unsaturated bond is more preferable, and a compound having three or more groups having an ethylenically unsaturated bond is still more preferable. The upper limit of the number of the groups having an ethylenically unsaturated bond is, for example, preferably 15 or less and more preferably 6 or less. Examples of the group having an ethylenically unsaturated bond include a vinyl group, a styryl group, a (meth)allyl group, and a (meth)acryloyl group. Among these, a (meth)acryloyl group is preferable. The radically polymerizable compound is preferably a (meth)acrylate compound having 3 to 15 functional groups and more preferably a (meth)acrylate compound having 3 to 6 functional groups.

The radically polymerizable compound may be in the form of a monomer or a polymer and is preferably a monomer. The molecular weight of the monomer type radically polymerizable compound is preferably 200 to 3000. The upper limit of the molecular weight is preferably 2500 or lower and more preferably 2000 or lower. The lower limit of the molecular weight is preferably 250 or higher and more preferably 300 or higher.

Examples of the radically polymerizable compound can be found in paragraphs “0033” and “0034” of JP2013-253224A, the content of which is incorporated herein by reference. As the polymerizable compound, ethyleneoxy-modified pentaerythritol tetraacrylate (as a commercially available product, NK ESTER ATM-35E manufactured by Shin-Nakamura Chemical Co., Ltd.), dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., A-DPH-12E, manufactured by Shin-Nakamura Chemical Co., Ltd.), or a structure in which the (meth)acryloyl group is bonded through an ethylene glycol residue and/or a propylene glycol residue is preferable. In addition, oligomers of the above-described examples can be used. For example, the details of the polymerizable compound can be found in paragraphs “0034” to “0038” of JP2013-253224A, the content of which is incorporated herein by reference. Examples of the compound having an ethylenically unsaturated bond include a polymerizable monomer in paragraph “0477” of JP2012-208494A (corresponding to paragraph “0585” of US2012/0235099A), the content of which is incorporated herein by reference. In addition, diglycerin ethylene oxide (EO)-modified (meth)acrylate (as a commercially available product, M-460 manufactured by Toagosei Co., Ltd.), pentaerythritol tetraacrylate (A-TMMT manufactured by Shin-Nakamura Chemical Co., Ltd.), or 1,6-hexanediol diacrylate (KAYARAD HDDA manufactured by Nippon Kayaku Co., Ltd.) is also preferable. Oligomers of the above-described examples can be used. For examples, RP-1040 (manufactured by Nippon Kayaku Co., Ltd.) is used. In addition, as the radically polymerizable compound, ARONIX M-350 or TO-2349 (manufactured by Toagosei Co., Ltd.) can also be used.

The radically polymerizable compound may have an acid group such as a carboxyl group, a sulfo group, or a phosphate group. Examples of the radically polymerizable compound having an acid group include an ester of an aliphatic polyhydroxy compound and an unsaturated carboxylic acid. A polymerizable compound having an acid group obtained by causing a nonaromatic carboxylic anhydride to react with an unreacted hydroxy group of an aliphatic polyhydroxy compound is preferable. In particular, it is more preferable that, in this ester, the aliphatic polyhydroxy compound is pentaerythritol and/or dipentaerythritol. Examples of a commercially available product of the monomer having an acid group include M-305, M-510, and M-520 of ARONIX series as polybasic acid-modified acrylic oligomer (manufactured by Toagosei Co., Ltd.). The acid value of the radically polymerizable compound having an acid group is preferably 0.1 to 40 mgKOH/g. The lower limit is preferably 5 mgKOH/g or higher. The upper limit is preferably 30 mgKOH/g or lower.

In addition, it is also preferable that the radically polymerizable compound is a compound having a caprolactone structure. The radically polymerizable compound having a caprolactone structure is not particularly limited as long as it has a caprolactone structure in the molecule thereof, and examples thereof include E-caprolactone-modified polyfunctional (meth)acrylate obtained by esterification of a polyhydric alcohol, (meth)acrylic acid, and E-caprolactone, the polyhydric alcohol being, for example, trimethylolethane, ditrimethylolethane, trimethylolpropane, ditrimethylolpropane, pentaerythritol, dipentaerythritol, tripentaerythritol, glycerin, diglycerol, or trimethylolmelamine. Examples of the polymerizable compound having a caprolactone structure can be found in paragraphs “0042” to “0045” of JP2013-253224A, the content of which is incorporated herein by reference. Examples of the compound having a caprolactone structure include: DPCA-20, DPCA-30, DPCA-60, and DPCA-120 which are commercially available as KAYARADDPCA series manufactured by Nippon Kayaku Co., Ltd.; SR-494 (manufactured by Sartomer) which is a tetrafunctional acrylate having four ethyleneoxy chains; and TPA-330 which is a trifunctional acrylate having three isobutyleneoxy chains.

As the radically polymerizable compound, a urethane acrylate described in JP1973-041708B (JP-S48-041708B), JP1976-037193A (JP-S51-037193A), JP1990-032293B (JP-H2-032293B), or JP1990-016765B (JP-H2-016765B), or a urethane compound having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) is also preferable. In addition, an addition-polymerizable compound having an amino structure or a sulfide structure in the molecules described in JP1988-277653A (JP-S63-277653A), JP1988-260909A (JP-S63-260909A), or JP1989-105238A (JP-H1-105238A) can be used. Examples of a commercially available product of the polymerizable compound include URETHANE OLIGOMER UAS-10 and UAB-140 (manufactured by Sanyo-Kokusaku Pulp Co., Ltd.), UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600 and AI-600 (manufactured by Kyoeisha Chemical Co., Ltd.).

In a case where the composition according to the embodiment of the present invention includes the radically polymerizable compound, the content of the radically polymerizable compound is preferably 0.1 to 40 mass % with respect to the total solid content of the composition. For example, the lower limit is preferably 0.5 mass % or higher and more preferably 1 mass % or higher. For example, the upper limit is more preferably 30 mass % or lower and still more preferably 20 mass % or lower. As the radically polymerizable compound, one kind may be used alone, or two or more kinds may be used in combination. In a case where two or more radically polymerizable compounds are used in combination, it is preferable that the total content of the two or more radically polymerizable compounds is in the above-described range.

(Cationically Polymerizable Compound)

Examples of the cationically polymerizable compound include a compound having a cationically polymerizable group. Examples of the cationically polymerizable group include a cyclic ether group such as an epoxy group or an oxetanyl group and an unsaturated carbon double bond group such as a vinyl ether group or an isobutene group. As the cationically polymerizable compound, a compound having a cyclic ether group is preferable, and a compound having an epoxy group is more preferable.

Examples of the compound having an epoxy group include a compound having one or more epoxy groups in one molecule. In particular, a compound having two or more epoxy groups in one molecule is preferable. The number of epoxy groups in one molecule is preferably 1 to 100. The upper limit of the number of epoxy groups is, for example, 10 or less or 5 or less. The lower limit of the number of epoxy groups is preferably 2 or more.

The compound having an epoxy group may be a low molecular weight compound (for example, molecular weight: lower than 2000 or lower than 1000) or a high molecular weight compound (macromolecule; for example, molecular weight: 1000 or higher, and in the case of a polymer, weight-average molecular weight: 1000 or higher). The weight-average molecular weight of the compound having an epoxy group is preferably 200 to 100000 and more preferably 500 to 50000. The upper limit of the weight-average molecular weight is preferably 10000 or lower, more preferably 5000 or lower, and still more preferably 3000 or lower.

In a case where the compound having an epoxy group is a low molecular weight compound, the compound having an epoxy group is, for example, a compound represented by the following Formula (EP1).

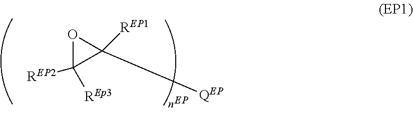

In Formula (EP1), R^{EP1} to R^{EP3} each independently represent a hydrogen atom, a halogen atom, or an alkyl group. The alkyl group may have a cyclic structure or may have a substituent. In addition, R^{EP1} and R^{EP2}, or R^{EP2} and R^{EP3} may be bonded to each other to form a ring structure. Q^{EP} represents a single bond or a n^{EP}-valent organic group. R^{EP1} to R^{EP3} may be bonded to Q^{EP} to form a ring structure. n^{EP} represents an integer of 2 or more, preferably 2 to 10, and more preferably 2 to 6. In a case where Q^{EP} represents a single bond, n^{EP} represents 2.

The details of R^{EP1} to R^{EP3} and Q^{EP} can be found in paragraphs “0087” and “0088” of JP2014-089408A, the content of which is incorporated herein by reference. Specific examples of the compound represented by Formula (EP1) include a compound described in paragraph “0090” of JP2014-089408A and a compound described in paragraph “0151” of JP2010-054632A, the content of which is incorporated herein by reference.

As the low molecular weight compound, a commercially available product can also be used. Examples of the commercially available product include ADEKA GLYCILOL series manufactured by Adeka Corporation (for example, ADEKA GLYCILOL ED-505) and EPOLEAD series manufactured by Daicel Corporation (for example, EPOLEAD GT401).

As the compound having an epoxy group, an epoxy resin can be preferably used. Examples of the epoxy resin include an epoxy resin which is a glycidyl-etherified product of a phenol compound, an epoxy resin which is a glycidyl-etherified product of various novolac resins, an alicyclic epoxy resin, an aliphatic epoxy resin, a heterocyclic epoxy resin, a glycidyl ester epoxy resin, a glycidyl amine epoxy resin, an epoxy resin which is a glycidylated product of a halogenated phenol, a condensate of a silicon compound having an epoxy group and another silicon compound, and a copolymer of a polymerizable unsaturated compound having an epoxy group and another polymerizable unsaturated compound.

Examples of the epoxy resin which is a glycidyl-etherified product of a phenol compound include: 2-[4-(2,3-epoxypropoxy)phenyl]-2-[4-[1,1-bis[4-(2,3-hydroxy)phenyl]ethyl]phenyl]propane, bisphenol A, bisphenol F, bisphenol S, 4,4′-biphenol, tetramethyl bisphenol A, dimethyl bisphenol A, tetramethyl bisphenol F, dimethyl bisphenol F, tetramethyl bisphenol S, dimethyl bisphenol S, tetramethyl-4,4′-biphenol, dimethyl-4,4′-biphenol, 1-(4-hydroxyphenyl)-2-[4-(1,1-bis-(4-hydroxyphenyl)ethyl)phenyl]propane, 2,2′-methylene-bis(4-methyl-6-t-butylphenol), 4,4′-butylidene-bis(3-methyl-6-t-butylphenol), trishydroxyphenylmethane, resorcinol, hydroquinone, pyrogallol, phloroglucinol, a phenol having a diisopropylidene skeleton; a phenol having a fluorene skeleton such as 1,1-di-4-hydroxyphenyl fluorene; and an epoxy resin which is a glycidyl-etherified product of a polyphenol compound, such as phenolic polybutadiene.

Examples of the epoxy resin which is a glycidyl-etherified product of a novolac resin include glycidyl-etherified products of various novolac resins including: novolac resins which contain various phenols, for example, phenol, cresols, ethyl phenols, butyl phenols, octyl phenols, bisphenols such as bisphenol A, bisphenol F, or bisphenol S, or naphthols; phenol novolac resins having a xylylene skeleton; phenol novolac resins having a dicyclopentadiene skeleton; phenol novolac resins having a biphenyl skeleton; or phenol novolac resins having a fluorene skeleton.

Examples of the alicyclic epoxy resin include an alicyclic epoxy resin having an aliphatic ring skeleton such as 3,4-epoxycyclohexylmethyl-(3,4-epoxy)cyclohexylcarboxylate or bis(3,4-epoxycyclohexylmethyl)adipate.

Examples of the aliphatic epoxy resin include glycidyl ethers of polyhydric alcohols such as 1,4-butanediol, 1,6-hexanediol, polyethylene glycol, or pentaerythritol.

Examples of the heterocyclic epoxy resin include a heterocyclic epoxy resin having a heterocycle such as an isocyanuric ring or a hydantoin ring.

Examples of the glycidyl ester epoxy resin include an epoxy resin including a carboxylic acid ester such as hexahydrophthalic acid diglycidyl ester.

Examples of the glycidyl amine epoxy resin include an epoxy resin which is a glycidylated product of an amine such as aniline or toluidine.

Examples of the epoxy resin which is a glycidylated product of a halogenated phenol include an epoxy resin which is a glycidylated product of a halogenated phenol such as brominated bisphenol A, brominated bisphenol F, brominated bisphenol S, brominated phenol novolac, brominated cresol novolac, chlorinated bisphenol S, or chlorinated bisphenol A.

Examples of a commercially available product of the copolymer of a polymerizable unsaturated compound having an epoxy group and another polymerizable unsaturated compound include MARPROOF G-0150M, G-0105SA, G-0130SP, G-0250SP, G-1005S, G-1005SA, G-1010S, G-2050M, G-01100, and G-01758 (all of which are manufactured by NOF Corporation; epoxy group-containing polymers). Examples of the polymerizable unsaturated compound having an epoxy group include glycidyl acrylate, glycidyl methacrylate, and 4-vinyl-1-cyclohexene-1,2-epoxide. In addition, examples of the other polymerizable unsaturated compound include methyl (meth)acrylate, benzyl (meth)acrylate, cyclohexyl (meth)acrylate, styrene, and vinyl cyclohexane. In particular, methyl (meth)acrylate, benzyl (meth)acrylate, or styrene is preferable.

The epoxy equivalent of the epoxy resin is preferably 310 to 3300 g/eq, more preferably 310 to 1700 g/eq, and still more preferably 310 to 1000 g/eq.

As the epoxy resin, a commercially available product can also be used. Examples of the commercially available product include “EHPE3150” (manufactured by Daicel Corporation) and “EPICLON N-695” (manufactured by DIC Corporation).

In the present invention, as the compound having an epoxy group, compounds described in paragraphs “0034” to “0036” of JP2013-011869A, paragraphs “0147” to “0156” of JP2014-043556A, and paragraphs “0085” to “0092” of JP2014-089408A can also be used. The contents of which are incorporated herein by reference.

In a case where the composition according to the embodiment of the present invention includes the cationically polymerizable compound, the content of the cationically polymerizable compound is preferably 0.1 to 40 mass % with respect to the total solid content of the composition. For example, the lower limit is preferably 0.5 mass % or higher and more preferably 1 mass % or higher. For example, the upper limit is more preferably 30 mass % or lower and still more preferably 20 mass % or lower. As the cationically polymerizable compound, one kind may be used alone, or two or more kinds may be used in combination. In a case where two or more cationically polymerizable compounds are used in combination, it is preferable that the total content of the two or more cationically polymerizable compounds is in the above-described range.

In addition, in a case where the composition according to the embodiment of the present invention includes the radically polymerizable compound and the cationically polymerizable compound, a mass ratio radically polymerizable compound:cationically polymerizable compound is preferably 100:1 to 100:400 and more preferably 100:1 to 100:100.

<<Photoinitiator>>

The composition according to the embodiment of the present invention may include a photoinitiator. Examples of the photoinitiator include a photoradical polymerization initiator and a photocationic polymerization initiator. It is preferable that the photoinitiator is selected and used according to the kind of the curable compound. In a case where the radically polymerizable compound is used as the curable compound, it is preferable that the photoradical polymerization initiator is used as the photoinitiator. In a case where the cationically polymerizable compound is used as the curable compound, it is preferable that the photocationic polymerization initiator is used as the photoinitiator. The photoinitiator is not particularly limited and can be appropriately selected from well-known photoinitiators. For example, a compound having photosensitivity to light in a range from the ultraviolet range to the visible range is preferable.

The content of the photoinitiator is preferably 0.1 to 50 mass %, more preferably 0.5 to 30 mass %, and still more preferably 1 to 20 mass % with respect to the total solid content of the composition. In a case where the content of the photoinitiator is in the above-described range, higher sensitivity and pattern formability can be obtained. The composition according to the embodiment of the present invention may include one photoinitiator or two or more photoinitiators. In a case where the composition includes two or more photoinitiators, it is preferable that the total content of the photoinitiators is in the above-described range.

(Photoradical Polymerization Initiator)

Examples of the photoradical polymerization initiator include: a halogenated hydrocarbon derivative (For example, a compound having a triazine skeleton or a compound having an oxadiazole skeleton); an acylphosphine compound such as acylphosphine oxide; an oxime compound such as hexaarylbiimidazole or an oxime derivative; an organic peroxide, a thio compound, a ketone compound, an aromatic onium salt, keto oxime ether, an aminoacetophenone compound, and hydroxyacetophenone. Examples of the halogenated hydrocarbon compound having a triazine skeleton include a compound described in Bull. Chem. Soc. Japan, 42, 2924 (1969) by Wakabayshi et al., a compound described in Great Britain Patent No. 1388492, a compound described in JP1978-133428A (JP-S53-133428A), a compound described in German Patent No. 3337024, a compound described in J. Org. Chem.; 29, 1527 (1964) by F. C. Schaefer et al., a compound described in JP1987-058241A (JP-S62-058241A), a compound described in JP1993-281728A (JP-H5-281728A), a compound described in JP1993-034920A (JP-S5-034920A), and a compound described in U.S. Pat. No. 4,212,976A (for example, a compound having an oxadiazole skeleton).

In addition, from the viewpoint of exposure sensitivity, as the photoradical polymerization initiator, a compound selected from the group consisting of a trihalomethyltriazine compound, a benzyldimethylketanol compound, an α-hydroxy ketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable.

As the photoradical polymerization initiator, an α-hydroxyketone compound, an α-aminoketone compound, or an acylphosphine compound can also be preferably used. For example, an α-aminoketone compound described in JP1998-291969A (JP-H10-291969A) or an acylphosphine compound described in JP4225898B can also be used. As the α-hydroxyketone compound, for example, IRGACURE-184, DAROCUR-1173, IRGACURE-500, IRGACURE-2959, or IRGACURE-127 (all of which are manufactured by BASF SE) can be used. As the α-aminoketone compound, IRGACURE-907, IRGACURE-369, IRGACURE-379, or IRGACURE-379EG (all of which are manufactured by BASF SE) which is a commercially available product can be used. As the α-aminoketone compound, a compound described in JP2009-191179A can be used. As the acylphosphine compound, IRGACURE-819, or DAROCUR-TPO (all of which are manufactured by BASF SE) which is a commercially available product can be used.

As the photoradical polymerization initiator, an oxime compound can be preferably used. Specific examples of the oxime compound include a compound described in JP2001-233842A, a compound described in JP2000-080068A, a compound described in JP2006-342166A, and a compound described in JP2016-021012A. Examples of the oxime compound which can be preferably used in the present invention include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. In addition, examples of the oxime compound include a compound described in J. C. S. Perkin II (1979), pp. 1653-1660, J. C. S. Perkin II (1979), pp. 156-162 and Journal of Photopolymer Science and Technology (1995), pp. 202-232, JP2000-066385A, JP2000-080068A, JP2004-534797A, or JP2006-342166A.

As a commercially available product of the oxime compound, IRGACURE-OXE01, IRGACURE-OXE02, IRGACURE-OXE03, or IRGACURE-OXE04 (all of which are manufactured by BASF SE) can also be preferably used. In addition, TR-PBG-304 (manufactured by Changzhou Tronly New Electronic Materials Co., Ltd.), ADEKA ARKLS NCI-831 (manufactured by Adeka Corporation), ADEKA ARKLS NCI-930 (manufactured by Adeka Corporation), ADEKA OPTOMER N-1919 (manufactured by Adeka Corporation, a photopolymerization initiator 2 described in JP2012-014052A) can also be used.

In addition, in addition to the above-described oxime compounds, for example, a compound described in JP2009-519904A in which oxime is linked to a N-position of a carbazole ring, a compound described in U.S. Pat. No. 7,626,957B in which a hetero substituent is introduced into the benzophenone site, a compound described in JP2010-015025A or US2009/292039A in which a nitro group is introduced into a colorant site, a ketoxime compound described in WO2009/131189A, a compound described in U.S. Pat. No. 7,556,910B having a triazine skeleton and an oxime skeleton in the same molecule, a compound described in JP2009-221114A having an absorption maximum at 405 nm and having excellent sensitivity to a light source of g-rays may be used.

As the oxime compound, a compound represented by the following Formula (OX-1) can be preferably used. In the oxime compound, an N—O bond of oxime may form an (E) isomer, a (Z) isomer, or a mixture of an (E) isomer and a (Z) isomer.

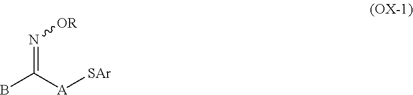

In Formula (OX-1), R and B each independently represent a monovalent substituent, A represents a divalent organic group, and Ar represents an aryl group. The details of Formula (OX-1) can be found in paragraphs “0276” to “0304” of JP2013-029760A, the content of which is incorporated herein by reference.

In the present invention, an oxime compound having a fluorene ring can also be used as the photoradical polymerization initiator. Specific examples of the oxime compound having a fluorene ring include a compound described in JP2014-137466A. The content is incorporated herein by reference.

In the present invention, an oxime compound having a fluorine atom can also be used as the photoradical polymerization initiator. Specific examples of the oxime compound having a fluorine atom include a compound described in JP2010-262028A, Compound 24 and 36 to 40 described in JP2014-500852A, and Compound (C-3) described in JP2013-164471A. The content is incorporated herein by reference.

In the present invention, as the photoradical polymerization initiator, an oxime compound having a nitro group can be used. It is preferable that the oxime compound having a nitro group is a dimer. Specific examples of the oxime compound having a nitro group include a compound described in paragraphs “0031” to “0047” of JP2013-114249A and paragraphs “0008” to “0012” and “0070” to “0079” of JP2014-137466A, a compound described in paragraphs “0007” to 0025″ of JP4223071B, and ADEKA ARKLS NCI-831 (manufactured by Adeka Corporation).

Hereinafter, specific examples of the oxime compound which are preferably used in the present invention are shown below, but the present invention is not limited thereto.

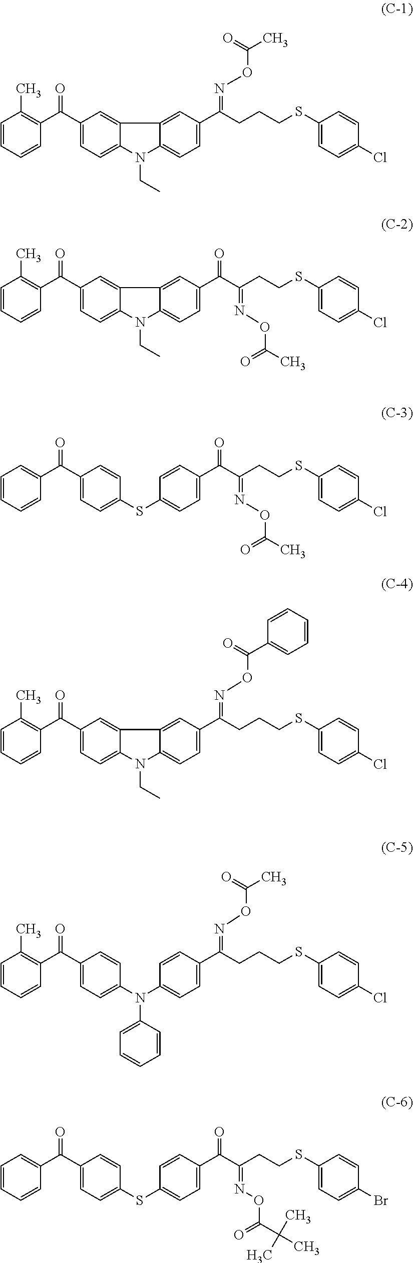 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

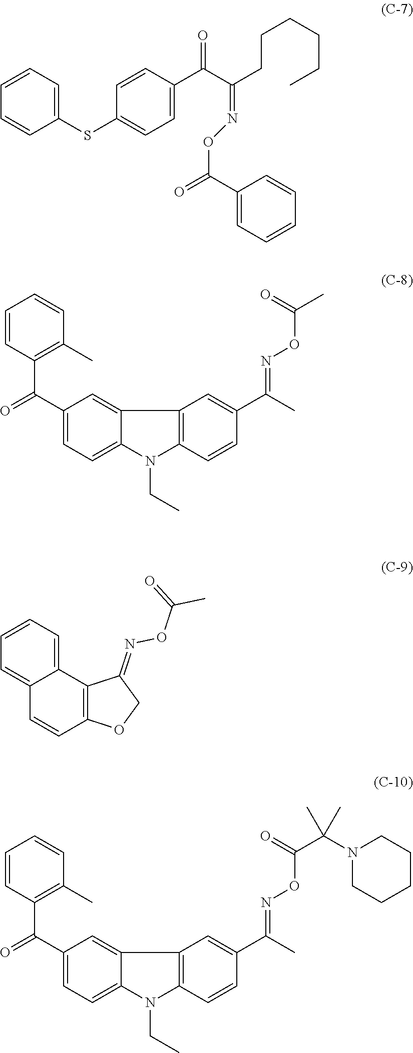 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21]

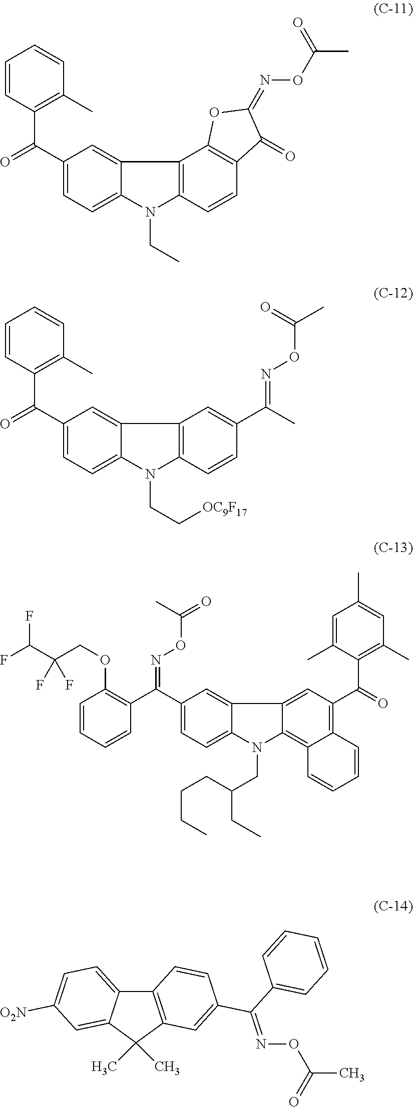

The oxime compound is preferably a compound having an absorption maximum in a wavelength range of 350 nm to 500 nm and more preferably a compound having an absorption maximum in a wavelength range of 360 nm to 480 nm. In addition, the oxime compound is preferably a compound having a high absorbance at 365 nm and 405 nm.

The molar absorption coefficient of the oxime compound at 365 nm or 405 nm is preferably 1000 to 300000, more preferably 2000 to 300000, and still more preferably 5000 to 200000 from the viewpoint of sensitivity.

The molar absorption coefficient of the compound can be measured using a well-known method. For example, it is preferable that the absorption coefficient can be measured using an ultraviolet-visible spectrophotometer (Cary-5 spectrophotometer, manufactured by Varian Medical Systems, Inc.) and ethyl acetate as a solvent at a concentration of 0.01 g/L.

It is preferable that the photoradical polymerization initiator includes an oxime compound and an α-aminoketone compound. By using the oxime compound and the α-aminoketone compound in combination, the developability is improved, and a pattern having excellent rectangularity is likely to be formed. In a case where the oxime compound and the α-aminoketone compound are used in combination, the content of the α-aminoketone compound is preferably 50 to 600 parts by mass and more preferably 150 to 400 parts by mass with respect to 100 parts by mass of the oxime compound.

The content of the photoradical polymerization initiator is preferably 0.1 to 50 mass %, more preferably 0.5 to 30 mass %, and still more preferably 1 to 20 mass % with respect to the total solid content of the composition. In a case where the content of the photoradical polymerization initiator is in the above-described range, higher sensitivity and pattern formability can be obtained. The composition according to the embodiment of the present invention may include one photoradical polymerization initiator or two or more photoradical polymerization initiators. In a case where the composition includes two or more photoradical polymerization initiators, it is preferable that the total content of the photoradical polymerization initiators is in the above-described range.

(Photocationic Polymerization Initiator)

Examples of the photocationic polymerization initiator include a photoacid generator. Examples of the photoacid generator include compounds which are decomposed by light irradiation to generate an acid including: an onium salt compound such as a diazonium salt, a phosphonium salt, a sulfonium salt, or an iodonium salt; and a sulfonate compound such as imidosulfonate, oximesulfonate, diazodisulfone, disulfone, or o-nitrobenzyl sulfonate. The details of the photocationic polymerization initiator can be found in paragraphs “0139” to “0214” of JP2009-258603A, the content of which is incorporated herein by reference.

As the photocationic polymerization initiator, a commercially available product can also be used. Examples of the commercially available product of the photocationic polymerization initiator include ADEKA ARKLS SP series manufactured by Adeka Corporation (for example, ADEKA ARKLS SP-606) and IRGACURE 250, IRGACURE 270, and IRGACURE 290 manufactured by BASF SE.

The content of the photocationic polymerization initiator is preferably 0.1 to 50 mass %, more preferably 0.5 to 30 mass %, and still more preferably 1 to 20 mass % with respect to the total solid content of the composition. In a case where the content of the photocationic polymerization initiator is in the above-described range, higher sensitivity and pattern formability can be obtained. The composition according to the embodiment of the present invention may include one photocationic polymerization initiator or two or more photocationic polymerization initiators. In a case where the composition includes two or more photocationic polymerization initiators, it is preferable that the total content of the two or more photocationic polymerization initiators is in the above-described range.

<<Chromatic Colorant>>

The composition according to the embodiment of the present invention may include a chromatic colorant. In the present invention, “chromatic colorant” denotes a colorant other than a white colorant and a black colorant. It is preferable that the chromatic colorant is a colorant having an absorption in a wavelength range of 400 nm or longer and shorter than 650 nm.

In the present invention, the chromatic colorant may be a pigment or a dye. As the pigment, an organic pigment is preferable. Examples of the organic pigment are as follows:

Color Index (C.I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214 (all of which are yellow pigments);

C.I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C.I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279 (all of which are red pigments);

C.I. Pigment Green 7, 10, 36, 37, 58, and 59 (all of which are green pigments); C.I. Pigment Violet 1, 19, 23, 27, 32, 37, and 42 (all of which are violet pigments); and

C.I. Pigment Blue 1, 2, 15, 15:1, 15:2, 15:3, 15:4, 15:6, 16, 22, 60, 64, 66, 79, and 80 (all of which are blue pigments).

Among these organic pigments, one kind may be used alone, or two or more kinds may be used in combination.

As the dye, well-known dyes can be used without any particular limitation. In terms of a chemical structure, a dye such as a pyrazole azo dye, an anilino azo dye, a triarylmethane dye, an anthraquinone dye, an anthrapyridone dye, a benzylidene dye, an oxonol dye, a pyrazolotriazole azo dye, a pyridone azo dye, a cyanine dye, a phenothiazine dye, a pyrrolopyrazole azomethine dye, a xanthene dye, a phthalocyanine dye, a benzopyran dye, an indigo dye, or a pyrromethene dye can be used. In addition, a polymer of the above-described dyes may be used. In addition, dyes described in JP2015-028144A and JP2015-034966A can also be used.

In a case where the composition according to the embodiment of the present invention includes a chromatic colorant, the content of the chromatic colorant is preferably 0.1 to 70 mass % with respect to the total solid content of the composition according to the embodiment of the present invention. The lower limit is preferably 0.5 mass % or higher and more preferably 1.0 mass % or higher. The upper limit is preferably 60 mass % or lower, and more preferably 50 mass % or lower.

The content of the chromatic colorant is preferably 10 to 1000 parts by mass and more preferably 50 to 800 parts by mass with respect to 100 parts by mass of the near infrared absorber.

In addition, the total content of the chromatic colorant and the near infrared absorber is preferably 1 to 80 mass % with respect to the total solid content of the composition according to the embodiment of the present invention. The lower limit is preferably 5 mass % or higher and more preferably 10 mass % or higher. The upper limit is preferably 70 mass % or lower, and more preferably 60 mass % or lower.

In a case where the composition according to the embodiment of the present invention includes two or more chromatic colorants, it is preferable that the total content of the two or more chromatic colorants is in the above-described range.

<<Coloring Material that Allows Transmission of Infrared Light and Shields Visible Light>>

The composition according to the embodiment of the present invention may also include the coloring material that allows transmission of infrared light and shields visible light (hereinafter, also referred to as “coloring material that shields visible light”).

In the present invention, it is preferable that the coloring material that shields visible light is a coloring material that absorbs light in a wavelength range of violet to red. In addition, in the present invention, it is preferable that the coloring material that shields visible light is a coloring material that shields light in a wavelength range of 450 to 650 nm. In addition, it is preferable that the coloring material that shields visible light is a coloring material that allows transmission of light in a wavelength range of 900 to 1300 nm.

In the present invention, it is preferable that the coloring material that shields visible light satisfies at least one of the following requirement (1) or (2).

(1): The coloring material that shields visible light includes two or more chromatic colorants, and a combination of the two or more chromatic colorants forms black

(2): The coloring material that shields visible light includes an organic black colorant

In a case where the composition according to the embodiment of the present invention includes the coloring material that shields visible light, the content of the coloring material that shields visible light is preferably 30 mass % or lower, more preferably 20 mass % or lower, and still more preferably 15 mass % or lower with respect to the total solid content of the composition. The lower limit is, for example, 0.01 mass % or higher or 0.5 mass % or higher.

<<Pigment Derivative>>

The composition according to the embodiment of the present invention may further include a pigment derivative. Examples of the pigment derivative include a compound having a structure in which a portion of a pigment is substituted with an acidic group, a basic group, a group having a salt structure, or a phthalimidomethyl group. Among these, a pigment derivative represented by Formula (B1) is more preferable.

PL-(X)ₙ)ₘ (B1)

In Formula (B1), P represents a colorant structure, L represents a single bond or a linking group, X represents an acidic group, a basic group, a group having a salt structure, or a phthalimidomethyl group, m represents an integer of 1 or more, n represents an integer of 1 or more, in a case where m represents 2 or more, a plurality of L's and a plurality of X's may be different from each other, and in a case where n represents 2 or more, a plurality of X's may be different from each other.

In Formula (B1), P represents a colorant structure, preferably at least one selected from the group consisting of a pyrrolopyrrole colorant structure, a diketo pyrrolopyrrole colorant structure, a quinacridone colorant structure, an anthraquinone colorant structure, an anthraquinone colorant structure, a benzoisoindole colorant structure, a thiazine indigo colorant structure, an azo colorant structure, a quinophthalone colorant structure, a phthalocyanine colorant structure, a naphthalocyanine colorant structure, a dioxazine colorant structure, a perylene colorant structure, a perinone colorant structure, a benzimidazolone colorant structure, a benzothiazole colorant structure, a benzimidazole colorant structure, and a benzoxazole colorant structure, more preferably at least one selected from the group consisting of a pyrrolopyrrole colorant structure, a diketo pyrrolopyrrole colorant structure, a quinacridone colorant structure, and a benzimidazolone colorant structure, and still more preferably a pyrrolopyrrole colorant structure.

In Formula (B1), L represents a single bond or a linking group. The linking group is preferably a group composed of 1 to 100 carbon atoms, 0 to 10 nitrogen atoms, 0 to 50 oxygen atoms, 1 to 200 hydrogen atoms, and 0 to 20 sulfur atoms, and may be unsubstituted or may further have a substituent.

In Formula (B1), X represents an acidic group, a basic group, a group having a salt structure, or a phthalimidomethyl group.

Specific examples of the pigment derivative include the following compounds. In the following structural formulae, Me represents a methyl group, and Ph represents a phenyl group. In addition, for example, compounds described in JP1981-118462A (JP-S56-118462A), JP1988-264674A (JP-S63-264674A), JP1989-217077A (JP-H1-217077A), JP1991-009961A (JP-113-009961A), JP1991-026767A (JP-H3-026767A), JP1991-153780A (JP-H3-153780A), JP1991-045662A (JP-H3-045662A), JP1992-285669A (JP-H4-285669A), JP1994-145546A (JP-H6-145546A), JP1994-212088A (JP-H6-212088A), JP1994-240158A (JP-H6-240158A), JP1998-030063A (JP-H10-030063A), JP1998-195326A (JP-H10-195326A), paragraphs “0086” to “0098” of WO2011/024896A, and paragraphs “0063” to “0094” of WO2012/102399A can be used, the contents of which are incorporated herein by reference.

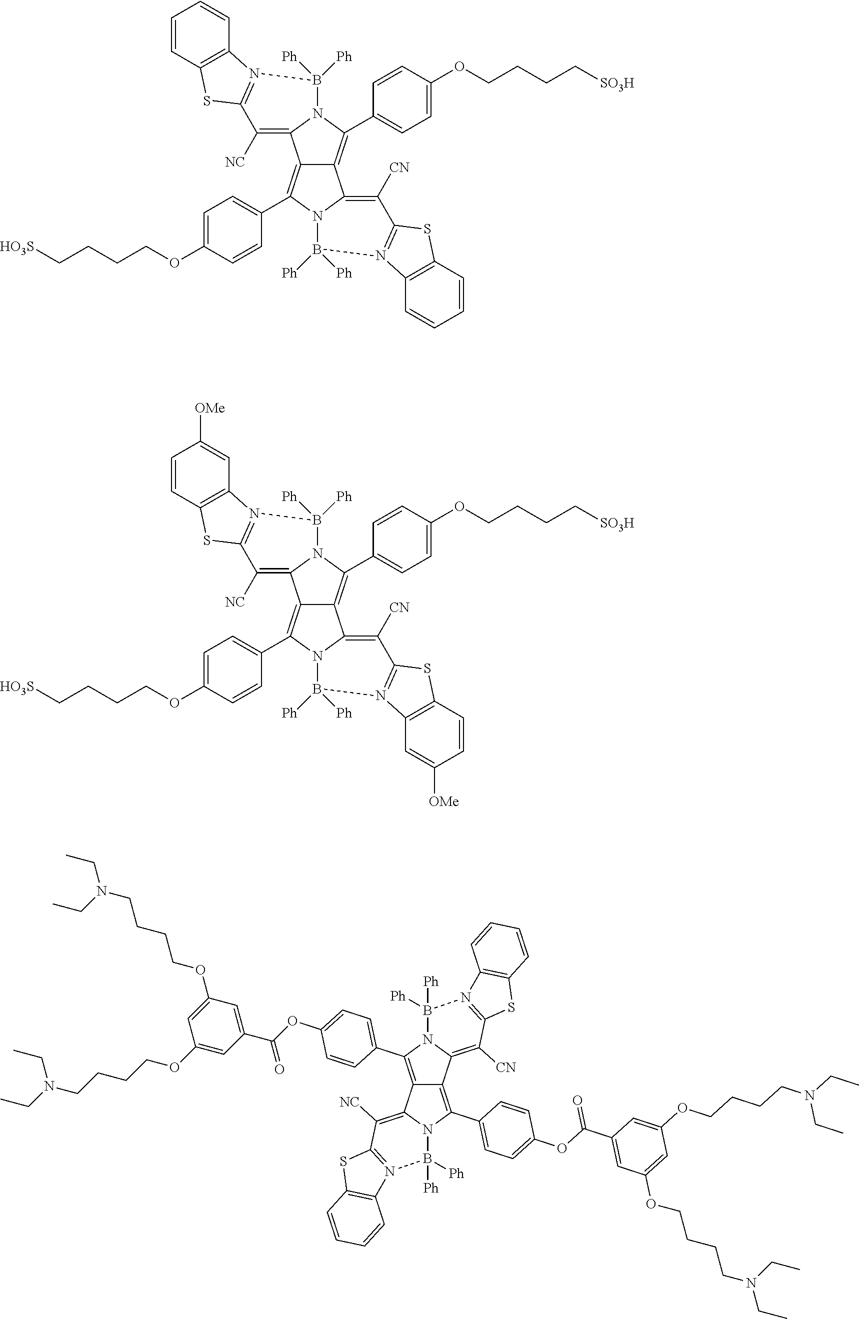

In a case where the composition according to the embodiment of the present invention includes the pigment derivative, the content of the pigment derivative is preferably 1 to 50 parts by mass with respect to 100 parts by mass of the pigment. The lower limit value is preferably 3 parts by mass or more and more preferably 5 parts by mass or more. The upper limit value is preferably 40 parts by mass or less and more preferably 30 parts by mass or less. In a case where the content of the pigment derivative is in the above-described range, the pigment dispersibility can be improved, and aggregation of the pigment can be effectively suppressed. As the pigment derivative, one kind may be used alone, or two or more kinds may be used in combination. In a case where two or pigment derivatives are used in combination, it is preferable that the total content of the two or more pigment derivatives is in the above-described range.

<<Resin>>

It is preferable that the composition according to the embodiment of the present invention includes a resin. The resin is mixed, for example, in order to disperse the pigment and the like in the composition or to be used as a binder. The resin which is mainly used to disperse the pigments and the like will also be called a dispersant. However, the above-described uses of the resin are merely exemplary, and the resin can be used for purposes other than the uses.

The weight-average molecular weight (Mw) of the resin is preferably 2000 to 2000000. The upper limit is preferably 1000000 or lower and more preferably 500000 or lower. The lower limit is preferably 3000 or higher and more preferably 5000 or higher.

Examples of the resin include a (meth)acrylic resin, an epoxy resin, an enethiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide imide resin, a polyolefin resin, a cyclic olefin resin, a polyester resin, and a styrene resin. Among these resins, one kind may be used alone, or a mixture of two or more kinds may be used.

In the present invention, it is preferable that a resin having an acid group is used as the resin. According to this aspect, a pattern having excellent rectangularity can be easily formed. Examples of the acid group include a carboxyl group, a phosphate group, a sulfo group, and a phenolic hydroxyl group. Among these, a carboxyl group is preferable. The resin having an acid group can be used as, for example, an alkali-soluble resin.

As the resin having an acid group, a polymer having a carboxyl group at a side chain is preferable. Specific examples of the alkali-soluble resin include an alkali-soluble phenol resin such as a methacrylic acid copolymer, an acrylic acid copolymer, an itaconic acid copolymer, a crotonic acid copolymer, a maleic acid copolymer, a partially esterified maleic acid copolymer, or a novolac resin, an acidic cellulose derivative having a carboxyl group at a side chain thereof, and a resin obtained by adding an acid anhydride to a polymer having a hydroxy group. In particular, a copolymer of (meth)acrylic acid and another monomer which is copolymerizable with the (meth)acrylic acid is preferable as the alkali-soluble resin. Examples of the monomer which is copolymerizable with the (meth)acrylic acid include an alkyl (meth)acrylate, an aryl (meth)acrylate, and a vinyl compound. Examples of the alkyl (meth)acrylate and the aryl (meth)acrylate include methyl (meth)acrylate, ethyl (meth)acrylate, propyl (meth) acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyl toluene, glycidyl methacrylate, acrylonitrile, vinyl acetate, N-vinylpyrrolidone, tetrahydrofurfuryl methacrylate, a polystyrene macromonomer, and a polymethyl methacrylate macromonomer. Examples of other monomers include a N-position-substituted maleimide monomer described in JP1998-300922A (H10-300922A) such as N-phenylmaleimide or N-cyclohexylmaleimide. Among these monomers which are copolymerizable with the (meth)acrylic acid, one kind may be used alone, or two or more kinds may be used in combination.

The resin having an acid group may further have a polymerizable group. Examples of the polymerizable group include a (meth)allyl group and a (meth)acryloyl group. Examples of a commercially available product of the resin include DIANAL NR series (manufactured by Mitsubishi Rayon Co., Ltd.), PHOTOMER 6173 (a COOH-containing polyurethane acrylic oligomer; manufactured by Diamond Shamrock Co., Ltd.), VISCOAT R-264 and KS Resist 106 (both of which are manufactured by Osaka Organic Chemical Industry Ltd.), CYCLOMER-P series (for example, ACA230AA) and PLAKCEL CF200 series (both of which manufactured by Daicel Corporation), EBECRYL 3800 (manufactured by Daicel-UCB Co., Ltd.), and ACRYCURE RD-F8 (manufactured by Nippon Shokubai Co., Ltd.).

As the resin having an acid group, a copolymer including benzyl (meth)acrylate and (meth)acrylic acid; a copolymer including benzyl (meth)acrylate, (meth)acrylic acid, and 2-hydroxyethyl (meth)acrylate; or a multi-component copolymer including benzyl (meth)acrylate, (meth)acrylic acid, and another monomer can be preferably used. In addition, copolymers described in JP1995-140654A (JP-H7-140654A) obtained by copolymerization of 2-hydroxyethyl (meth)acrylate can be preferably used, and examples thereof include: a copolymer including 2-hydroxypropyl (meth)acrylate, a polystyrene macromonomer, benzyl methacrylate, and methacrylic acid; a copolymer including 2-hydroxy-3-phenoxypropyl acrylate, a polymethyl methacrylate macromonomer, benzyl methacrylate, and methacrylic acid; a copolymer including 2-hydroxyethyl methacrylate, a polystyrene macromonomer, methyl methacrylate, and methacrylic acid; or a copolymer including 2-hydroxyethyl methacrylate, a polystyrene macromonomer, benzyl methacrylate, and methacrylic acid.

As the resin having an acid group, a polymer obtained by polymerization of monomer components including a compound represented by the following Formula (ED1) and/or a compound represented by the following Formula (ED2) (hereinafter, these compounds will also be referred to as “ether dimer”) is also preferable.

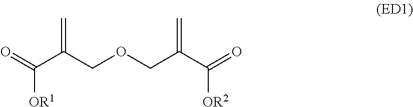

In Formula (ED1), R¹ and R² each independently represent a hydrogen atom or a hydrocarbon group having 1 to 25 carbon atoms which may have a substituent.

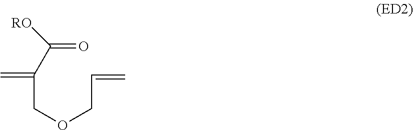

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph “0317” of JP2013-029760A, the content of which is incorporated herein by reference. As the ether dimer, one kind may be used alone, or two or more kinds may be used in combination.

The resin having an acid group may include a repeating unit which is derived from a compound represented by the following Formula (X).

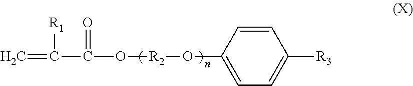

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may have a benzene ring. n represents an integer of 1 to 15.

The details of the resin having an acid group can be found in paragraphs “0558” to “0571” of JP2012-208494A (corresponding to paragraphs “0685” to “0700” of US2012/0235099A) and paragraphs “0076” to “0099” of JP2012-198408A, the contents of which are incorporated herein by reference.

The acid value of the resin having an acid group is preferably 30 to 200 mgKOH/g. The lower limit is preferably 50 mgKOH/g or higher and more preferably 70 mgKOH/g or higher. The upper limit is preferably 150 mgKOH/g or lower and more preferably 120 mgKOH/g or lower.

Examples of the resin having an acid group include resins having the following structures. In the following structural formulae, Me represents a methyl group.

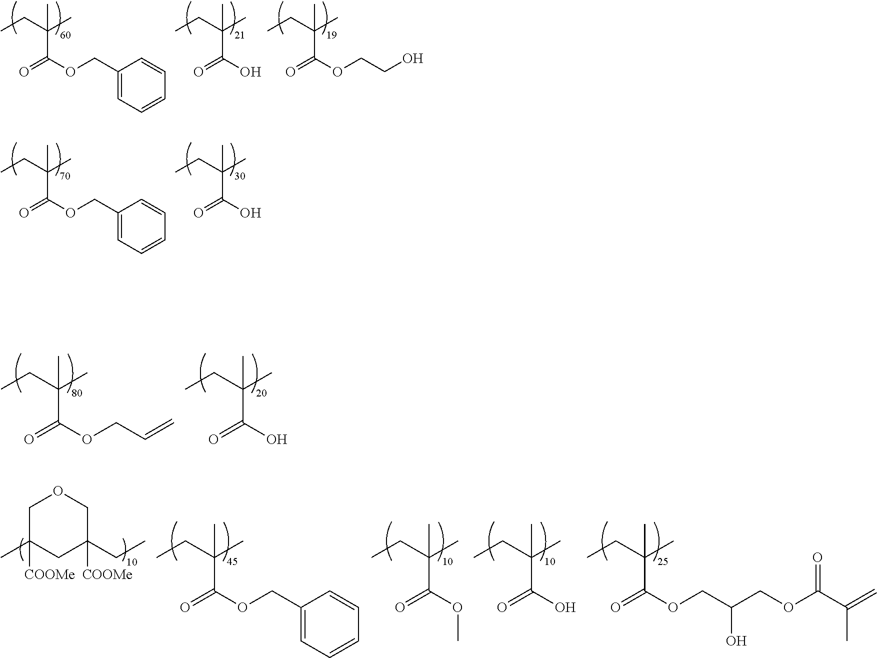

In the composition according to the embodiment of the present invention, as the resin, a resin having a repeating unit represented by any one of Formulae (A3-1) to (A3-7) can also be used.

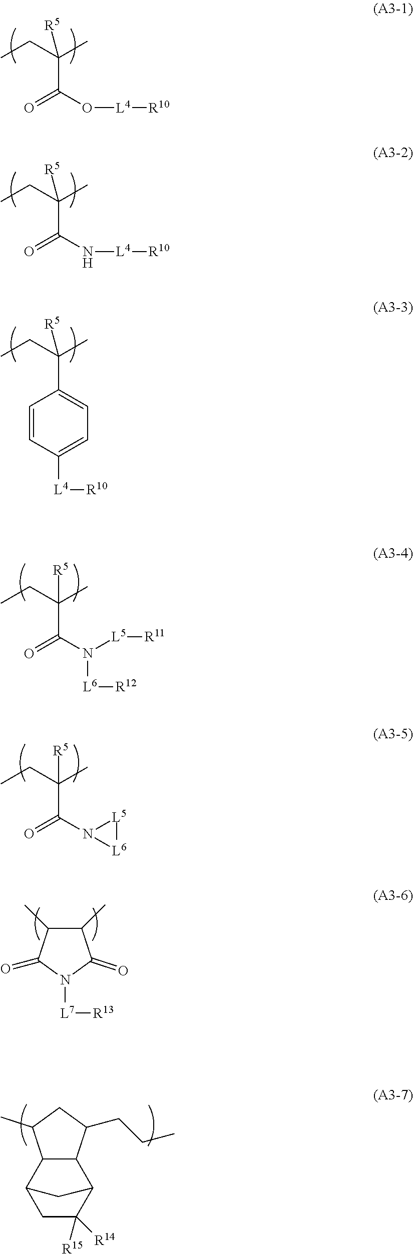

In the formulae, R⁵ represents a hydrogen atom or an alkyl group, L⁴ to L⁷ each independently represent a single bond or a divalent linking group, and R¹⁰ to R¹³ each independently represent an alkyl group or an aryl group. R¹⁴ and R¹⁵ each independently represent a hydrogen atom or a substituent.

R⁵ represents a hydrogen atom or an alkyl group. The number of carbon atoms in the alkyl group is preferably 1 to 5, more preferably 1 to 3, and still more preferably 1. It is preferable that R⁵ represents a hydrogen atom or a methyl group.

L⁴ to L⁷ each independently represent a single bond or a divalent linking group. Examples of the divalent linking group include an alkylene group, an arylene group, —O—, —S—, —CO—, —COO—, —OCO—, —SO₂—, —NR¹⁰— (R represents a hydrogen atom or an alkyl group and preferably a hydrogen atom), and a group including a combination thereof. Among these, a group including a combination —O— and at least one of an alkylene group, an arylene group, or an alkylene group is preferable. The number of carbon atoms in the alkylene group is preferably 1 to 30, more preferably 1 to 15, and still more preferably 1 to 10. The alkylene group may have a substituent but is preferably unsubstituted. The alkylene group may be linear, branched, or cyclic. In addition, the cyclic alkylene group may be monocyclic or polycyclic. The number of carbon atoms in the arylene group is preferably 6 to 18, more preferably 6 to 14, and still more preferably 6 to 10.

The alkyl group represented by R¹⁰ may be linear, branched, or cyclic and is preferably cyclic. The alkyl group may have a substituent or may be unsubstituted. The number of carbon atoms in the alkyl group is preferably 1 to 30, more preferably 1 to 20, and still more preferably 1 to 10. The number of carbon atoms in the aryl group represented by R¹⁰ is preferably 6 to 18, more preferably 6 to 12, and still more preferably 6. It is preferable that R¹⁰ represents a cyclic alkyl group or an aryl group.

The alkyl group represented by R¹¹ and R¹² may be linear, branched, or cyclic and is preferably linear or branched. The alkyl group may have a substituent or may be unsubstituted. The number of carbon atoms in the alkyl group is preferably 1 to 12, more preferably 1 to 6, and still more preferably 1 to 4. The number of carbon atoms in the aryl group represented by R¹¹ and R¹² is preferably 6 to 18, more preferably 6 to 12, and still more preferably 6. It is preferable that R¹¹ and R¹² represent a linear or branched alkyl group.

The alkyl group represented by R¹³ may be linear, branched, or cyclic and is preferably linear or branched. The alkyl group may have a substituent or may be unsubstituted. The number of carbon atoms in the alkyl group is preferably 1 to 12, more preferably 1 to 6, and still more preferably 1 to 4. The number of carbon atoms in the aryl group represented by R¹³ is preferably 6 to 18, more preferably 6 to 12, and still more preferably 6. It is preferable that R¹³ represents a linear or branched alkyl group or an aryl group.

Examples of the substituent represented by R¹⁴ and R¹⁵ include a halogen atom, a cyano group, a nitro group, an alkyl group, an alkenyl group, an alkynyl group, an aryl group, a heteroaryl group, an aralkyl group, an alkoxy group, an aryloxy group, a heteroaryloxy group, an alkylthio group, an arylthio group, a heteroarylthio group, —NR^{a1}R^{a2}, —COR^{a3}, —COOR^{a4}, —OCOR^{a5}, —NHCOR^{a6}, —CONR^{a7}R^{a8}, —NHCONR^{a9}R^{a10}, —NHCOOR^{a11}, —SO₂R^{a12}, —SO₂OR^{a13}, —NHSO₂R^{a14}, and —SO₂NR^{a15}R^{a16}. R^{a1} to R^{a16} each independently represent a hydrogen atom, an alkyl group, an alkenyl group, an alkynyl group, an aryl group, or a heteroaryl group. In particular, it is preferable that at least one of R¹⁴ or R¹⁵ represents a cyano group or —COOR^{a4}. It is preferable that R^{a4} represents a hydrogen atom, an alkyl group, or an aryl group.

Examples of a commercially available product of the resin having a repeating unit represented by Formula (A3-7) include ARTON F4520 (manufactured by JSR Corporation). In addition, the details of the resin having a repeating unit represented by Formula (A3-7) can be found in paragraphs “0053” to “0075” and “0127” to “0130” of JP2011-100084A, the content of which is incorporated herein by reference.

(Dispersant)

The composition according to the embodiment of the present invention may include a dispersant as a resin. In particular, in a case where a pigment is used, it is preferable that the composition includes a dispersant. Examples of the dispersant include an acidic dispersant (acidic resin) and a basic dispersant (basic resin). It is preferable that the dispersant includes at least an acidic dispersant, and it is more preferable that the dispersant consists of only an acidic dispersant. By the dispersant including at least the acidic dispersant, the pigment dispersibility is improved, and excellent developability can be obtained. Therefore, a pattern can be suitably formed using a photolithography method. In a case where the dispersant consists of only an acidic dispersant, for example, the content of the acidic dispersant is preferably 99 mass % or higher and more preferably 99.9 mass % or higher with respect to the total mass of the dispersant.

Here, the acidic dispersant (acidic resin) refers to a resin in which the amount of an acid group is more than the amount of a basic group. In a case where the sum of the amount of an acid group and the amount of a basic group in the acidic dispersant (acidic resin) is represented by 100 mol %, the amount of the acid group is preferably 70 mol % or higher and more preferably substantially 100 mol %. The acid group in the acidic dispersant (acidic resin) is preferably a carboxyl group. An acid value of the acidic dispersant (acidic resin) is preferably 40 to 105 mgKOH/g, more preferably 50 to 105 mgKOH/g, and still more preferably 60 to 105 mgKOH/g.

In addition, the basic dispersant (basic resin) refers to a resin in which the amount of a basic group is more than the amount of an acid group. In a case where the sum of the amount of an acid group and the amount of a basic group in the basic dispersant (basic resin) is represented by 100 mol %, the amount of the basic group is preferably higher than 50 mol %. The basic group in the basic dispersant is preferably amine.

It is preferable that the resin A used as the dispersant further includes a repeating unit having an acid group. By the resin, which is used as the dispersant, including the repeating unit having an acid group, in a case where a pattern is formed using a photolithography method, the amount of residues formed in an underlayer of a pixel can be reduced.

It is preferable that the resin used as the dispersant is a graft copolymer. Since the graft copolymer has affinity to the solvent due to the graft chain, the pigment dispersibility and the dispersion stability over time are excellent. In addition, the composition has affinity to the curable compound or the like due to the presence of the graft chain. Therefore, formation of residues during alkali development can be suppressed. As the graft copolymer, a graft copolymer including a repeating unit represented by any one of the following Formulae (111) to (114) is preferably used.

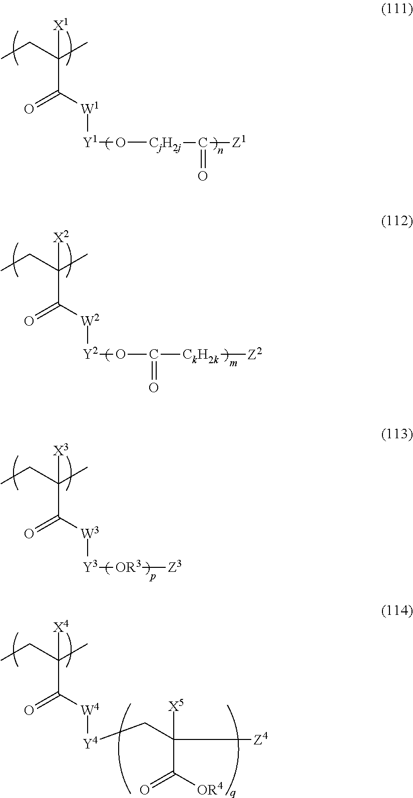

In Formulae (111) to (114), W¹, W², W³, and W⁴ each independently represent an oxygen atom or NH, X¹, X², X³, X⁴, and X⁵ each independently represent a hydrogen atom or a monovalent group, Y¹, Y², Y³, and Y⁴ each independently represent a divalent linking group, Z¹, Z², Z³, and Z⁴ each independently represent a monovalent group, R³ represents an alkylene group, R⁴ represents a hydrogen atom or a monovalent group, n, m, p, and q each independently represent an integer of 1 to 500, and j and k each independently represent an integer of 2 to 8. In Formula (113), in a case where p represents 2 to 500, a plurality of R³'s may be the same as or different from each other. In Formula (114), in a case where q represents 2 to 500, a plurality of X⁵'s and a plurality of R⁴'s may be the same as or different from each other.

The details of the graft copolymer can be found in the description of paragraphs “0025” to “0094” of JP2012-255128A, the content of which is incorporated herein by reference. In addition, specific examples of the graft copolymer include the following resins. The following resin may also be a resin having an acid group (alkali-soluble resin). Other examples of the graft copolymer include resins described in paragraphs “0072” to “0094” of JP2012-255128A, the content of which is incorporated herein by reference.

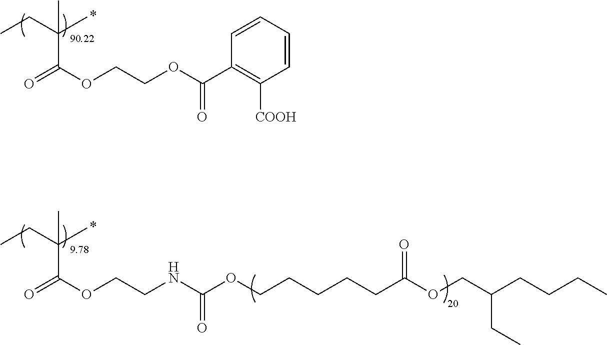

In addition, in the present invention, as the resin (dispersant), an oligoimine dispersant having a nitrogen atom at at least either a main chain or a side chain is also preferably used. As the oligoimine dispersant, a resin, which includes a structural unit having a partial structure X with a functional group (pKa: 14 or lower) and a side chain Y having 40 to 10000 atoms and has a basic nitrogen atom at at least either a main chain or a side chain, is preferable. The basic nitrogen atom is not particularly limited as long as it is a nitrogen atom exhibiting basicity. Examples of the oligoimine dispersant include a dispersant including a structural unit represented by the following Formula (I-1), a structural unit represented by the following Formula (I-2), and/or a structural unit represented by the following Formula (I-2a).

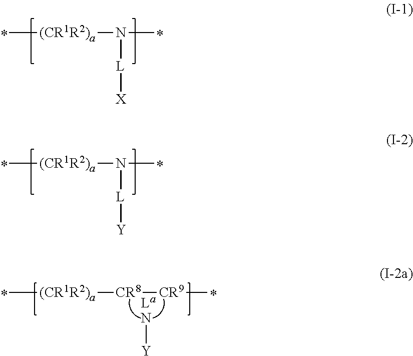

R¹ and R² each independently represent a hydrogen atom, a halogen atom, or an alkyl group (having preferably 1 to 6 carbon atoms). a's each independently represent an integer of 1 to 5. * represents a linking portion between structural units.

R⁸ and R⁹ represent the same group as that of R¹.

L represents a single bond, an alkylene group (having preferably 1 to 6 carbon atoms), an alkenylene group (having preferably 2 to 6 carbon atoms), an arylene group (having preferably 6 to 24 carbon atoms), an heteroarylene group (having preferably 1 to 6 carbon atoms), an imino group (having preferably 0 to 6 carbon atoms), an ether group, a thioether group, a carbonyl group, or a linking group of a combination of the above-described groups. Among these, a single bond or —CR⁵R⁶—NR⁷— (an imino group is present at the X or Y site) is preferable. Here, R⁵ and R⁶ each independently represent a hydrogen atom, a halogen atom, or an alkyl group (having preferably 1 to 6 carbon atoms). R⁷ represents a hydrogen atom or an alkyl group having 1 to 6 carbon atoms.

L^{a} is a structural unit which forms a ring structure with CR⁸CR⁹ and N, preferably a structural unit which forms a nonaromatic heterocycle having 3 to 7 carbon atoms with CR⁸CR⁹ and a carbon atom, more preferably a structural unit which forms a nonaromatic 5- to 7-membered heterocycle with CR⁸CR⁹ and N (nitrogen atom), still more preferably a structural unit which forms a nonaromatic 5-membered heterocycle with CR⁸CR⁹ and N, and even still more preferably a structural unit which forms pyrrolidine with CR⁸CR⁹ and N. This structural unit may have a substituent such as an alkyl group.

X represents a group having a functional group (pKa: 14 or lower).

Y represents a side chain having 40 to 10000 atoms.

The oligoimine dispersant may further include one or more copolymerization components selected from the group consisting of the structural units represented by Formulae (I-3), (I-4), and (I-5). By the oligoimine dispersant including the above-described structural units, the dispersibility of the pigment or the like can be further improved.

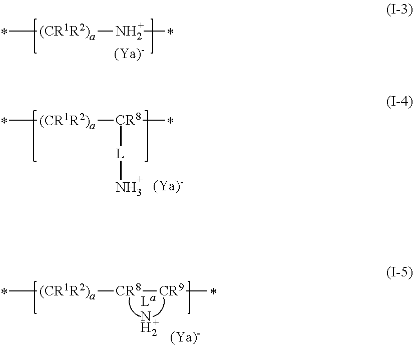

R¹, R², R⁸, R⁹, L, La, a, and * have the same definitions as R¹, R², R⁸, R⁹, L, La, a, and * in Formulae (I-1), (I-2), and (I-2a).

Ya represents a side chain having 40 to 10000 atoms which has an anionic group. The structural unit represented by Formula (I-3) can be formed by adding an oligomer or a polymer having a group, which reacts with amine to form a salt, to a resin having a primary or secondary amino group at a main chain such that they react with each other.

The oligoimine dispersant can be found in the description of paragraphs “0102” to “0166” of JP2012-255128A, the content of which is incorporated herein by reference. Specific examples of the oligoimine dispersant are as follows. The following resin may also be a resin having an acid group (alkali-soluble resin). In addition, as the oligoimine dispersant, a resin described in paragraphs “0168” to “0174” of JP2012-255128A can be used.

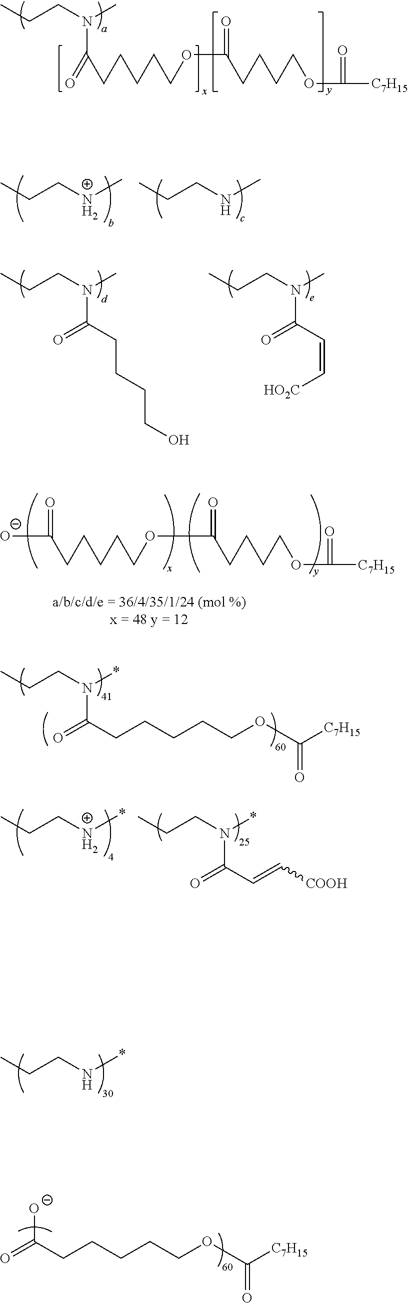

The dispersant is available as a commercially available product, and specific example thereof include Disperbyk-111 (manufactured by BYK Chemie). In addition, a pigment dispersant described in paragraphs “0041” to “0130” of JP2014-130338A can also be used, the content of which is incorporated herein by reference. In addition, the resin having an acid group or the like can also be used as a dispersant.

In the composition according to the embodiment of the present invention, the content of the resin is preferably 14 to 70 mass % with respect to the total solid content of the composition according to the embodiment of the present invention. The lower limit is preferably 17 mass % or higher and more preferably 20 mass % or higher. The upper limit is preferably 56 mass % or lower and more preferably 42 mass % or lower.

In the composition according to the embodiment of the present invention, the content of the resin having an acid group is preferably 14 to 70 mass % with respect to the total solid content of the composition according to the embodiment of the present invention. The lower limit is preferably 17 mass % or higher and more preferably 20 mass % or higher. The upper limit is preferably 56 mass % or lower and more preferably 42 mass % or lower.

In a case where the composition according to the embodiment of the present invention includes the radically polymerizable compound and the resin, a mass ratio radically polymerizable compound/resin of the radically polymerizable compound to the resin is preferably 0.4 to 1.4. The lower limit of the mass ratio is preferably 0.5 or higher and more preferably 0.6 or higher. The upper limit of the mass ratio is preferably 1.3 or lower and more preferably 1.2 or lower. In a case where the mass ratio is in the above-described range, a pattern having more excellent rectangularity can be formed.

In addition, in the composition according to the embodiment of the present invention, it is preferable that a mass ratio radically polymerizable compound/resin having an acid group of the radically polymerizable compound to the resin having an acid group is 0.4 to 1.4. The lower limit of the mass ratio is preferably 0.5 or higher and more preferably 0.6 or higher. The upper limit of the mass ratio is preferably 1.3 or lower and more preferably 1.2 or lower. In a case where the mass ratio is in the above-described range, a pattern having more excellent rectangularity can be formed.

<<Solvent>>

The composition according to the embodiment of the present invention may include a solvent. Examples of the solvent include an organic solvent. Basically, the solvent is not particularly limited as long as it satisfies the solubility of each component and the coating properties of the composition. However, it is preferable that the organic solvent is selected in consideration of the coating properties and safety of the composition.

Examples of the organic solvent include esters, ethers, ketones, and aromatic hydrocarbons. The details of the organic solvent can be found in paragraph “0223” of WO2015/166779A, the content of which is incorporated herein by reference. Specific examples of the organic solvent include dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, and propylene glycol methyl ether acetate. In the present invention, as the organic solvent, one kind may be used alone, or two or more kinds may be used in combination. In this case, it may be preferable that the content of the aromatic hydrocarbon (for example, benzene, toluene, xylene, or ethylbenzene) as the solvent is low (for example, 50 mass parts per million (ppm) or lower, 10 mass ppm or lower, or 1 mass ppm or lower with respect to the total mass of the organic solvent) in consideration of environmental aspects and the like.

In the present invention, a solvent having a low metal content is preferably used. For example, the metal content in the solvent is preferably 10 mass parts per billion (ppb) or lower. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method of removing impurities such as metal from the solvent include distillation (for example, molecular distillation or thin-film distillation) and filtering using a filter. The pore size of a filter used for the filtering is preferably 10 nm or less, more preferably 5 nm or less, and still more preferably 3 nm or less. As a material of the filter, polytetrafluoroethylene, polyethylene, or nylon is preferable.

The solvent may include an isomer (a compound having the same number of atoms and a different structure). In addition, the organic solvent may include only one isomer or a plurality of isomers.

In the present invention, as the organic solvent, an organic solvent containing 0.8 mmol/L or lower of a peroxide is preferable, and an organic solvent containing substantially no peroxide is more preferable.

The content of the solvent is preferably 10 to 90 mass %, more preferably 20 to 80 mass %, and still more preferably 25 to 75 mass % with respect to the total mass of the composition.

<<Polymerization Inhibitor>>

The composition according to the embodiment of the present invention may include a polymerization inhibitor. Examples of the polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), and N-nitrosophenylhydroxyamine salt (for example, an ammonium salt or a cerium (III) salt). Among these, p-methoxyphenol is preferable. The content of the polymerization inhibitor is preferably 0.01 to 5 mass % with respect to the total solid content of the composition.

<<<Surfactant>>>

The composition according to the embodiment of the present invention may include a surfactant from the viewpoint of further improving coating properties. As the surfactants, various surfactants such as a fluorine surfactant, a nonionic surfactant, a cationic surfactant, an anionic surfactant, or a silicone surfactant can be used.

By the composition according to the embodiment of the present invention containing a fluorine surfactant, liquid characteristics (for example, fluidity) of a coating solution prepared from the coloring composition are further improved, and the uniformity in coating thickness and liquid saving properties can be further improved. In a case where a film is formed using a coating solution prepared using the composition including a fluorine surfactant, the interfacial tension between a coated surface and the coating solution decreases, the wettability on the coated surface is improved, and the coating properties on the coated surface are improved. Therefore, a film having a uniform thickness with reduced unevenness in thickness can be formed more suitably.

The fluorine content in the fluorine surfactant is preferably 3 to 40 mass %, more preferably 5 to 30 mass %, and still more preferably 7 to 25 mass %. The fluorine surfactant in which the fluorine content is in the above-described range is effective from the viewpoints of the uniformity in the thickness of the coating film and liquid saving properties, and the solubility thereof in the composition is also excellent.

Specific examples of the fluorine surfactant include a surfactant described in paragraphs “0060” to “0064” of JP2014-041318A (paragraphs “0060” to “0064” of corresponding WO2014/017669A) and a surfactant described in paragraphs “0117” to “0132” of JP2011-132503A, the content of which is incorporated herein by reference. Examples of a commercially available product of the fluorine surfactant include: MEGAFACE F171, F172, F173, F176, F177, F141, F142, F143, F144, R30, F437, F475, F479, F482, F554, and F780 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC1068, SC-381, SC-383, S393, and KH-40 (all of which are manufactured by Asahi Glass Co., Ltd.); and PolyFox, PF636, PF656, PF6320, PF6520, and PF7002 (all of which are manufactured by OMNOVA Solutions Inc.).

In addition, as the fluorine surfactant, an acrylic compound in which, in a case where heat is applied to a molecular structure which has a functional group having a fluorine atom, the functional group having a fluorine atom is cut and a fluorine atom is volatilized can also be preferably used. Examples of the fluorine surfactant include MEGAFACE DS series (manufactured by DIC Corporation, The Chemical Daily, Feb. 22, 2016, Nikkei Business Daily, Feb. 23, 2016), for example, MEGAFACE DS-21.

As the fluorine surfactant, a block polymer can also be used. Examples of the block polymer include a compound described in JP2011-089090A. As the fluorine surfactant, a fluorine-containing polymer compound can be preferably used, the fluorine-containing polymer compound including: a repeating unit derived from a (meth)acrylate compound having a fluorine atom; and a repeating unit derived from a (meth)acrylate compound having 2 or more (preferably 5 or more) alkyleneoxy groups (preferably an ethyleneoxy group and a propyleneoxy group). For example, the following compound can also be used as the fluorine surfactant used in the present invention.

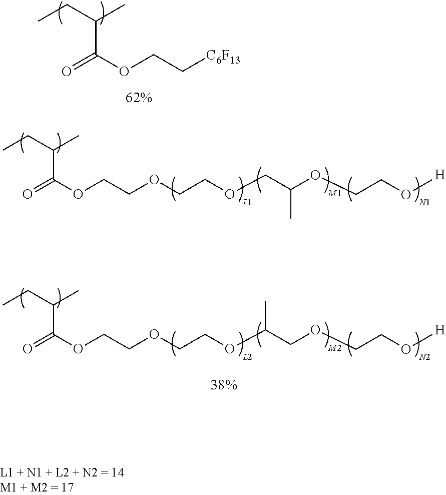

The weight-average molecular weight of the compound is preferably 3000 to 50000 and, for example, 14000. In the compound, “%” representing the proportion of a repeating unit is mass %.

In addition, as the fluorine surfactant, a fluorine-containing polymer having an ethylenically unsaturated group at a side chain can also be used. Specific examples include a compound described in paragraphs “0050” of “0090” and paragraphs “0289” to “0295” of JP2010-164965A, for example, MEGAFACE RS-101, RS-102, RS-718K, and RS-72-K manufactured by DIC Corporation. As the fluorine surfactant, a compound described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and sorbitan fatty acid esters (PLURONIC L10, L31, L61, L62, 10R5, 17R2, and 25R2 (manufactured by BASF SE) and TETRONIC 304, 701, 704, 901, 904, and 150R1 (manufactured by BASF SE)); SOLSPERSE 20000 (manufactured by Lubrication Technology Inc.); NCW-101, NCW-1001, and NCW-1002 (all of which are manufactured by Wako Pure Chemical Industries, Ltd.); PIONIN D-6112, D-6112-W, and D-6315 (all of which are manufactured by Takemoto Oil&Fat Co., Ltd.); and OLFINE E1010, SURFYNOL 104, 400, and 440 (all of which are manufactured by Nissin Chemical Co., Ltd.).

Examples of the cationic surfactant include an organosiloxane polymer KP341 (manufactured by Shin-Etsu Chemical Co., Ltd.), a (meth)acrylic acid (co)polymer POLYFLOW No. 75, No. 90, or No. 95 (manufactured by Kyoeisha Chemical Co., Ltd.), and W001 (manufactured by Yusho Co., Ltd.).

Examples of the anionic surfactant include W004, W005, and W017 (manufactured by Yusho Co., Ltd.), and SANDET BL (manufactured by Sanyo Chemical Industries Ltd.).

Examples of the silicone surfactant include: TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH3OPA, and TORAY SILICONE SH8400 (all of which are manufactured by Dow Coming Corporation); TSF-4440, TSF-4300, TSF-4445, TSF-4460, and TSF-4452 (all of which are manufactured by Momentive Performance Materials Inc.); KP341, KF6001, and KF6002 (all of which are manufactured by Shin-Etsu Chemical Co., Ltd.); and BYK307, BYK323, and BYK330 (all of which are manufactured by BYK-Chemie Japan K.K.).

The content of the surfactant is preferably 0.001 to 2.0 mass % and more preferably 0.005 to 1.0 mass % with respect to the total solid content of the composition. Among these surfactants, one kind may be used alone, or two or more kinds may be used in combination.

<<Silane Coupling Agent>>

The composition according to the embodiment of the present invention may include a silane coupling agent. In the present invention, the silane coupling agent is a different component from the curable compound. In the present invention, the silane coupling agent refers to a silane compound having a functional group other than a hydrolyzable group. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group. Among these, an alkoxy group is preferable. That is, it is preferable that the silane coupling agent is a compound having an alkoxysilyl group. In addition, it is preferable that the functional group other than a hydrolyzable group is a group which interacts with the resin or forms a bond with the resin to exhibit affinity. Examples of the functional group other than a hydrolyzable group include a vinyl group, a styryl group, a (meth)acryloyl group, a mercapto group, an epoxy group, an oxetanyl group, an amino group, an ureido group, a sulfide group, an isocyanate group, and a phenyl group. Among these, a (meth)acryloyl group or an epoxy group is preferable. Examples of the silane coupling agent include a compound described in paragraphs “0018” to “0036” of JP2009-288703A and a compound described in paragraphs “0056” to “0066” of JP2009-242604A, the content of which is incorporated herein by reference.

The content of the silane coupling agent is preferably 0.01 to 15.0 mass % and more preferably 0.05 to 10.0 mass % with respect to the total solid content of the composition. As the silane coupling agent, one kind may be used alone, or two or more kinds may be used. In a case where two or more silane coupling agents are used in combination, it is preferable that the total content of the two or more silane coupling agents is in the above-described range.

<<Other Components>>

Optionally, the composition according to the embodiment of the present invention may further include a sensitizer, a curing accelerator, a filler, a thermal curing accelerator, a thermal polymerization inhibitor, a plasticizer, an adhesion accelerator, and other auxiliary agents (for example, conductive particles, a filler, an antifoaming agent, a flame retardant, a leveling agent, a peeling accelerator, an antioxidant, an aromatic chemical, a surface tension adjuster, or a chain transfer agent). The details of these components can be found in paragraphs “0101” to “0104” and “0107” to “0109” of JP2008-250074A, the content of which is incorporated herein by reference. In addition, examples of the antioxidant include a phenol compound, a phosphite compound, and a thioether compound. As the antioxidant, a phenol compound having a molecular weight of 500 or higher, a phosphite compound having a molecular weight of 500 or higher, or a thioether compound having a molecular weight of 500 or higher is more preferable. Among these compounds, a mixture of two or more kinds may be used. As the phenol compound, any phenol compound which is known as a phenol antioxidant can be used. As the phenol compound, for example, a hindered phenol compound is preferable. In particular, a compound having a substituent at a position (ortho position) adjacent to a phenolic hydroxyl group is preferable. As the substituent, a substituted or unsubstituted alkyl group having 1 to 22 carbon atoms is preferable, and a methyl group, an ethyl group, a propionyl group, an isopropionyl group, a butyl group, an isobutyl group, a t-butyl group, a pentyl group, an isopentyl group, a t-pentyl group, a hexyl group, an octyl group, an isooctyl group, or a 2-ethylhexyl group is more preferable. In addition, as the antioxidant, a compound having a phenol group and a phosphite group in the same molecule is also preferable. In addition, as the antioxidant, a phosphorus antioxidant can also be preferably used. Examples of the phosphorus antioxidant include at least one compound selected from the group consisting of tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-t-butyldibenzo[d,f][1,3,2]dioxaphosphepin-2-yl)oxy]ethyl]amine, and ethyl bis(2,4-di-t-butyl-6-methylphenyl)phosphite. These antioxidants are available as a commercially available product. Examples of the commercially available product include ADEKA STAB AO-20, ADEKA STAB AO-30, ADEKA STAB AO-40, ADEKA STAB AO-50, ADEKA STAB AO-50F, ADEKA STAB AO-60, ADEKA STAB AO-60G, ADEKA STAB AO-80, and ADEKA STAB AO-330 (manufactured by Adeka Corporation). The content of the antioxidant is preferably 0.01 to 20 mass % and more preferably 0.3 to 15 mass % with respect to the mass of the total solid content of the composition. As the antioxidant, one kind may be used alone, or two or more kinds may be used. In a case where two or more antioxidants are used in combination, it is preferable that the total content of the two or more antioxidants is in the above-described range.

For example, in a case where a film is formed by coating, the viscosity (23° C.) of the composition according to the embodiment of the present invention is preferably in a range of 1 to 3000 mPa·s. The lower limit is preferably 3 mPa·s or higher and more preferably 5 mPa·s or higher. The upper limit is preferably 2000 mPa·s or lower and more preferably 1000 mPa·s or lower.

The composition according to the embodiment of the present invention can be preferably used for forming a near infrared cut filter, an infrared transmitting filter, or the like.

<Method of Preparing Composition>

The composition according to the embodiment of the present invention can be prepared by mixing the above-described components with each other.

During the preparation of the composition, the respective components may be mixed with each other collectively, or may be mixed with each other sequentially after dissolved and dispersed in an organic solvent. In addition, during mixing, the order of addition or working conditions are not particularly limited. For example, all the components may be dissolved or dispersed in an organic solvent at the same time to prepare the composition. Optionally, two or more solutions or dispersions to which the respective components are appropriately added may be prepared, and the solutions or dispersions may be mixed with each other during use (during application) to prepare the composition.

In addition, it is preferable that a method of preparing the composition according to the embodiment of the present invention includes a process of dispersing particles of the pigment and the like. Examples of a mechanical force used for dispersing the particles in the process of dispersing the particles include compression, squeezing, impact, shearing, and cavitation. Specific examples of the process include a beads mill, a sand mill, a roll mill, a ball mill, a paint shaker, a Microfluidizer, a high-speed impeller, a sand grinder, a project mixer, high-pressure wet atomization, and ultrasonic dispersion. During the pulverization of the particles using a sand mill (beads mill), it is preferable that the process is performed under conditions for increasing the pulverization efficiency, for example, by using beads having a small size and increasing the filling rate of the beads. In addition, it is preferable that rough particles are removed by filtering, centrifugal separation, and the like. In addition, as the process and the disperser for dispersing the particles, a process and a disperser described in “Complete Works of Dispersion Technology, Johokiko Co., Ltd., Jul. 15, 2005”, “Dispersion Technique focusing on Suspension (Solid/Liquid Dispersion) and Practical Industrial Application, Comprehensive Reference List, Publishing Department of Management Development Center, Oct. 10, 1978”, and paragraph “0022” JP2015-157893A can be suitably used. In addition, in the process of dispersing the particles, particles may be refined in a salt milling step. A material, a device, process conditions, and the like used in the salt milling step can be found in, for example, JP2015-194521A and JP2012-046629A.

During the preparation of the composition, it is preferable that the composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is suitably about 0.01 to 7.0 μm and is preferably about 0.01 to 3.0 μm and more preferably about 0.05 to 0.5 μm. In a case where the pore size of the filter is in the above-described range, fine foreign matter can be reliably removed. In addition, it is preferable that a fibrous filter material is used. Examples of the fibrous filter material include polypropylene fiber, nylon fiber, and glass fiber. Specific examples include a filter cartridge of SBP type series (for example, SBP008), TPR type series (for example, TPR002 or TPR005), and SHPX type series (for example, SHPX003) all of which are manufactured by Roki Techno Co., Ltd.

In a case where a filter is used, a combination of different filters (for example, a first filter and a second filter) may be used. At this time, the filtering using each of the filters may be performed once, or twice or more.

In addition, a combination of filters having different pore sizes in the above-described range may be used. Here, the pore size of the filter can refer to a nominal value of a manufacturer of the filter. A commercially available filter can be selected from various filters manufactured by Pall Corporation (for example, DFA4201NIEY), Toyo Roshi Kaisha, Ltd., Entegris Japan Co., Ltd. (former Mykrolis Corporation), or Kits Microfilter Corporation.

The second filter may be formed of the same material as that of the first filter. In addition, the filtering using the first filter may be performed only on the dispersion, and the filtering using the second filter may be performed on a mixture of the dispersion and other components.

<Cured Film>

Next, a cured film according to the embodiment of the present invention will be described. The cured film according to the embodiment of the present invention is formed by curing the above-described composition (photosensitive composition) according to the embodiment of the present invention. The cured film according to the embodiment of the present invention has excellent infrared shielding properties and visible transparency, and thus can be preferably used as a near infrared cut filter. In addition, the cured film according to the embodiment of the present invention can also be used as a heat ray shielding filter or an infrared transmitting filter. In addition, the cured film according to the embodiment of the present invention may be used in a state where it is laminated on a support, or the cured film according to the embodiment of the present invention may be peeled off from a support.

The thickness of the cured film according to the embodiment of the present invention can be adjusted according to the purpose. The thickness of the cured film is preferably 20 μm or less, more preferably 10 μm or less, and still more preferably 5 μm or less. For example, the lower limit of the thickness is preferably 0.1 μm or more, more preferably 0.2 μm or more, and still more preferably 0.3 μm or more.

The cured film according to the embodiment of the present invention has an absorption maximum preferably in a wavelength range of 700 to 1000 nm, more preferably in a wavelength range of 720 to 980 nm, and more preferably in a wavelength range of 740 to 960 nm. In addition, a ratio absorbance Amax/absorbance A550 of an absorbance Amax at the absorption maximum to an absorbance A550 at a wavelength of 550 nm is preferably 50 to 500, more preferably 70 to 450, and still more preferably 100 to 400.

It is preferable that the cured film according to the embodiment of the present invention and a near infrared cut filter described below satisfy at least one of the following conditions (1) to (4), it is more preferable that the cured film according to the embodiment of the present invention and the near infrared cut filter satisfy all the following conditions (1) to (4).

(1) A transmittance at a wavelength of 400 nm is preferably 70% or higher, more preferably 80% or higher, still more preferably 85% or higher, and even still more preferably 90% or higher

(2) A transmittance at a wavelength of 500 nm is preferably 70% or higher, more preferably 80% or higher, still more preferably 90% or higher, and even still more preferably 95% or higher

(3) A transmittance at a wavelength of 600 nm is preferably 70% or higher, more preferably 80% or higher, still more preferably 90% or higher, and even still more preferably 95% or higher

(4) A transmittance at a wavelength of 650 nm is preferably 70% or higher, more preferably 80% or higher, still more preferably 90% or higher, and even still more preferably 95% or higher

A transmittance of the cured film according to the embodiment of the present invention and the near infrared cut filter described below having a thickness of 20 μm or less in the entire wavelength range of 400 to 650 nm is preferably 70% or higher, more preferably 80% or higher, and still more preferably 90% or higher. In addition, a transmittance at at least one point in a wavelength range of 700 to 1000 nm is preferably 20% or lower, more preferably 15% or lower, and still more preferably 10% or lower.

The cured film according to the embodiment of the present invention can be used in combination with a color filter that includes a chromatic colorant. The color filter can be manufactured using a photosensitive coloring composition including a chromatic colorant. Examples of the chromatic colorant include the chromatic colorants described regarding the composition according to the embodiment of the present invention. The photosensitive coloring composition may further include, for example, a resin, a curable compound, a photoinitiator, a surfactant, an organic solvent, a polymerization inhibitor, and an ultraviolet absorber. In more detail, for example, the materials described above regarding the photosensitive composition according to the embodiment of the present invention can be used. In addition, the cured film according to the embodiment of the present invention may have not only a function as a near infrared cut filter but also a function as a color filter by including a chromatic colorant.

The cured film according to the embodiment of the present invention can be used in various devices including a solid image pickup element such as a charge coupled device (CCD) or a complementary metal-oxide semiconductor (CMOS), an infrared sensor, or an image display device.

<Optical Filter>

Next, an optical filter according to the embodiment of the present invention will be described. The optical filter according to the embodiment of the present invention includes the cured film according to the embodiment of the present invention. The optical filter can be preferably used as a near infrared cut filter or an infrared transmitting filter. In addition, the optical filter can also be used as a heat ray shielding filter. In the present invention, “near infrared cut filter” refers to a filter that allows transmission of light (visible light) in the visible range and shields at least a part of light (near infrared light) in the near infrared range. The near infrared cut filter may be a filter that allows transmission of light in the entire wavelength range of the visible range, or may be a filter that allows transmission of light in a specific wavelength range of the visible range and shields light in another specific wavelength range of the visible range. In addition, in the present invention, a color filter refers to a filter that allows transmission of light in a specific wavelength range of the visible range and shields light in another specific wavelength range of the visible range. In addition, in the present invention, “infrared transmitting filter” refers to a filter that shields visible light and allows transmission of at least a part of near infrared light.

In a case where the optical filter according to the embodiment of the present invention is used as an infrared transmitting filter, examples of the infrared transmitting filter include a filter that shields visible light and allows transmission of light in a wavelength range of 900 nm or longer. In a case where the optical filter according to the embodiment of the present invention is used as an infrared transmitting filter, it is preferable that the optical filter is a filter in which a layer including the coloring material that shields visible light is separately present on the cured film according to the embodiment of the present invention (layer formed of the composition according to the embodiment of the present invention).

In the optical filter, the thickness of the cured film according to the embodiment of the present invention (layer formed of the composition) can be appropriately adjusted according to the purpose. The thickness is preferably 20 μm or less, more preferably 10 μm or less, and still more preferably 5 μm or less. For example, the lower limit is preferably 0.1 μm or more, more preferably 0.2 μm or more, and still more preferably 0.3 μm or more.

In a case where the optical filter according to the embodiment of the present invention is used as a near infrared cut filter, the optical filter may further include, for example, a layer containing copper, a dielectric multi-layer film, or an ultraviolet absorbing layer in addition to the cured film according to the embodiment of the present invention. By further including the layer containing copper and/or the dielectric multi-layer film, the near infrared cut filter having a viewing angle and excellent infrared shielding properties can be easily obtained. In addition, by including the ultraviolet absorbing layer, the near infrared cut filter having excellent ultraviolet shielding properties can be obtained. The details of the ultraviolet absorbing layer can be found in the description of an absorbing layer described in paragraphs “0040” to “0070” and paragraphs “0119” to “0145” of WO2015/099060, the content of which is incorporated herein by reference. The details of the dielectric multi-layer film can be found in paragraphs “0255” to “0259” of JP2014-041318A As the layer containing copper, a glass substrate (copper-containing glass substrate) formed of glass containing copper, or a layer (copper complex-containing layer) containing a copper complex may also be used. Examples of the copper-containing glass substrate include a phosphate glass including copper and a fluorophosphate glass including copper. Examples of a commercially available product of the copper-containing glass include NF-50 (manufactured by AGC Techno Glass Co., Ltd.), BG-60 and BG-61 (both of which are manufactured by Schott A G), and CD5000 (manufactured by Hoya Corporation). Examples of the copper complex-containing layer include a layer that is formed using a composition including a copper complex.

The optical filter according to the embodiment of the present invention can be used in various devices including a solid image pickup element such as a charge coupled device (CCD) or a complementary metal-oxide semiconductor (CMOS), an infrared sensor, or an image display device.

In addition, it is also preferable that the optical filter according to the present invention includes a pixel of the cured film according to the embodiment of the present invention and a pixel selected from the group consisting of a red pixel, a green pixel, a blue pixel, a magenta pixel, a yellow pixel, a cyan pixel, a black pixel, and an achromatic pixel.

<Laminate>

In addition, a laminate according to the embodiment of the present invention includes: the cured film according to the embodiment of the present invention; and a color filter that includes a chromatic colorant. In the laminate according to the embodiment of the present invention, the cured film according to the embodiment of the present invention and the color filter may be or may not be adjacent to the color filter in the thickness direction. In a case where the cured film according to the embodiment of the present invention is not adjacent to the color filter in the thickness direction, the cured film according to the embodiment of the present invention may be formed on another support other than a support on which the color filter is formed, or another member (for example, a microlens or a planarizing layer) constituting a solid image pickup element may be interposed between the cured film according to the embodiment of the present invention and the color filter.

<Pattern Forming Method>

Next, a pattern forming method using the composition according to the embodiment of the present invention will be described. The pattern forming method includes: a step of forming a composition layer on a support using the composition according to the embodiment of the present invention; and a step of forming a pattern on the composition layer using a photolithography method. It is preferable that the pattern forming method according to the embodiment of the present invention includes: a step of forming a composition layer on a support using the composition according to the embodiment of the present invention; a step of exposing the composition layer in a pattern shape; and a step of forming a pattern by removing a non-exposed portion by development. Optionally, the pattern formation further includes: a step (pre-baking step) of baking the composition layer before exposure; and a step (post-baking step) of baking the developed pattern. Hereinafter, the respective steps will be described.

<<Step of Forming Composition Layer>>

In the step of forming a composition layer, a composition layer is formed on a support using the composition according to the embodiment of the present invention.

As the support, for example, a substrate for a solid image pickup element obtained by providing a solid image pickup element (light-receiving element) such as CCD or CMOS on a substrate (for example, a silicon substrate) can be used. As a method of applying the composition to the support, a well-known method can be used. Examples of the well-known method include: a drop casting method; a slit coating method; a spray coating method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using metal or the like; and a nanoimprint lithography method. The application method using an ink jet method is not particularly limited, and examples thereof include a method (in particular, pp. 115 to 133) described in “Extension of Use of Ink Jet—Infinite Possibilities in Patent—” (February, 2005, S. B. Research Co., Ltd.) and methods described in JP2003-262716A, JP2003-185831A, JP2003-261827A, JP2012-126830A, and JP2006-169325A.

The composition layer formed on the support may be dried (pre-baked). The pre-baking temperature is preferably 150° C. or lower, more preferably 120° C. or lower, and still more preferably 110° C. or lower. The lower limit is, for example, 50° C. or higher or 80° C. or higher. By setting the pre-baking temperature to be 150° C. or lower, the characteristics can be effectively maintained, for example, even in a case where a photoelectric conversion film of an image sensor is formed of an organic material.

The pre-baking time is preferably 10 to 3000 seconds, more preferably 40 to 2500 seconds, and still more preferably 80 to 220 seconds. Drying can be performed using a hot plate, an oven, or the like.

<<Exposure Step>>

Next, the composition layer is exposed in a pattern shape (exposure step). For example, the composition layer can be exposed in a pattern shape using an exposure device such as a stepper through a mask having a predetermined mask pattern. As a result, an exposed portion can be cured.

As radiation (light) used during the exposure, in particular, ultraviolet rays such as g-rays or i-rays are preferable, and i-rays are more preferable. The irradiation dose (exposure dose) is preferably 0.03 to 2.5 J/cm², more preferably 0.05 to 1.0 J/cm², and most preferably 0.08 to 0.5 J/cm².

The oxygen concentration during exposure can be appropriately selected. The exposure may be performed not only in air but also in a low-oxygen atmosphere having an oxygen concentration of 19 vol % or lower (for example, 15 vol %, 5 vol %, or substantially 0 vol %) or in a high-oxygen atmosphere having an oxygen concentration of higher than 21 vol % (for example, 22 vol %, 30 vol %, or 50 vol %). In addition, the exposure illuminance can be appropriately set and typically can be selected in a range of 1000 W/m² to 100000 W/m² (for example, 5000 W/m², 15000 W/m², or 35000 W/m²). Conditions of the oxygen concentration and conditions of the exposure illuminance may be appropriately combined. For example, conditions are oxygen concentration: 10 vol % and illuminance: 10000 W/m², or oxygen concentration: 35 vol % and illuminance: 20000 W/m².

<<Development Step>>

Next, a pattern is formed by removing a non-exposed portion by development. The non-exposed portion can be removed by development using a developer. As a result, a non-exposed portion of the composition layer in the exposure step is eluted into the developer, and only the photocured portion remains on the support.

As the developer, any developer can be used as long as the composition layer in the non-cured portion is soluble therein. Specifically, an organic solvent or an alkaline aqueous solution can be used. As the developer, a developer which does not cause damages to a solid image pickup element as a substrate, a circuit or the like is preferable, and an alkaline aqueous solution is more preferable. For example, the temperature of the developer is preferably 20° C. to 30° C. The development time is preferably 20 to 180 seconds. In addition, in order to further improve residue removing properties, a step of shaking the developer off per 60 seconds and supplying a new developer may be repeated multiple times.

Examples of the organic solvent include the organic solvents described above regarding the composition according to the embodiment of the present invention.

Examples of the alkaline agent used as the alkaline aqueous solution include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, benzyltrimethylammonium hydroxide, dimethyl bis(2-hydroxyethyl)ammonium hydroxide, choline, pyrrole, piperidine, or 1,8-diazabicyclo[5.4.0]-7-undecene; and an inorganic alkaline compound such as sodium hydroxide, potassium hydroxide, sodium carbonate, sodium bicarbonate, sodium silicate, or sodium metasilicate. As the alkaline aqueous solution, an alkaline aqueous solution in which the above alkaline agent is diluted with pure water is preferably used. A concentration of the alkaline agent in the alkaline aqueous solution is preferably 0.001 to 10 mass % and more preferably 0.01 to 1 mass %. In addition, a surfactant may be used in the alkaline aqueous solution. Examples of the surfactant include the surfactants described above regarding the composition according to the embodiment of the present invention. Among these, a nonionic surfactant is preferable. In a case where the alkaline aqueous solution is used for development, it is preferable that the layer is rinsed with pure water after development.

After development, it is preferable that the film is dried and then heated (post-baking). Post-baking is a heat treatment which is performed after development to completely cure the film. In a case where post-baking is performed, for example, the post-baking temperature is preferably 180° C. to 260° C. The lower limit is preferably 180° C. or higher, more preferably 190° C. or higher, and still more preferably 200° C. or higher. The upper limit is preferably 260° C. or lower, more preferably 240° C. or lower, and still more preferably 220° C. or lower. The film after the development is post-baked continuously or batchwise using heating means such as a hot plate, a convection oven (hot air circulation dryer), a high-frequency heater under the above-described temperature conditions.

The pattern forming method according to the embodiment of the present invention further includes:

a step of forming a pattern (pixel) of a cured film formed of the composition according to the embodiment of the present invention using the above-described method and subsequently forming a photosensitive coloring composition layer on the obtained pattern using a photosensitive coloring composition including a chromatic colorant; and

a step of forming a pattern by exposing the photosensitive coloring composition layer from the photosensitive coloring composition layer side and subsequently developing the exposed photosensitive coloring composition layer. According to this configuration, a laminate in which the pattern (colored pixel) of the coloring cured film is formed on the pattern (pixel) of the cured film formed of the composition according to the embodiment of the present invention can be formed. In addition, in the cured film that is formed using the composition according to the embodiment of the present invention, the residual amount of the ultraviolet absorber is small. Therefore, reflected light or scattered light from a support or the cured film can also be used for exposure during the formation of the coloring cured film, and the sensitivity during the formation of the coloring cured film can be improved.

In the step of forming the photosensitive coloring composition layer, the photosensitive coloring composition layer can be formed by applying the photosensitive coloring composition to the pattern (pixel) of the cured film formed of the composition according to the embodiment of the present invention. Examples of a method of applying the photosensitive coloring composition include the methods described above regarding the step of forming the composition layer.

Examples of an exposure method and a development method of the photosensitive coloring composition layer include the methods described above regarding the exposure step and the development step. A heating treatment (post-baking) may be further performed on the developed photosensitive coloring composition layer. For example, the post-baking temperature is preferably 180° C. to 260° C. The lower limit is preferably 180° C. or higher, more preferably 190° C. or higher, and still more preferably 200° C. or higher. The upper limit is preferably 260° C. or lower, more preferably 240° C. or lower, and still more preferably 220° C. or lower.

<Solid Image Pickup Element>

A solid image pickup element according to the embodiment of the present invention includes the cured film according to the embodiment of the present invention. The configuration of the solid image pickup element according to the embodiment of the present invention is not particularly limited as long as it includes the cured film according to the embodiment of the present invention and functions as a solid image pickup element. For example, the following configuration can be adopted.

The solid image pickup element includes plural photodiodes and transfers electrodes on the support, the photodiodes constituting a light receiving area of the solid image pickup element, and the transfer electrode being formed of polysilicon or the like. In the solid image pickup element, a light shielding film formed of tungsten or the like which has openings through only light receiving sections of the photodiodes is provided on the photodiodes and the transfer electrodes, a device protective film formed of silicon nitride or the like is formed on the light shielding film so as to cover the entire surface of the light shielding film and the light receiving sections of the photodiodes, and the film according to the embodiment of the present invention is formed on the device protective film. Further, a configuration in which light collecting means (for example, a microlens; hereinafter, the same shall be applied) is provided above the device protective film and below the cured film according to the present invention (on a side thereof close the support), or a configuration in which light collecting means is provided on the cured film according to the present invention may be adopted. In addition, the color filter may have a structure in which a cured film which forms each pixel is embedded in a space which is partitioned in, for example, a lattice shape by a partition wall. In this case, it is preferable that the partition wall has a low refractive index with respect to each pixel. Examples of an imaging device having such a structure include a device described in JP2012-227478A and JP2014-179577A.

<Image Display Device>

The cured film according to the embodiment of the present invention can also be used in an image display device such as a liquid crystal display device or an organic electroluminescence (organic EL) display device. For example, the cured film according to the embodiment of the present invention can be used for the purpose of shielding infrared light included in light emitted from a backlight (for example, a white light emitting diode (white LED)) of an image display device to prevent a malfunction of a peripheral device, or for the purpose of forming an infrared pixel in addition to the respective colored pixels.

The definition and details of the image display device can be found in, for example, “Electronic Display Device (by Akiya Sasaki, Kogyo Chosakai Publishing Co., Ltd., 1990)” or “Display Device (Sumiaki Ibuki, Sangyo Tosho Co., Ltd.). In addition, the details of a liquid crystal display device can be found in, for example, “Next-Generation Liquid Crystal Display Techniques (Edited by Tatsuo Uchida, Kogyo Chosakai Publishing Co., Ltd., 1994)”. The liquid crystal display device to which the present invention is applicable is not particularly limited. For example, the present invention is applicable to various liquid crystal display devices described in “Next-Generation Liquid Crystal Display Techniques”.

The image display device may include a white organic EL element. It is preferable that the white organic EL element has a tandem structure. The tandem structure of the organic EL element is described in, for example, JP2003-045676A, or pp. 326-328 of “Forefront of Organic EL Technology Development -Know-How Collection of High Brightness, High Precision, and Long Life” (Technical Information Institute, 2008). It is preferable that a spectrum of white light emitted from the organic EL element has high maximum emission peaks in a blue range (430 nm to 485 nm), a green range (530 nm to 580 nm), and a yellow range (580 nm to 620 nm). It is more preferable that the spectrum has a maximum emission peak in a red range (650 nm to 700 nm) in addition to the above-described emission peaks.

<Infrared Sensor>

An infrared sensor according to the embodiment of the present invention includes the cured film according to the embodiment of the present invention. The configuration of the infrared sensor according to the embodiment of the present invention is not particularly limited as long as it includes the cured film according to the embodiment of the present invention and functions as an infrared sensor.

Hereinafter, an embodiment of the infrared sensor according to the embodiment of the present invention will be described using the drawings.

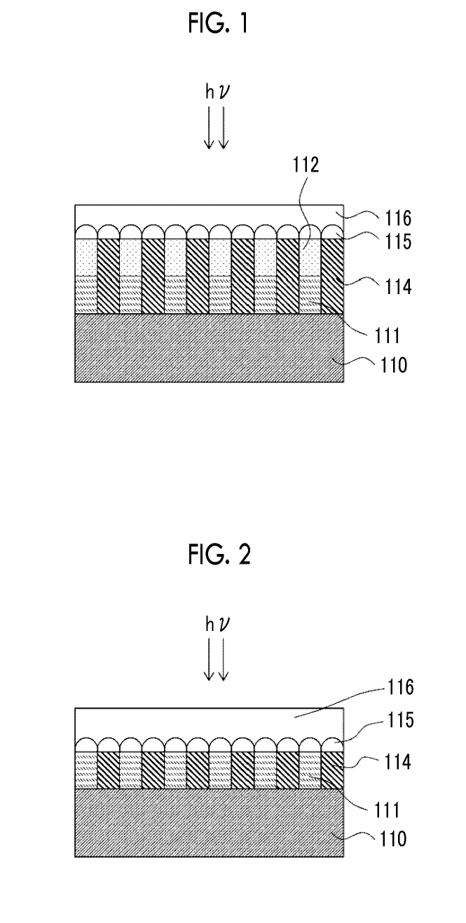

In FIG. 1, reference numeral 110 represents a solid image pickup element. In an imaging region provided on a solid image pickup element 110, near infrared cut filters 111 and infrared transmitting filters 114 are provided. In addition, color filters 112 are laminated on the near infrared cut filters 111. Microlenses 115 are disposed on an incidence ray hv side of the color filters 112 and the infrared transmitting filters 114. A planarizing layer 116 is formed so as to cover the microlenses 115.

The near infrared cut filters 111 are filters that allow light in a visible range and shield light in a near infrared range. Spectral characteristics of the near infrared cut filters 111 can be selected depending on the emission wavelength of an infrared light emitting diode (infrared LED) to be used. The near infrared cut filter 111 can be formed using the composition according to the embodiment of the present invention.

The color filters 112 are not particularly limited as long as pixels which allow transmission of light having a specific wavelength in the visible range and absorbs the light are formed therein, and well-known color filters of the related art for forming a pixel can be used. For example, pixels of red (R), green (G), and blue (B) are formed in the color filters. For example, the details of the color filters can be found in paragraphs “0214” to “0263” of JP2014-043556A, the content of which is incorporated herein by reference.

Characteristics of the infrared transmitting filters 114 can be selected depending on the emission wavelength of the infrared LED to be used. For example, in a case where the emission wavelength of the infrared LED is 850 nm, a maximum value of a light transmittance of the infrared transmitting filter 114 in the thickness direction of the film in a wavelength range of 400 to 650 nm is preferably 30% or lower, more preferably 20% or lower, still more preferably 10% or lower and even still more preferably 0.1% or lower. It is preferable that the transmittance satisfies the above-described conditions in the entire wavelength range of 400 to 650 nm. The maximum value of the light transmittance in a wavelength range of 400 to 650 nm is typically 0.1% or higher.

A minimum value of a light transmittance of the infrared transmitting filter 114 in the thickness direction of the film in a wavelength range of 800 nm or longer (preferably 800 to 1300 nm) is preferably 70% or higher, more preferably 80% or higher, and still more preferably 90% or higher. It is preferable that the transmittance satisfies the above-described conditions in at least a part of a wavelength range of 800 nm or longer, and it is more preferable that the transmittance satisfies the above-described conditions at a wavelength corresponding to the emission wavelength of the infrared LED. The minimum value of the light transmittance in a wavelength range of 900 to 1300 nm is typically 99.9% or lower.

The thickness of the infrared transmitting filter 114 is preferably 100 μm or less, more preferably 15 μm or less, still more preferably 5 μm or less, and even still more preferably 1 μm or less. The lower limit value is preferably 0.1 μm. In a case where the thickness is in the above-described range, the film can satisfy the above-described spectral characteristics.

A method of measuring the spectral characteristics, the thickness, and the like of the infrared transmitting filter 114 is as follows.

The thickness is obtained by measuring the thickness of the dried substrate including the film using a stylus surface profilometer (DEKTAK 150, manufactured by ULVAC Inc.).

The spectral characteristics of the film are values obtained by measuring the transmittance in a wavelength range of 300 to 1300 nm using an ultraviolet-visible-near infrared spectrophotometer (U-4100, manufactured by Hitachi High-Technologies Corporation).

In addition, for example, in a case where the emission wavelength of the infrared LED is 940 nm, it is preferable that a maximum value of a light transmittance of the infrared transmitting filter 114 in a thickness direction in a wavelength range of 450 to 650 nm is 20% or lower, that a light transmittance of the infrared transmitting filter 114 in the thickness direction at a wavelength of 835 nm is 20% or lower, and that a minimum value of a light transmittance of the infrared transmitting filter 114 in the thickness direction in a wavelength range of 1000 to 1300 nm is 70% or higher.

FIG. 2 is a diagram showing another embodiment of the infrared sensor. The same members as those in FIG. 1 are represented by the same reference numerals, and the description thereof will not be repeated. The infrared sensor shown in FIG. 2 has the same configuration as that of FIG. 1, except that it does not include the color filters 112. Examples

Hereinafter, the present invention will be described in detail using examples. Materials, used amounts, ratios, treatment details, treatment procedures, and the like shown in the following examples can be appropriately changed within a range not departing from the scope of the present invention. Accordingly, the scope of the present invention is not limited to the following specific examples. Unless specified otherwise, “part(s)” and “%” represent “part(s) by mass” and “mass %”.

<Measurement of Loss Percentage of Ultraviolet Absorber After Heating>

2 mg of an ultraviolet absorber was weighed on an aluminum pan and was set on a theimogravimetric analyzer (device name: TGA-Q500, manufactured by TA Instrument Inc.). Nitrogen gas is caused to flow through the inside of the device at a flow rate of 60 mL/min. In a nitrogen gas atmosphere, the ultraviolet absorber was heated from 25° C. to 100° C. at a temperature increase rate of 10° C./min. The ultraviolet absorber was held at 100° C. for 30 minute, was heated to 220° C. at a temperature increase rate of 10° C./min, and then was held at 220° C. for 30 minutes. In a case where the ultraviolet absorber was held at 100° C. for 30 minutes, the average value of the mass of the ultraviolet absorber in a period from the start of the holding to 24 to 29 minutes was set as a reference value of the mass of the ultraviolet absorber, the mass of the ultraviolet absorber at 150° C. and the mass of the ultraviolet absorber after holding at 220° C. for 30 minutes were measured, and the mass loss percentage was calculated based on the following expression.

Mass Loss Percentage (%) at 150° C.=100−(Mass of Ultraviolet Absorber at 150° C./Reference Value of Mass of Ultraviolet Absorber)×100

Mass Loss Percentage (%) at 220° C.=100−(Mass of Ultraviolet Absorber after Holding at 220° C. for 30 Minutes/Reference Value of Mass of Ultraviolet Absorber)×100

<Measurement of Absorption Maximum, Absorbance Ratio, and Molar Absorption Coefficient at Wavelength of 365 nm of Ultraviolet Absorber>

The ultraviolet absorber was mixed with dichloromethane (manufactured by Wako Pure Chemical Industries, Ltd.) to prepare an ultraviolet absorber solution. At this time, the concentration of the ultraviolet absorber was appropriately adjusted such that the absorbance at an absorption maximum was 1 to 0.8. The prepared ultraviolet absorber solution was put into a 1 cmx 1 cm quartz glass cell, the absorbance was measured using an ultraviolet-visible-near infrared spectrophotometer (U-4100, manufactured by Hitachi High-Technologies Corporation), and an absorbance ratio A365/A400 of an absorbance A365 at a wavelength of 365 nm to an absorbance A400 at a wavelength of 400 nm was obtained. In addition, a molar absorption coefficient at a wavelength of 365 nm was calculated based on the following expression.

Molar Absorption Coefficient−(Absorbance of Ultraviolet Absorber Solution at 365 nm)/(Volume Molar Concentration of Ultraviolet Absorber Solution)

TABLE 1

| | Mass Loss | | | | Molar Absorption |
|---|---|---|---|---|---|
| | Percentage (%) | | Absorbance | Absorption | Coefficient |
| | | 220° C. | Ratio | Ratio | (×10⁴L · mol⁻¹ · |
| | 150° C. | 30 min | A365/A400 | (nm) | cm⁻¹) |
| UV1 | 0 | 40 | 0.14 | 375 | 6.72 |
| UV2 | 0 | 93 | 0.09 | 370 | 5.36 |
| UV3 | 0 | 90 | 0.09 | 370 | 6.38 |
| UV4 | 0 | 95 | 0.07 | 365 | 5.06 |
| UV5 | 1 | 98 | 0.56 | 380 | 4.97 |
| UV6 | 1 | 35 | 0.08 | 360 | 3.67 |
| UV7 | 0 | 0 | 0.02 | 355 | 3.41 |
| UV8 | 7 | 93 | 0.004 | 345 | 1.61 |

UV1 to UV6: compounds having the following structures

UV7: TINUVIN 460 (manufactured by BASF SE)

UV8: TINUVIN PS (manufactured by BASF SE)

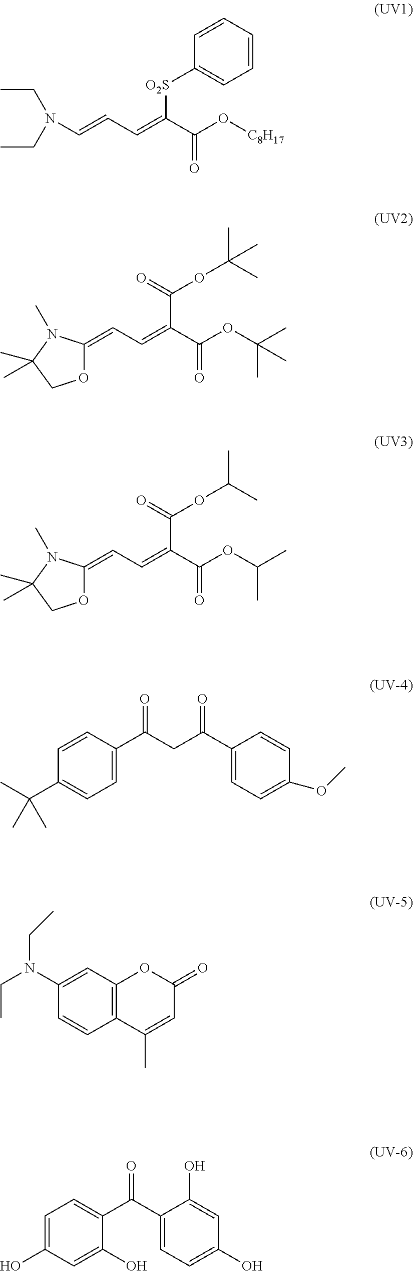

<Preparation of Photosensitive Composition>

Raw materials shown in the following tables were mixed with each other to prepare a photosensitive composition. In the photosensitive composition in which a dispersion was used as a raw material, the dispersion was prepared as follows.

An near infrared absorber, a pigment derivative, a dispersant, and a solvent described in “Dispersion” of the following tables were mixed with each other in part(s) by mass shown in “Dispersion” of the following tables, 230 parts by mass of zirconia beads having a diameter of 0.3 mm was further added thereto, the mixture was dispersed using a paint shaker for 5 hours, and the beads were separated by filtration. As a result, a dispersion was manufactured.

TABLE 2

Dispersant

| | Near Infrared Absorber | | Pigment Derivative | | Dispersant | | Solvent | | Near Infrared Absorber | | Resin | | Curable Compound | |
|---|---|---|---|---|---|---|---|---|---|---|---|---|---|---|
| | | Part(s) by | | Part(s) by | | Parts(s) by | | Part(s) by | | Part(s) by | | Part(s) by | | Part(s) by |
| | Kind | Mass | Kind | Mass | Kind | Mass | Kind | Mass | Kind | Mass | Kind | Mass | Kind | Mass |
| Example 1 | A1 | 2.5 | B1 | 0.5 | C1 | 1.8 | J1 | 39 | — | — | D1 | 5.5 | E1 | 6.4 |
| Example 2 | A1 | 2.5 | B1 | 0.5 | C1 | 1.8 | J1 | 39 | — | — | D1 | 5.5 | E1 | 6.4 |
| Example 3 | A1 | 2.5 | B1 | 0.5 | C1 | 1.8 | J1 | 39 | — | — | D1 | 5.5 | E1 | 6.4 |
| Example 4 | A1 | 2.5 | B1 | 0.5 | C1 | 1.8 | J1 | 39 | — | — | D1 | 5.5 | E1 | 6.4 |
| Example 5 | A1 | 2.5 | B1 | 0.5 | C1 | 1.8 | J1 | 39 | — | — | D1 | 5.5 | E1 | 6.4 |
| Example 6 | A1 | 2.5 | B1 | 0.5 | C1 | 1.8 | J1 | 39 | — | — | D2 | 5.5 | E1 | 6.4 |
| Example 7 | A1 | 2.5 | B1 | 0.5 | C1 | 1.8 | J1 | 39 | — | — | D3 | 5.5 | E1 | 6.4 |
| Example 8 | A1 | 2.5 | B1 | 0.5 | C1 | 1.8 | J1 | 39 | — | — | D4 | 5.5 | E1 | 6.4 |
| Example 9 | A1 | 2.5 | B1 | 0.5 | C1 | 1.8 | J1 | 39 | — | — | D1 + D4 | 5.5 | E1 | 6.4 |
| Example 10 | A1 | 2.5 | B1 | 0.5 | C1 | 1.8 | J1 | 39 | — | — | D3 | 5.5 | E2 | 6.4 |
| Example 11 | A1 | 2.5 | B1 | 0.5 | C1 | 1.8 | J1 | 39 | — | — | D3 | 5.5 | E3 | 6.4 |
| Example 12 | A1 | 2.5 | B1 | 0.5 | C1 | 1.8 | J1 | 39 | — | — | D3 | 5.5 | E4 | 6.4 |
| Example 13 | A1 | 2.5 | B1 | 0.5 | C1 | 1.8 | J1 | 39 | — | — | D3 | 5.5 | E5 | 6.4 |
| Example 14 | A1 | 2.5 | B1 | 0.5 | C1 | 1.8 | J1 | 39 | — | — | D3 | 5.5 | E6 | 6.4 |
| Example 15 | A1 | 2.5 | B1 | 0.5 | C1 | 1.8 | J1 | 39 | — | — | D3 | 5.5 | E7 | 6.4 |
| Example 16 | A1 | 2.5 | B1 | 0.5 | C1 | 1.8 | J1 | 39 | — | — | D3 | 5.5 | E2 + E4 | 3.2 + 3.2 |
| Example 17 | A1 | 2.5 | B1 | 0.5 | C1 | 1.8 | J1 | 39 | — | — | D4 | 5.5 | E2 | 6.4 |
| Example 18 | A1 | 2.5 | B1 | 0.5 | C1 | 1.8 | J1 | 39 | — | — | D4 | 5.5 | E3 | 6.4 |
| Example 19 | A1 | 2.5 | B1 | 0.5 | C1 | 1.8 | J1 | 39 | — | — | D4 | 5.5 | E4 | 6.4 |
| Example 20 | A1 | 2.5 | B1 | 0.5 | C1 | 1.8 | J1 | 39 | — | — | D4 | 5.5 | E5 | 6.4 |
| Example 21 | A1 | 2.5 | B1 | 0.5 | C1 | 1.8 | J1 | 39 | — | — | D4 | 5.5 | E6 | 6.4 |
| Example 22 | A1 | 2.5 | B1 | 0.5 | C1 | 1.8 | J1 | 39 | — | — | D4 | — | E6 | 11.9 |
| Example 23 | A1 | 2.5 | B1 | 0.5 | C1 | 1.8 | J1 | 39 | — | — | D4 | 5.5 | E7 | 6.4 |
| Example 24 | A1 | 2.5 | B1 | 0.5 | C1 | 1.8 | J1 | 39 | — | — | D4 | 5.5 | E2 + E4 | 3.2 + 3.2 |
| Example 25 | A1 | 2.5 | B1 | 0.5 | C1 | 1.8 | J1 | 39 | — | — | D4 | 5.5 | E6 | 6.4 |
| Example 26 | A1 | 2.5 | B1 | 0.5 | C1 | 1.8 | J1 | 39 | — | — | D4 | 5.5 | E6 | 6.4 |
| Example 27 | A1 | 2.5 | B1 | 0.5 | C1 | 1.8 | J1 | 39 | — | — | D4 | 5.5 | E6 | 6.4 |
| Example 28 | A1 | 2.5 | B1 | 0.5 | C1 | 1.8 | J1 | 39 | — | — | D4 | 5.5 | E6 | 6.4 |
| Example 29 | A1 | 2.5 | B1 | 0.5 | C1 | 1.8 | J1 | 39 | — | — | D4 | 5.5 | E6 | 6.4 |
| Example 30 | A1 | 2.5 | B1 | 0.5 | C1 | 1.8 | J1 | 39 | — | — | D4 | 5.5 | E6 | 6.4 |
| Example 31 | A1 | 2.5 | B1 | 0.5 | C1 | 1.8 | J1 | 39 | — | — | D4 | 5.5 | E6 | 6.4 |
| Example 32 | A1 | 2.5 | B1 | 0.5 | C1 | 1.8 | J1 | 39 | — | — | D4 | 5.5 | E6 | 6.4 |
| Example 33 | A1 | 2.5 | B1 | 0.5 | C1 | 1.8 | J1 | 39 | — | — | D4 | 5.5 | E6 | 6.4 |
| Example 34 | A1 | 2.5 | B1 | 0.5 | C1 | 1.8 | J1 | 39 | — | — | D4 | 5.5 | E6 | 6.4 |
| Example 35 | A1 | 2.5 | B1 | 0.5 | C1 | 1.8 | J1 | 39 | — | — | D4 | 5.5 | E6 | 6.4 |
| Example 36 | A1 | 2.5 | B1 | 0.5 | C1 | 1.8 | J1 | 39 | — | — | D4 | 5.5 | E6 + E9 | 5.4 + 1 |
| Example 37 | A1 | 2.5 | B1 | 0.5 | C1 | 1.8 | J1 | 39 | — | — | D4 | 5.5 | E6 + E10 | 5.4 + 1 |
| Example 38 | A2 | 2.5 | B1 | 0.5 | C1 | 1.8 | J1 | 39 | — | — | D4 | 5.5 | E6 | 6.4 |
| Example 39 | A1 | 2.5 | B1 | 0.5 | C1 | 1.8 | J1 | 39 | — | — | D4 | 5.5 | E6 | 6.4 |
| Example 40 | A1 | 2.5 | B1 | 0.5 | C1 | 1.8 | J1 | 39 | — | — | D4 | 5.5 | E6 | 6.4 |
| Example 41 | A1 | 2.5 | B1 | 0.5 | C1 | 1.8 | J2 | 39 | — | — | D4 | 5.5 | E6 | 6.4 |
| Example 42 | A1 + A2 | 1.5 + 1 | B1 | 0.5 | C1 | 1.8 | J1 | 39 | — | — | D4 | 5.5 | E6 | 6.4 |
| Example 43 | A1 | 2.5 | B1 + B2 | 0.3 + 0.2 | C1 | 1.8 | J1 | 39 | — | — | D4 | 5.5 | E6 | 6.4 |
| Example 44 | A1 | 2.5 | B1 | 0.5 | C1 + C2 | 0.9 + 0.9 | J1 | 39 | — | — | D4 | 5.5 | E6 | 6.4 |
| Example 45 | A1 | 2.5 | B1 | 0.5 | C1 | 1.8 | J1 | 39 | — | — | D4 | 5.5 | E6 | 6.4 |
| Example 46 | — | — | — | — | — | — | — | — | A3 | 3 | D4 | 5.5 | E6 | 6.4 |
| Example 47 | — | — | — | — | — | — | — | — | A4 | 3 | D4 | 5.5 | E6 | 6.4 |
| Example 48 | — | — | — | — | — | — | — | — | A5 | 3 | D4 | 5.5 | E6 | 6.4 |
| Example 49 | A1 | 1.5 | B1 | 0.3 | C1 | 0.9 | J1 | 19.5 | A3 | 1.2 | D4 | 5.5 | E6 | 6.4 |
| Example 50 | A1 | 2.5 | B1 | 0.5 | C1 | 1.8 | J1 | 26 | — | — | D3 | 5.5 | E6 | 6.4 |

| | Photoinitiator | | Ultraviolet Absorber | | Surfactant | | Polymerizatiion Inhibitor | | Anti-Coloring Agent | | Solvent | |
|---|---|---|---|---|---|---|---|---|---|---|---|---|
| | | Part(s) by | | Part(s) by | | Part(s) by | | Part(s) by | | Part(s) by | | Part(s) by |
| | Kind | Mass | Kind | Mass | Kind | Mass | Kind | Mass | Kind | Mass | Kind | Mass |
| Example 1 | F1 | 1 | UV1 | 1.6 | G1 | 0.025 | H1 | 0.003 | I1 | 0.2 | J1 | 41.47 |
| Example 2 | F1 | 1 | UV2 | 1.6 | G1 | 0.025 | H1 | 0.003 | I1 | 0.2 | J1 | 41.47 |
| Example 3 | F1 | 1 | UV3 | 1.6 | G1 | 0.025 | H1 | 0.003 | I1 | 0.2 | J1 | 41.47 |
| Example 4 | F1 | 1 | UV4 | 1.6 | G1 | 0.025 | H1 | 0.003 | I1 | 0.2 | J1 | 41.47 |
| Example 5 | F1 | 1 | UV1 + UV4 | 1.6 | G1 | 0.025 | H1 | 0.003 | I1 | 0.2 | J1 | 41.47 |
| Example 6 | F1 | 1 | UV4 | 1.6 | G1 | 0.025 | H1 | 0.003 | I1 | 0.2 | J1 | 41.47 |
| Example 7 | F1 | 1 | UV4 | 1.6 | G1 | 0.025 | H1 | 0.003 | I1 | 0.2 | J1 | 41.47 |
| Example 8 | F1 | 1 | UV4 | 1.6 | G1 | 0.025 | H1 | 0.003 | I1 | 0.2 | J1 | 41.47 |
| Example 9 | F1 | 1 | UV4 | 1.6 | G1 | 0.025 | H1 | 0.003 | I1 | 0.2 | J1 | 41.47 |
| Example 10 | F1 | 1 | UV4 | 1.6 | G1 | 0.025 | H1 | 0.003 | I1 | 0.2 | J1 | 41.47 |
| Example 11 | F1 | 1 | UV4 | 1.6 | G1 | 0.025 | H1 | 0.003 | I1 | 0.2 | J1 | 41.47 |
| Example 12 | F1 | 1 | UV4 | 1.6 | G1 | 0.025 | H1 | 0.003 | I1 | 0.2 | J1 | 41.47 |
| Example 13 | F1 | 1 | UV4 | 1.6 | G1 | 0.025 | H1 | 0.003 | I1 | 0.2 | J1 | 41.47 |
| Example 14 | F1 | 1 | UV4 | 1.6 | G1 | 0.025 | H1 | 0.003 | I1 | 0.2 | J1 | 41.47 |
| Example 15 | F1 | 1 | UV4 | 1.6 | G1 | 0.025 | H1 | 0.003 | I1 | 0.2 | J1 | 41.47 |
| Example 16 | F1 | 1 | UV4 | 1.6 | G1 | 0.025 | H1 | 0.003 | I1 | 0.2 | J1 | 41.47 |
| Example 17 | F1 | 1 | UV4 | 1.6 | G1 | 0.025 | H1 | 0.003 | I1 | 0.2 | J1 | 41.47 |
| Example 18 | F1 | 1 | UV4 | 1.6 | G1 | 0.025 | H1 | 0.003 | I1 | 0.2 | J1 | 41.47 |
| Example 19 | F1 | 1 | UV4 | 1.6 | G1 | 0.025 | H1 | 0.003 | I1 | 0.2 | J1 | 41.47 |
| Example 20 | F1 | 1 | UV4 | 1.6 | G1 | 0.025 | H1 | 0.003 | I1 | 0.2 | J1 | 41.47 |
| Example 21 | F1 | 1 | UV4 | 1.6 | G1 | 0.025 | H1 | 0.003 | I1 | 0.2 | J1 | 41.47 |
| Example 22 | F1 | 1 | UV4 | 1.6 | G1 | 0.025 | H1 | 0.003 | I1 | 0.2 | J1 | 41.47 |
| Example 23 | F1 | 1 | UV4 | 1.6 | G1 | 0.025 | H1 | 0.003 | I1 | 0.2 | J1 | 41.47 |
| Example 24 | F1 | 1 | UV4 | 1.6 | G1 | 0.025 | H1 | 0.003 | I1 | 0.2 | J1 | 41.47 |
| Example 25 | F2 | 1 | UV4 | 1.6 | G1 | 0.025 | H1 | 0.003 | I1 | 0.2 | J1 | 41.47 |
| Example 26 | F3 | 1 | UV4 | 1.6 | G1 | 0.025 | H1 | 0.003 | I1 | 0.2 | J1 | 41.47 |
| Example 27 | F4 | 1 | UV4 | 1.6 | G1 | 0.025 | H1 | 0.003 | I1 | 0.2 | J1 | 41.47 |
| Example 28 | F5 | 1 | UV4 | 1.6 | G1 | 0.025 | H1 | 0.003 | I1 | 0.2 | J1 | 41.47 |
| Example 29 | F6 | 1 | UV4 | 1.6 | G1 | 0.025 | H1 | 0.003 | I1 | 0.2 | J1 | 41.47 |
| Example 30 | F7 | 1 | UV4 | 1.6 | G1 | 0.025 | H1 | 0.003 | I1 | 0.2 | J1 | 41.47 |
| Example 31 | F8 | 1 | UV4 | 1.6 | G1 | 0.025 | H1 | 0.003 | I1 | 0.2 | J1 | 41.47 |
| Example 32 | F1 + F2 | 1 | UV4 | 1.6 | G1 | 0.025 | H1 | 0.003 | I1 | 0.2 | J1 | 41.47 |
| Example 33 | F1 | 1 | UV4 | 1.6 | G1 | 0.025 | H1 | 0.003 | I1 | 0.2 | J1 | 41.47 |
| Example 34 | F1 | 1 | UV4 | 1.6 | G1 | 0.025 | H1 | 0.003 | I2 | 0.2 | J1 | 41.47 |
| Example 35 | F1 | 1 | UV4 | 1.6 | G1 | 0.025 | H1 | 0.003 | — | — | J1 | 41.49 |
| Example 36 | F1 | 1 | UV4 | 1.6 | G1 | 0.025 | H1 | 0.003 | I1 | 0.2 | J1 | 41.47 |
| Example 37 | F1 | 1 | UV4 | 1.6 | G1 | 0.025 | H1 | 0.003 | I1 | 0.2 | J1 | 41.47 |
| Example 38 | F1 | 1 | UV4 | 1.6 | G1 | 0.025 | H1 | 0.003 | I1 | 0.2 | J1 | 41.47 |
| Example 39 | F1 | 1 | UV4 | 1.6 | G1 | 0.025 | H1 | 0.003 | I1 | 0.2 | J1 | 41.47 |
| Example 40 | F1 | 1 | UV4 | 1.6 | G1 | 0.025 | H1 | 0.003 | I1 | 0.2 | J1 | 41.47 |
| Example 41 | F1 | 1 | UV4 | 1.6 | G1 | 0.025 | H1 | 0.003 | I1 | 0.2 | J1 | 41.47 |
| Example 42 | F1 | 1 | UV4 | 1.6 | G1 | 0.025 | H1 | 0.003 | I1 | 0.2 | J1 | 41.47 |
| Example 43 | F1 | 1 | UV4 | 1.6 | G1 | 0.025 | H1 | 0.003 | I1 | 0.2 | J1 | 41.47 |
| Example 44 | F1 | 1 | UV4 | 1.6 | G1 | 0.025 | H1 | 0.003 | I1 | 0.2 | J1 | 41.47 |
| Example 45 | F1 | 1 | UV4 | 1.6 | G1 | 0.025 | H1 | 0.003 | I1 | 0.2 | J1 | 41.47 |
| Example 46 | F1 | 1 | UV4 | 1.6 | G1 | 0.025 | H1 | 0.003 | I1 | 0.2 | J1 | 82.27 |
| Example 47 | F1 | 1 | UV4 | 1.6 | G1 | 0.025 | H1 | 0.003 | I1 | 0.2 | J1 | 82.27 |
| Example 48 | F1 | 1 | UV4 | 1.6 | G1 | 0.025 | H1 | 0.003 | I1 | 0.2 | J1 | 82.27 |
| Example 49 | F1 | 1 | UV4 | 1.6 | G1 | 0.025 | H1 | 0.003 | I1 | 0.2 | J1 | 63.07 |
| Example 50 | F1 | 1 | UV4 | 1.6 | G1 | 0.025 | H1 | 0.003 | I1 | 0.2 | J1 | 54.97 |

TABLE 3

| | Dispersion | | | | | | | | | | | | | | | | | | | | | | | | | |
|---|---|---|---|---|---|---|---|---|---|---|---|---|---|---|---|---|---|---|---|---|---|---|---|---|---|---|
| | Near | | | | | | | | Near | | | | | | | | | | | | | | | | | |
| | Infrared | | Pigment | | | | | | Infrared | | | | Curable | | | | Ultraviolet | | | | Polymerizatiion | | Anti-Coloring | | | |
| | Absorber | | Derivative | | Dispersant | | Solvent | | Absorber | | Resin | | Compound | | Photoinitiator | | Absorber | | Surfactant | | Inhibitor | | Agent | | Solvent | |
| | | Part | | Part | | Part | | Part | | Part | | Part | | Part | | Part | | Part | | Part | | Part | | Part | | Part |
| | | (s) | | (s) | | (s) | | (s) | | (s) | | (s) | | (s) | | (s) | | (s) | | (s) | | (s) | | (s) | | (s) |
| | | by | | by | | by | | by | | by | | by | | by | | by | | by | | by | | by | | by | | by |
| | Kind | Mass | Kind | Mass | Kind | Mass | Kind | Mass | Kind | Mass | Kind | Mass | Kind | Mass | Kind | Mass | Kind | Mass | Kind | Mass | Kind | Mass | Kind | Mass | Kind | Mass |
| Example 51 | A1 | 2.5 | B1 | 0.5 | C1 | 1.8 | J1 | 19.5 | — | — | D3 | 5.5 | E6 | 6.4 | F1 | 1 | UV4 | 1.6 | G1 | 0.025 | H1 | 0.003 | I1 | 0.2 | J1 | 60.97 |
| Example 52 | A1 | 2.5 | B1 | 0.5 | C1 | 1.8 | J1 | 39 | — | — | D3 | 5.75 | E6 | 6.4 | F1 | 0.75 | UV4 | 1.6 | G1 | 0.025 | H1 | 0.003 | I1 | 0.2 | J1 | 41.47 |
| Example 53 | A1 | 2.5 | B1 | 0.5 | C1 | 1.8 | J1 | 39 | — | — | D3 | 6 | E6 | 6.4 | F1 | 0.5 | UV4 | 1.6 | G1 | 0.025 | H1 | 0.003 | I1 | 0.2 | J1 | 41.47 |
| Example 54 | A1 | 2.5 | B1 | 0.5 | C1 | 1.8 | J1 | 39 | — | — | D3 | 5.9 | E6 | 6.4 | F1 | I | UV4 | 1.2 | G1 | 0.025 | H1 | 0.003 | I1 | 0.2 | J1 | 41.47 |
| Example 55 | A1 | 2.5 | B1 | 0.5 | C1 | 1.8 | J1 | 39 | — | — | D3 | 6.3 | E6 | 6.4 | F1 | I | UV4 | 0.8 | G1 | 0.025 | H1 | 0.003 | I1 | 0.2 | J1 | 41.47 |
| Example 56 | A1 | 2.5 | B1 | 0.5 | C1 | 1.8 | J1 | 39 | — | — | D3 | 6.15 | E6 | 6.4 | F1 | 0.75 | UV4 | 1.2 | G1 | 0.025 | H1 | 0.003 | I1 | 0.2 | J1 | 41.47 |
| Example 57 | A1 | 2.5 | B1 | 0.5 | C1 | 1.8 | J1 | 39 | — | — | D3 | 6.55 | E6 | 6.4 | F1 | 0.75 | UV4 | 0.8 | G1 | 0.025 | H1 | 0.003 | I1 | 0.2 | J1 | 41.47 |
| Example 58 | A1 | 2.5 | B1 | 0.5 | C1 | 1.8 | J1 | 39 | — | — | D3 | 6.4 | E6 | 6.4 | F1 | 0.5 | UV4 | 1.2 | G1 | 0.025 | H1 | 0.003 | I1 | 0.2 | J1 | 41.47 |
| Example 59 | A1 | 2.5 | B1 | 0.5 | C1 | 1.8 | J1 | 39 | — | — | D3 | 6.8 | E6 | 6.4 | F1 | 0.5 | UV4 | 0.8 | G1 | 0.025 | H1 | 0.003 | I1 | 0.2 | J1 | 41.47 |
| Example 60 | A1 | 2 | B1 | 0.4 | C1 | 1.44 | J1 | 42 | — | — | D3 | 6.6 | E6 | 6.8 | F1 | 1 | UV4 | 1.6 | G1 | 0.025 | H1 | 0.003 | I1 | 0.2 | J1 | 37.93 |
| Example 61 | A1 | 3 | B1 | 0.6 | C1 | 2.16 | J1 | 65 | — | — | D3 | 5.1 | E6 | 6.2 | F1 | 1 | UV4 | 1.6 | G1 | 0.025 | H1 | 0.003 | I1 | 0.2 | J1 | 15.11 |
| Example 62 | A1 | 4 | B1 | 0.8 | C1 | 2.88 | J1 | 32.5 | — | — | D3 | 3.7 | E6 | 5.7 | F1 | 1 | UV4 | 1.6 | G1 | 0.025 | H1 | 0.003 | I1 | 0.2 | J1 | 47.59 |
| Example 63 | A1 | 5 | B1 | 1 | C1 | 3.6 | J1 | 26 | — | — | D3 | 2.2 | E6 | 5.1 | F1 | 1 | UV4 | 1.6 | G1 | 0.025 | H1 | 0.003 | I1 | 0.2 | J1 | 54.27 |
| Example 64 | A1 | 2.5 | B1 | 0.5 | C1 | 1.8 | J1 | 39 | — | — | D3 | 4.2 | E6 | 7.7 | F1 | 1 | UV4 | 1.6 | G1 | 0.025 | H1 | 0.003 | I1 | 0.2 | J1 | 41.47 |
| Example 65 | A1 | 2.5 | B1 | 0.5 | C1 | 1.8 | J1 | 39 | — | — | D3 | 3.3 | E6 | 8.6 | F1 | 1 | UV4 | 1.6 | G1 | 0.025 | H1 | 0.003 | I1 | 0.2 | J1 | 41.47 |
| Example 66 | A1 | 2.5 | B1 | 0.5 | C1 | 1.8 | J1 | 39 | — | — | D3 | 6.7 | E6 | 5.6 | F1 | 1 | UV4 | 1.6 | G1 | 0.025 | H1 | 0.003 | I1 | 0.2 | J1 | 41.07 |
| Example 67 | A1 | 2.5 | B1 | 0.5 | C1 | 1.8 | J1 | 39 | — | — | D3 | 8 | E6 | 4.5 | F1 | 1 | UV4 | 1.6 | G1 | 0.025 | H1 | 0.003 | I1 | 0.2 | J1 | 40.87 |
| Example 68 | A1 | 2.5 | B1 | 0.5 | C1 | 1.8 | J1 | 26 | — | — | D4 | 5.5 | E6 | 6.4 | F1 | 1 | UV4 | 1.6 | G1 | 0.025 | H1 | 0.003 | I1 | 0.2 | J1 | 54.47 |
| Example 69 | A1 | 2.5 | B1 | 0.5 | C1 | 1.8 | J1 | 19.5 | — | — | D4 | 5.5 | E6 | 6.4 | F1 | 1 | UV4 | 1.6 | G1 | 0.025 | H1 | 0.003 | I1 | 0.2 | J1 | 60.97 |
| Example 70 | A1 | 2.5 | B1 | 0.5 | C1 | 1.8 | J1 | 39 | — | — | D4 | 5.75 | E6 | 6.4 | F1 | 0.75 | UV4 | 1.6 | G1 | 0.025 | H1 | 0.003 | I1 | 0.2 | J1 | 41.47 |
| Example 71 | A1 | 2.5 | B1 | 0.5 | C1 | 1.8 | J1 | 39 | — | — | D4 | 6 | E6 | 6.4 | F1 | 0.5 | UV4 | 1.6 | G1 | 0.025 | H1 | 0.003 | I1 | 0.2 | J1 | 41.47 |
| Example 72 | A1 | 2.5 | B1 | 0.5 | C1 | 1.8 | J1 | 39 | — | — | D4 | 5.9 | E6 | 6.4 | F1 | 1 | UV4 | 1.6 | G1 | 0.025 | H1 | 0.003 | I1 | 0.2 | J1 | 41.47 |
| Example 73 | A1 | 2.5 | B1 | 0.5 | C1 | 1.8 | J1 | 39 | — | — | D4 | 6.3 | E6 | 6.4 | F1 | 1 | UV4 | 1.6 | G1 | 0.025 | H1 | 0.003 | I1 | 0.2 | J1 | 41.47 |
| Example 74 | A1 | 2.5 | B1 | 0.5 | C1 | 1.8 | J1 | 39 | — | — | D4 | 6.15 | E6 | 6.4 | F1 | 0.75 | UV4 | 1.6 | G1 | 0.025 | H1 | 0.003 | I1 | 0.2 | J1 | 41.47 |
| Example 75 | A1 | 2.5 | B1 | 0.5 | C1 | 1.8 | J1 | 39 | — | — | D4 | 6.55 | E6 | 6.4 | F1 | 0.75 | UV4 | 1.6 | G1 | 0.025 | H1 | 0.003 | I1 | 0.2 | J1 | 41.47 |
| Example 76 | A1 | 2.5 | B1 | 0.5 | C1 | 1.8 | J1 | 39 | — | — | D4 | 6.4 | E6 | 6.4 | F1 | 0.5 | UV4 | 1.6 | G1 | 0.025 | H1 | 0.003 | I1 | 0.2 | J1 | 41.47 |
| Example 77 | A1 | 2.5 | B1 | 0.5 | C1 | 1.8 | J1 | 39 | — | — | D4 | 6.3 | E6 | 6.4 | F1 | 0.5 | UV4 | 1.6 | G1 | 0.025 | H1 | 0.003 | I1 | 0.2 | J1 | 41.47 |
| Example 78 | A1 | 2 | B1 | 0.4 | C1 | 1.44 | J1 | 42 | — | — | D4 | 6.6 | E6 | 6.8 | F1 | 1 | UV4 | 1.6 | G1 | 0.025 | H1 | 0.003 | I1 | 0.2 | J1 | 37.93 |
| Example 79 | A1 | 3 | B1 | 0.6 | C1 | 2.16 | J1 | 65 | — | — | D4 | 5.1 | E6 | 6.2 | F1 | 1 | UV4 | 1.6 | G1 | 0.025 | H1 | 0.003 | I1 | 0.2 | J1 | 15.11 |
| Example 80 | A1 | 4 | B1 | 0.8 | C1 | 2.88 | J1 | 32.5 | — | — | D4 | 3.7 | E6 | 5.7 | F1 | 1 | UV4 | 1.6 | G1 | 0.025 | H1 | 0.003 | I1 | 0.2 | J1 | 47.59 |
| Example 81 | A1 | 5 | B1 | 1 | C1 | 3.6 | J1 | 26 | — | — | D4 | 2.2 | E6 | 5.1 | F1 | 1 | UV4 | 1.6 | G1 | 0.025 | H1 | 0.003 | I1 | 0.2 | J1 | 54.27 |
| Example 82 | A1 | 2.5 | B1 | 0.5 | C1 | 1.8 | J1 | 39 | — | — | D4 | 4.2 | E6 | 7.7 | F1 | 1 | UV4 | 1.6 | G1 | 0.025 | H1 | 0.003 | I1 | 0.2 | J1 | 41.47 |
| Example 83 | A1 | 2.5 | B1 | 0.5 | C1 | 1.8 | J1 | 39 | — | — | D4 | 3.3 | E6 | 8.6 | F1 | 1 | UV4 | 1.6 | G1 | 0.025 | H1 | 0.003 | I1 | 0.2 | J1 | 41.47 |
| Example 84 | A1 | 2.5 | B1 | 0.5 | C1 | 1.8 | J1 | 39 | — | — | D4 | 6.7 | E6 | 5.6 | F1 | 1 | UV4 | 1.6 | G1 | 0.025 | H1 | 0.003 | I1 | 0.2 | J1 | 41.07 |
| Example 85 | A1 | 2.5 | B1 | 0.5 | C1 | 1.8 | J1 | 39 | — | — | D4 | 8 | E6 | 4.5 | F1 | 1 | UV4 | 1.6 | G1 | 0.025 | H1 | 0.003 | I1 | 0.2 | J1 | 40.87 |
| Example 86 | A1 | 2.5 | B1 | 0.5 | C1 | 1.8 | J1 | 39 | — | — | D1 | 5.5 | E8 | 6.4 | F1 | 1 | UV4 | 1.6 | G1 | 0.025 | — | — | I1 | 0.2 | J1 | 42.48 |
| Example 87 | — | — | — | — | — | — | — | — | A4 | 3.6 | D1 | 7.3 | E8 | 6.4 | F1 | 1 | UV4 | 1.6 | G1 | 0.025 | — | — | I1 | 0.2 | J1 | 80.88 |
| Example 88 | A1 | 2.5 | B1 | 0.5 | C1 | 1.8 | J1 | 39 | — | — | D5 | 5.5 | E1 | 6.4 | F1 | 1 | UV4 | 1.6 | G1 | 0.025 | H1 | 0.003 | I1 | 0.2 | J1 | 41.47 |
| Example 89 | — | — | — | — | — | — | — | — | A4 | 3.6 | D5 | 7.3 | E1 | 6.4 | F1 | 1 | UV4 | 1.6 | G1 | 0.025 | H1 | 0.003 | I1 | 0.2 | J1 | 79.87 |
| Example 90 | | 2.5 | B1 | 0.5 | C1 | 1.8 | J1 | 39 | — | — | D1 | 5.5 | E1 | 6.4 | F1 | 1 | UV5 | 1.6 | G1 | 0.025 | H1 | 0.003 | I1 | 0.2 | J1 | 41.47 |
| Comparative | A1 | 2.5 | B1 | 0.5 | C1 | 1.8 | J1 | 39 | — | — | D1 | 5.5 | E1 | 6.4 | F1 | 1 | UV6 | 1.6 | G1 | 0.025 | H1 | 0.003 | I1 | 0.2 | J1 | 41.47 |
| Example 1 | | | | | | | | | | | | | | | | | | | | | | | | | | |
| Comparative | A1 | 2.5 | B1 | 0.5 | C1 | 1.8 | J1 | 39 | — | — | D1 | 5.5 | E1 | 6.4 | F1 | 1 | UV7 | 1.6 | G1 | 0.025 | H1 | 0.003 | I1 | 0.2 | J1 | 41.47 |
| Example 2 | | | | | | | | | | | | | | | | | | | | | | | | | | |
| Comparative | A1 | 2.5 | B1 | 0.5 | C1 | 1.8 | J1 | 39 | — | — | D1 | 5.5 | E1 | 6.4 | F1 | 1 | UV8 | 1.6 | G1 | 0.025 | H1 | 0.003 | I1 | 0.2 | J1 | 41.47 |
| Example 3 | | | | | | | | | | | | | | | | | | | | | | | | | | |

The raw materials shown above in the tables are as follows.

(Near Infrared Absorber)

A1 to A5: compounds having the following structures. In the following formulae, Me represents a methyl group, Ph represents a phenyl group, and EH represents an ethylhexyl group.

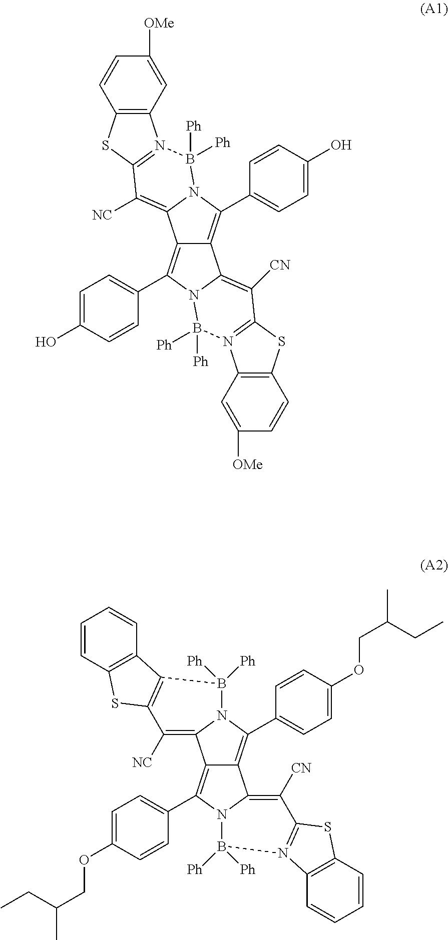

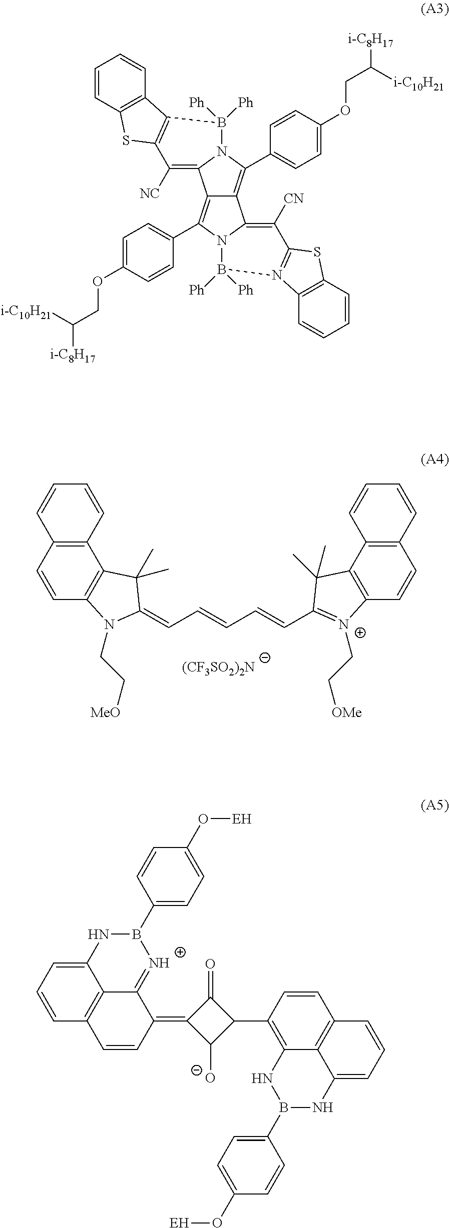

(Pigment Derivative)

B1 to B3: compounds having the following structures. In the following structural formulae, Me represents a methyl group, and Ph represents a phenyl group.

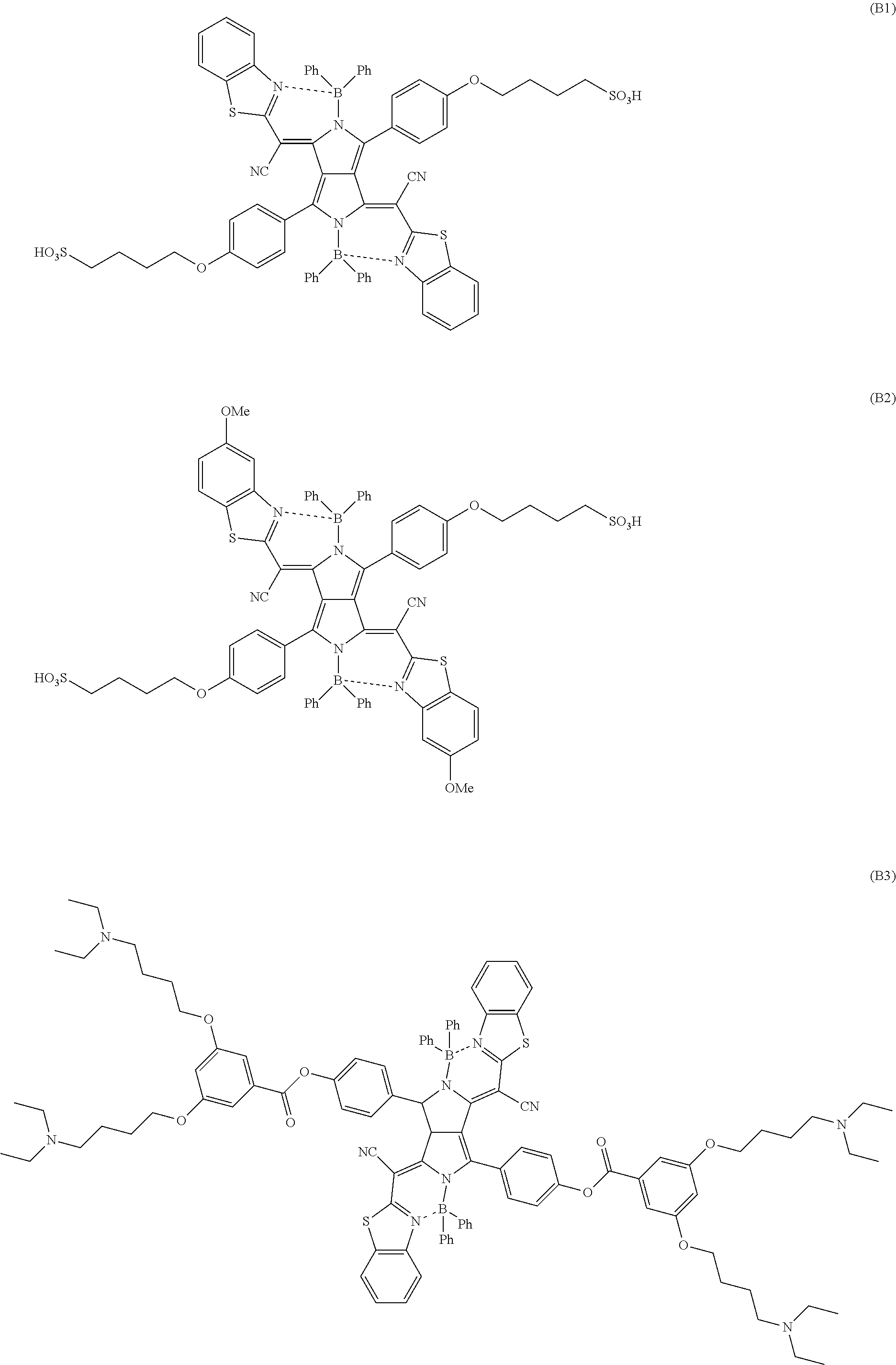

(Dispersant)

C1: a resin having the following structure (a numerical value added to a main chain represents a molar ratio, and a numerical value added to a side chain represents the number of repeating units. Mw=20000, acid value=105 mgKOH/g)

C2: a resin having the following structure (a numerical value added to a main chain represents a molar ratio, and a numerical value added to a side chain represents the number of repeating units. Mw=20000, acid value=30 mgKOH/g)

C3: a resin having the following structure (a numerical value added to a main chain represents a molar ratio, and a numerical value added to a side chain represents the number of repeating units. Mw=20000, acid value=105 mgKOH/g)

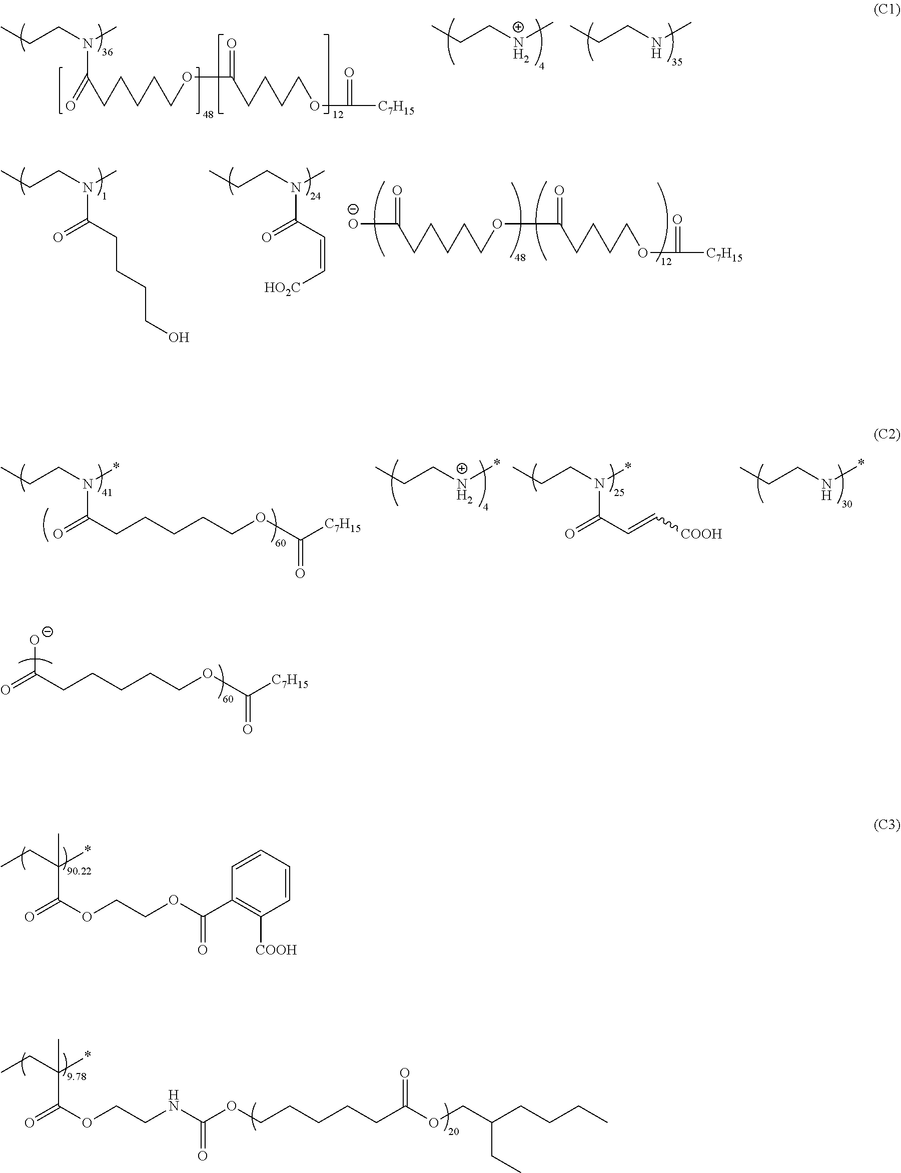

(Resin)

D 1: a resin having the following structure (a numerical value added to a main chain represents a molar ratio. Mw=10000, acid value=70 mgKOH/g)

D2: a resin having the following structure (a numerical value added to a main chain represents a molar ratio. Mw=30000, acid value=100 mgKOH/g)

D3: a resin having the following structure (a numerical value added to a main chain represents a molar ratio. Mw=40000, acid value=100 mgKOH/g)

D4: a resin having the following structure (a numerical value added to a main chain represents a molar ratio. Mw=10000, acid value=70 mgKOH/g)

D5: ARTON F4520 (manufactured by JSR Corporation)

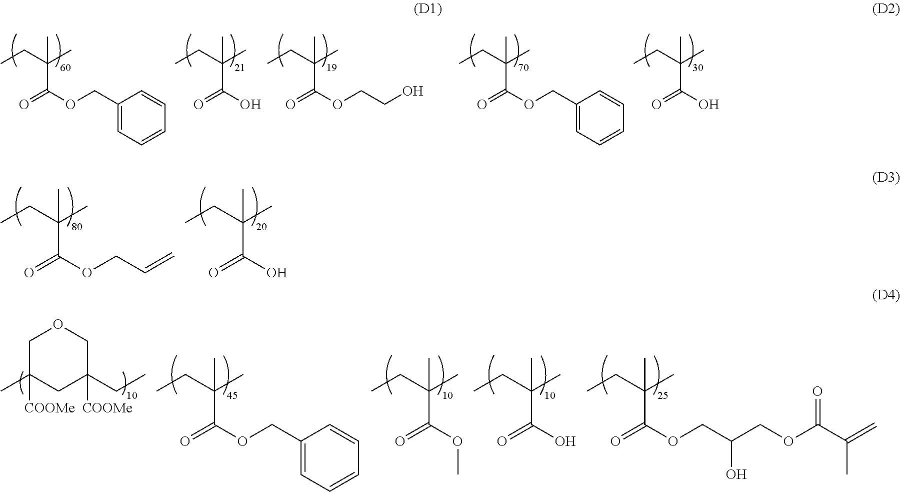

(Curable Compound)

E1: ARONIX M-305 (manufactured by Toagosei Co., Ltd., radically polymerizable compound)

E2: ARONIX TO-2349 (manufactured by Toagosei Co., Ltd., radically polymerizable compound)

E3: NK ESTER A-DPH-12E (manufactured by Shin-Nakamura Chemical Co., Ltd., radically polymerizable compound)

E4: NK ESTER A-TMMT (manufactured by Shin-Nakamura Chemical Co., Ltd., radically polymerizable compound)

E5: KAYARAD DPCA-20 (manufactured by Nippon Kayaku Co., Ltd., radically polymerizable compound)

E6: ARONIX M-510 (manufactured by Toagosei Co., Ltd., radically polymerizable compound)

E7: ARONIX M-350 (manufactured by Toagosei Co., Ltd., radically polymerizable compound)

E8: ED-505 (manufactured by Adeka Corporation, cationically polymerizable compound)

E9: EPICLON N-695 (manufactured by DIC Corporation, cationically polymerizable compound)

E10: EHPE 3150 (manufactured by Daicel Corporation, cationically polymerizable compound)

(Photoinitiator)

F1: IRGACURE OXE01 (manufactured by BASF SE, photoradical polymerization initiator)

F2: IRGACURE OXE02 (manufactured by BASF SE, photoradical polymerization initiator)

F3: IRGACURE OXE03 (manufactured by BASF SE, photoradical polymerization initiator)

F4: IRGACURE OXE04 (manufactured by BASF SE, photoradical polymerization initiator)

F5: IRGACURE 369 (manufactured by BASF SE, photoradical polymerization initiator)

F6, F7: compounds having the following structures (photoradical polymerization initiator)

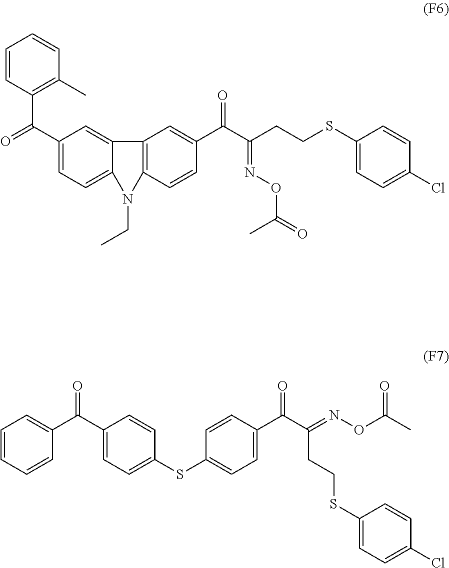 [SMILES: CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1]

F8: ADEKA ARKLS NCI-930 (manufactured by Adeka Corporation, photoradical polymerization initiator)

F9: ADEKA ARKLS SP-606 (manufactured by Adeka Corporation, photocationic polymerization initiator)

(Ultraviolet Absorber)

UV1 to UV8: the above-described ultraviolet absorbers

(Surfactant)

G1: the following mixture (Mw=14000). In the following expression, “%” representing the proportion of a repeating unit is mass %.

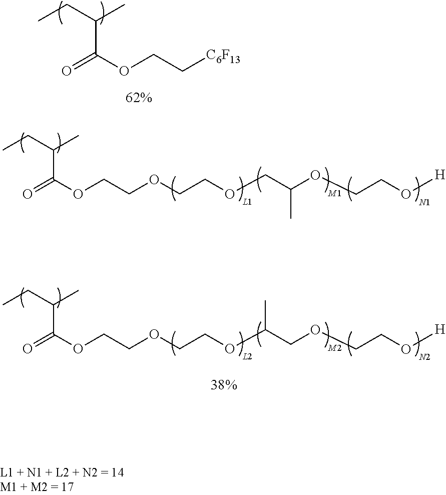

G2: KF6001 (manufactured by Shin-Etsu Chemical Co., Ltd.)

(Polymerization Inhibitor)

H1: p-methoxyphenol

(Anti-Coloring Agent)

I1: ADEKA STAB AO-80 (manufactured by Adeka Corporation)

I2: ADEKA STAB AO-60 (manufactured by Adeka Corporation)

(Solvent)

J1: propylene glycol monomethyl ether acetate (PGMEA)

J2: cyclohexanone

J3: dichloromethane

<Evaluation>

[Visible Transparency 1] (Visible Transparency Before Post-Baking)

Each of the photosensitive compositions was applied to a glass substrate using a spin coater (manufactured by Mikasa Co., Ltd.) such that the thickness after pre-baking was 0.8 μm. As a result, a coating film was formed. Next, the glass substrate was heated (pre-baked) using a hot plate at 100° C. for 120 seconds, and then the entire surface thereof was exposed using an i-ray stepper exposure device FPA-3000 i5+ (manufactured by Canon Corporation) at an exposure dose of 1000 mJ/cm². As a result, a cured film was obtained. An average value of absorbance in a wavelength range of 400 to 450 nm measured in a direction perpendicular to the film surface of the obtained cured film was evaluated based on the following criteria.

5: the average value of the absorbance was 0.075 or lower

4: the average value of the absorbance was higher than 0.075 and 0.080 or lower

3: the average value of the absorbance was higher than 0.080 and 0.10 or lower

2: the average value of the absorbance was higher than 0.10 and 0.20 or lower

1: the average value of the absorbance was higher than 0.20

[Visible Transparency 2] (Visible Transparency After Post-Baking)

Each of the photosensitive compositions was applied to a glass substrate using a spin coater (manufactured by Mikasa Co., Ltd.) such that the thickness after post-baking was 0.8 μm. As a result, a coating film was formed. Next, the glass substrate was heated (pre-baked) using a hot plate at 100° C. for 120 seconds, and then the entire surface thereof was exposed using an i-ray stepper exposure device FPA-3000 i5+ (manufactured by Canon Corporation) at an exposure dose of 1000 mJ/cm². Next, the glass substrate was further heated (post-baked) using a hot plate at 220° C. for 300 seconds. As a result, a cured film was obtained. An average value of absorbance in a wavelength range of 400 to 450 nm measured in a direction perpendicular to the film surface of the obtained cured film was evaluated based on the same criteria as those of “Visible Transparency 1”.

[Thermal Shrinkability]

The cured film prepared in the evaluation of Visible Transparency 2 was heated using a hot plate at 260° C. for 30 minutes. The thickness of the cured film was measured before and after heating, and the thicknesses of the cured film before and after heating were evaluated based on the following criteria to evaluate the thermal shrinkability of the cured film. As the thicknesses of the cured film before and after heating, average values of five samples (cured films) measured using Dektak (Bruker) were used.

5: (Thickness of Cured Film after Heating/Thickness of Cured Film before Heating) was 0.9 or more

4: (Thickness of Cured Film after Heating/Thickness of Cured Film before Heating) was 0.88 or more and less than 0.9

3: (Thickness of Cured Film after Heating/Thickness of Cured Film before Heating) was 0.85 or more and less than 0.88

2: (Thickness of Cured Film after Heating/Thickness of Cured Film before Heating) was 0.8 or more and less than 0.85

1: (Thickness of Cured Film after Heating/Thickness of Cured Film before Heating) was less than 0.8

[Rectangularity 1] (Rectangularity Before Post-Baking and After Development)

Each of the photosensitive compositions was applied to a silicon wafer using a spin coater (manufactured by Mikasa Co., Ltd.) such that the thickness after pre-baking was 1.0 As a result, a coating film was formed. Next, the silicon wafer was heated (pre-baked) using a hot plate at 100° C. for 2 minutes. Next, using an i-ray stepper exposure device FPA-3000 i5+ (manufactured by Canon Corporation) at 1000 mJ/cm², a 1 μm×1 μm Bayer pattern was exposed through a mask at an exposure dose of 1000 mJ/cm². Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. As a result, a pattern was formed. The silicon wafer on which the pattern was formed was divided, and platinum vapor deposition was performed. Next, a cross-sectional scanning electron microscopic (SEM) image of the pattern was obtained using a scanning electron microscope (manufactured by Hitachi High-Technologies Corporation). Five patterns were extracted from the obtained cross-sectional SEM image, and an average slope of cross-sections of the five patterns was obtained and was evaluated based on the following criteria.

As the slope of the cross-section of the pattern, a slope of the cured film on a portion of the silicon wafer where the pattern is formed in a thickness direction was measured. Specifically, an angle of a portion between the silicon wafer and a side of the cured film in the thickness direction was measured. A case where the slope of the pattern is less than 90 degrees with respect to the silicon wafer represents that the cured film is tapered in a direction from the silicon wafer side to the surface side of the cured film.

5: the average slope of the five patterns was 80 degrees or more and less than 100 degrees with respect to the silicon wafer

4: the average slope of the five patterns was 70 degrees or more and less than 80 degrees with respect to the silicon wafer

3: the average slope of the five patterns was 60 degrees or more and less than 70 degrees with respect to the silicon wafer

2: the average slope of the five patterns was 50 degrees or more and less than 60 degrees with respect to the silicon wafer

1: the average slope of the five patterns was less than 50 degrees or more than 100 degrees with respect to the silicon wafer

[Rectangularity 2] (Rectangularity After Post-Baking)

Each of the photosensitive compositions was applied to a silicon wafer using a spin coater (manufactured by Mikasa Co., Ltd.) such that the thickness after post-baking was 1.0 μm. As a result, a coating film was formed. Next, the silicon wafer was heated using a hot plate at 100° C. for 2 minutes. Next, using an i-ray stepper exposure device FPA-3000 i5+ (manufactured by Canon Corporation) at 1000 mJ/cm², a 1 μm×1 μm Bayler pattern was exposed through a mask at an exposure dose of 1000 mJ/cm². Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated (post-baked) using a hot plate at 200° C. for 5 minutes. As a result, a pattern was formed. The silicon wafer on which the pattern was formed was divided, and platinum vapor deposition was performed. Next, a cross-sectional scanning electron microscopic (SEM) image of the pattern was obtained using a scanning electron microscope (manufactured by Hitachi High-Technologies Corporation). Five patterns were extracted from the obtained cross-sectional SEM image, and an average slope of cross-sections of the five patterns was obtained and was evaluated based on the same criteria as those of Rectangularity 1.

<Sensitivity of Photosensitive Coloring Composition>

Each of the photosensitive compositions was applied to a silicon wafer using a spin coater (manufactured by Mikasa Co., Ltd.) such that the thickness after post-baking was 1.0 μm. As a result, a coating film was formed. Next, the silicon wafer was heated using a hot plate at 100° C. for 2 minutes. Next, using an i-ray stepper exposure device FPA-3000 i5+ (manufactured by Canon Corporation) at 1000 mJ/cm², a 1 μm×1 μm Bayler pattern was exposed through a mask at an exposure dose of 1000 mJ/cm². Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated (post-baked) using a hot plate at 200° C. for 5 minutes. As a result, a pattern (near infrared cut filter) was formed.

Next, SR-2000S (manufactured by FFEM) was applied to the near infrared cut filter using a spin coater (manufactured by Mikasa Co., Ltd.) such that the thickness of the formed film was 1.0 μm. Next, the silicon wafer was heated using a hot plate at 100° C. for 2 minutes. Next, using an i-ray stepper exposure device FPA-3000 i5+ (manufactured by Canon Corporation) at 1000 mJ/cm², a 1 μm×1 μm Bayler pattern was exposed through a mask at an exposure dose of 1000 mJ/cm². Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated using a hot plate at 200° C. for 5 minutes. As a result, a laminate in which a pattern of a red color filter was formed on the pattern of the near infrared cut filter was manufactured.

Next, SR-2000S (manufactured by FFEM) was applied to the silicon wafer using a spin coater (manufactured by Mikasa Co., Ltd.) such that the thickness of the formed film was 1.0 μin. As a result a coating film was formed. Next, the silicon wafer was heated using a hot plate at 100° C. for 2 minutes. Next, using an i-ray stepper exposure device FPA-3000 i5+ (manufactured by Canon Corporation) at 1000 mJ/cm², a 1 μm×1 μm Bayler pattern was exposed through a mask at an exposure dose of 1000 mJ/cm². Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated using a hot plate at 200° C. for 5 minutes. As a result, a pattern of a red color filter was formed on the silicon wafer.

Each of the silicon wafer on which the laminate (laminate including the near infrared cut filter and the red color filter) was formed and the silicon wafer on which the pattern of the red color filter was formed was divided, and platinum vapor deposition was performed. Next, a cross-sectional scanning electron microscopic (SEM) image of the pattern was obtained using a scanning electron microscope (manufactured by Hitachi High-Technologies Corporation).

A pattern width L1 of the red color filter on the near infrared cut filter in the laminate and a pattern width L2 of the red color filter formed on the silicon wafer were obtained based on the respective SEM images, and the sensitivity of the photosensitive coloring composition was evaluated based on the following criteria.

5: L1/L2 was 0.9 or higher

4: L1/L2 was 0.8 or higher and lower than 0.9

3: L1/L2 was 0.7 or higher and lower than 0.8

2: L1/L2 was 0.5 or higher and lower than 0.7

1: L1/L2 was lower than 0.5

TABLE 4

| | | | | | | Sensitivity of |
|---|---|---|---|---|---|---|
| | Visible | Visible | | | | Photosensitive |
| | Transparency | Transparency | Thermal | Rectangularity | Rectangularity | Coloring |
| | 1 | 2 | Shrinkability | 1 | 2 | Composition |
| Example 1 | 3 | 3 | 4 | 5 | 3 | 4 |
| Example 2 | 5 | 4 | 4 | 5 | 3 | 4 |
| Example 3 | 5 | 4 | 4 | 5 | 3 | 4 |
| Example 4 | 5 | 5 | 4 | 5 | 3 | 4 |
| Example 5 | 5 | 4 | 4 | 5 | 3 | 4 |
| Example 6 | 5 | 4 | 4 | 4 | 3 | 4 |
| Example 7 | 5 | 5 | 4 | 4 | 4 | 4 |
| Example 8 | 4 | 4 | 4 | 4 | 4 | 4 |
| Example 9 | 5 | 4 | 4 | 4 | 3 | 4 |
| Example 10 | 5 | 5 | 4 | 4 | 4 | 4 |
| Example 11 | 3 | 3 | 4 | 4 | 3 | 4 |
| Example 12 | 4 | 5 | 4 | 4 | 3 | 4 |
| Example 13 | 5 | 5 | 4 | 4 | 3 | 4 |
| Example 14 | 5 | 5 | 4 | 4 | 4 | 4 |
| Example 15 | 3 | 3 | 4 | 4 | 3 | 4 |
| Example 16 | 5 | 5 | 4 | 4 | 4 | 4 |
| Example 17 | 5 | 4 | 4 | 5 | 5 | 4 |
| Example 18 | 3 | 3 | 4 | 5 | 4 | 4 |
| Example 19 | 4 | 4 | 4 | 5 | 4 | 4 |
| Example 20 | 5 | 4 | 4 | 5 | 4 | 4 |
| Example 21 | 5 | 4 | 4 | 5 | 5 | 4 |
| Example 22 | 4 | 4 | 3 | 3 | 3 | 4 |
| Example 23 | 3 | 3 | 4 | 5 | 4 | 4 |
| Example 24 | 4 | 4 | 4 | 5 | 5 | 4 |
| Example 25 | 3 | 3 | 4 | 5 | 5 | 4 |
| Example 26 | 3 | 3 | 4 | 5 | 5 | 4 |
| Example 27 | 4 | 4 | 4 | 5 | 5 | 4 |
| Example 28 | 5 | 5 | 4 | 5 | 5 | 4 |
| Example 29 | 4 | 5 | 4 | 5 | 5 | 4 |
| Example 30 | 4 | 5 | 4 | 5 | 5 | 4 |
| Example 31 | 4 | 4 | 4 | 5 | 5 | 4 |
| Example 32 | 4 | 4 | 4 | 5 | 5 | 4 |
| Example 33 | 4 | 5 | 4 | 5 | 5 | 4 |
| Example 34 | 4 | 5 | 4 | 5 | 5 | 4 |
| Example 35 | 4 | 4 | 4 | 5 | 5 | 4 |
| Example 36 | 4 | 4 | 4 | 5 | 5 | 4 |
| Example 37 | 4 | 4 | 4 | 5 | 5 | 4 |
| Example 38 | 3 | 4 | 4 | 5 | 5 | 4 |
| Example 39 | 5 | 5 | 4 | 5 | 5 | 4 |
| Example 40 | 5 | 5 | 4 | 5 | 5 | 4 |
| Example 41 | 5 | 5 | 4 | 4 | 5 | 4 |
| Example 42 | 4 | 4 | 4 | 5 | 5 | 4 |
| Example 43 | 5 | 5 | 4 | 5 | 5 | 4 |
| Example 44 | 5 | 5 | 4 | 5 | 5 | 4 |
| Example 45 | 4 | 3 | 4 | 5 | 5 | 4 |
| Example 46 | 5 | 5 | 4 | 5 | 5 | 4 |
| Example 47 | 4 | 4 | 3 | 5 | 5 | 4 |
| Example 48 | 4 | 4 | 3 | 5 | 5 | 4 |
| Example 49 | 5 | 5 | 4 | 5 | 5 | 4 |
| Example 50 | 5 | 4 | 4 | 5 | 5 | 4 |

TABLE 5

| | | | | | | Sensitivity of |
|---|---|---|---|---|---|---|
| | Visible | Visible | | | | Photosensitive |
| | Transparency | Transparency | Thermal | Rectangularity | Rectangularity | Coloring |
| | 1 | 2 | Shrinkability | 1 | 2 | Composition |
| Example 51 | 5 | 4 | 4 | 5 | 5 | 4 |
| Example 52 | 5 | 4 | 4 | 5 | 5 | 4 |
| Example 53 | 5 | 5 | 4 | 5 | 5 | 4 |
| Example 54 | 5 | 5 | 4 | 5 | 5 | 4 |
| Example 55 | 5 | 5 | 5 | 5 | 5 | 5 |
| Example 56 | 5 | 5 | 4 | 5 | 5 | 4 |
| Example 57 | 5 | 5 | 5 | 5 | 5 | 5 |
| Example 58 | 5 | 5 | 4 | 5 | 5 | 4 |
| Example 59 | 5 | 5 | 5 | 5 | 5 | 5 |
| Example 60 | 5 | 4 | 4 | 5 | 5 | 4 |
| Example 61 | 5 | 5 | 5 | 5 | 5 | 5 |
| Example 62 | 5 | 4 | 4 | 5 | 5 | 4 |
| Example 63 | 4 | 3 | 3 | 5 | 5 | 4 |
| Example 64 | 5 | 4 | 4 | 5 | 5 | 4 |
| Example 65 | 5 | 4 | 4 | 4 | 4 | 4 |
| Example 66 | 5 | 4 | 4 | 5 | 5 | 4 |
| Example 67 | 5 | 4 | 4 | 4 | 4 | 4 |
| Example 68 | 5 | 4 | 4 | 5 | 5 | 4 |
| Example 69 | 5 | 4 | 4 | 5 | 5 | 4 |
| Example 70 | 5 | 4 | 4 | 5 | 5 | 4 |
| Example 71 | 5 | 4 | 4 | 5 | 5 | 4 |
| Example 72 | 5 | 4 | 4 | 5 | 5 | 4 |
| Example 73 | 5 | 4 | 5 | 5 | 5 | 5 |
| Example 74 | 5 | 4 | 4 | 5 | 5 | 4 |
| Example 75 | 5 | 4 | 5 | 5 | 5 | 5 |
| Example 76 | 5 | 4 | 4 | 5 | 5 | 4 |
| Example 77 | 5 | 4 | 5 | 5 | 5 | 5 |
| Example 78 | 5 | 4 | 4 | 5 | 5 | 4 |
| Example 79 | 5 | 5 | 5 | 5 | 5 | 5 |
| Example 80 | 5 | 4 | 4 | 5 | 5 | 4 |
| Example 81 | 4 | 3 | 3 | 5 | 5 | 4 |
| Example 82 | 5 | 4 | 4 | 5 | 5 | 4 |
| Example 83 | 5 | 4 | 4 | 4 | 4 | 4 |
| Example 84 | 5 | 4 | 4 | 5 | 5 | 4 |
| Example 85 | 5 | 4 | 4 | 4 | 4 | 4 |
| Example 86 | 5 | 4 | 4 | 4 | 3 | 4 |
| Example 87 | 4 | 3 | 4 | 4 | 3 | 4 |
| Example 88 | 4 | 3 | 4 | 3 | 3 | 4 |
| Example 89 | 4 | 3 | 4 | 3 | 3 | 4 |
| Example 90 | 1 | 3 | 4 | 4 | 3 | 4 |
| Comparative | 3 | 3 | 2 | 4 | 3 | 2 |
| Example 1 | | | | | | |
| Comparative | 3 | 2 | 1 | 3 | 2 | 1 |
| Example 2 | | | | | | |
| Comparative | 3 | 2 | 4 | 2 | 1 | 4 |
| Example 3 | | | | | | |

As shown in the tables, in Examples, a cured film that includes a pattern having excellent rectangularity and having suppressed thermal shrinkage was able to be formed. On the other hand, in Comparative Examples, at least one of Rectangularity 1, Rectangularity 2, or Thermal Shrinkability was poor.

In the evaluations of Rectangularity 1 and Rectangularity 2, even in a case where the organic solvent described above regarding the photosensitive composition in this specification was used as a developer for development instead of tetramethylammonium hydroxide (TMAH) 0.3 mass % aqueous solution, the same effects as those of Examples were obtained.

[Test Example 1]

The photosensitive composition according to Example 1, 14, or 21 was applied to a silicon wafer using a spin coating method such that the thickness of the formed film was 1.0 μm. Next, the silicon wafer was heated using a hot plate at 100° C. for 2 minutes. Next, using an i-ray stepper exposure device FPA-3000 i5+ (manufactured by Canon Corporation) at 1000 mJ/cm², a 2 μm×2 μm Bayer pattern was exposed through a mask at an exposure dose of 1000 mJ/cm².

Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated using a hot plate at 200° C. for 5 minutes. As a result, a 2 μm×2 μm Bayer pattern (near infrared cut filter) was formed.

Next, a Red composition was applied to the Bayer pattern of the near infrared cut filter using a spin coating method such that the thickness of the formed film was 1.0 μm Next, the silicon wafer was heated using a hot plate at 100° C. for 2 minutes. Next, using an i-ray stepper exposure device FPA-3000 i5+ (manufactured by Canon Corporation) at 1000 mJ/cm², a 2 μm×2 μm Bayer pattern was exposed through a mask at an exposure dose of 1000 mJ/cm². Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated using a hot plate at 200° C. for 5 minutes. As a result, the Red composition was patterned on the Bayer pattern of the near infrared cut filter. Likewise, a Green composition and a Blue composition were sequentially patterned to form red, blue, and green color patterns.

Next, a composition for forming an infrared transmitting filter was applied to the pattern-formed film using a spin coating method such that the thickness of the formed film was 2.0 μm. Next, the silicon wafer was heated using a hot plate at 100° C. for 2 minutes. Next, using an i-ray stepper exposure device FPA-3000 i5+ (manufactured by Canon Corporation) at 1000 mJ/cm², a 2 μm×2 μm Bayer pattern was exposed through a mask at an exposure dose of 1000 mJ/cm². Next, puddle development was performed at 23° C. for 60 seconds using a tetramethylammonium hydroxide (TMAH) 0.3 mass % aqueous solution. Next, the glass substrate was rinsed by spin showering and was cleaned with pure water. Next, the silicon wafer was heated using a hot plate at 200° C. for 5 minutes. As a result, the infrared transmitting filter was patterned on a portion where the Bayer pattern of the near infrared cut filter was not formed. This filter was incorporated into a solid image pickup element using a well-known method.

Using the obtained solid image pickup element, a subject was irradiated with an infrared light emitting diode (infrared LED) as a light source in a low-illuminance environment (0.001 Lux) to acquire images. Next, the imaging performance of the solid image pickup element was evaluated. The subject was able to be clearly recognized on the image. In addition, incidence angle dependency was good.

[Test Example 2]

The Red composition was applied to a silicon wafer using a spin coating method such that the thickness of the formed film was 1.0 μm. Next, the silicon wafer was heated using a hot plate at 100° C. for 2 minutes. Next, using an i-ray stepper exposure device FPA-3000 i5+ (manufactured by Canon Corporation) at 1000 mJ/cm², a 2 μm×2 μm Bayer pattern was exposed through a mask at an exposure dose of 1000 mJ/cm². Next, puddle development was performed at 23° C. for 60 seconds using a tetramethylammonium hydroxide (TMAH) 0.3 mass % aqueous solution. Next, the glass substrate was rinsed by spin showering and was cleaned with pure water. Next, the silicon wafer was heated using a hot plate at 200° C. for 5 minutes to obtain a 2 μm×2 μm Bayer pattern. Likewise, a Green composition and a Blue composition were sequentially patterned to form red, blue, and green color patterns.

The photosensitive composition according to Example 1, 14, or 21 was applied to the red, blue, and green color patterns using a spin coating method such that the thickness of the formed film was 1.0 μm. Next, the silicon wafer was heated using a hot plate at 100° C. for 2 minutes. Next, using an i-ray stepper exposure device FPA-3000 i5+ (manufactured by Canon Corporation) at 1000 mJ/cm², a 2 μm×2 μm Bayer pattern was exposed through a mask at an exposure dose of 1000 mJ/cm². Next, puddle development was performed at 23° C. for 60 seconds using a tetramethylammonium hydroxide (TMAH) 0.3 mass % aqueous solution. Next, the glass substrate was rinsed by spin showering and was cleaned with pure water. Next, the silicon wafer was heated using a hot plate at 200° C. for 5 minutes. As a result, a 2 μm×2 μmBayer pattern (near infrared cut filter) was formed.

Next, by performing the same method of Test Example 1 on the film on which the pattern was formed using the composition for forming an infrared transmitting filter, an infrared transmitting filter was patterned on a portion of the near infrared cut filter where the Bayer pattern was not formed. This filter was incorporated into a solid image pickup element using a well-known method.

Using the obtained solid image pickup element, a subject was irradiated with an infrared light emitting diode (infrared LED) as a light source in a low-illuminance environment (0.001 Lux) to acquire images. Next, the imaging performance of the solid image pickup element was evaluated. The subject was able to be clearly recognized on the image. In addition, incidence angle dependency was good.

[Test Example 3]

A composition for forming an infrared transmitting filter was applied to a silicon wafer using a spin coating method such that the thickness of the formed film was 1.0 μm. Next, the silicon wafer was heated using a hot plate at 100° C. for 2 minutes. Next, the silicon wafer was heated using a hot plate at 200° C. for 5 minutes. Next, a 2 μm×2 μm Bayer pattern (infrared transmitting filter) was formed using a dry etching method.

Next, the photosensitive composition according to Example 1, 14, or 21 was applied to the Bayler pattern of the infrared transmitting filter using a spin coating method such that the thickness of the formed film was 1.0 μm. Next, the silicon wafer was heated using a hot plate at 100° C. for 2 minutes. Next, using an i-ray stepper exposure device FPA-3000 i5+ (manufactured by Canon Corporation) at 1000 mJ/cm², a 2 μm×2 μm Bayler pattern was exposed through a mask at an exposure dose of 1000 mJ/cm². Next, puddle development was performed at 23° C. for 60 seconds using a tetramethylammonium hydroxide (TMAH) 0.3 mass % aqueous solution. Next, the glass substrate was rinsed by spin showering and was cleaned with pure water. Next, by heating the silicon wafer using a hot plate at 200° C. for 5 minutes, a near infrared cut filter was patterned. This filter was incorporated into a solid image pickup element using a well-known method.

Using the obtained solid image pickup element, a subject was irradiated with an infrared light emitting diode (infrared LED) as a light source in a low-illuminance environment (0.001 Lux) to acquire images. Next, the imaging performance of the solid image pickup element was evaluated. The subject was able to be clearly recognized on the image. In addition, incidence angle dependency was good.

The Red composition, the Green composition, the Blue composition, and the composition for forming an infrared transmitting filter used in Test Examples 1 to 3 are as follows.

(Red Composition)

The following components were mixed and stirred, and the obtained mixture was filtered through a nylon filter (manufactured by Pall Corporation) having a pore size of 0.45 μm to prepare a Red composition.

| | | |
|---|---|---|
| Red Pigment Dispersion | 51.7 | parts by mass |
| Resin 4 (40 mass % PGMEA solution) | 0.6 | parts by mass |
| Curable Compound 4 | 0.6 | parts by mass |
| Photopolymerization Initiator 1 | 0.4 | parts by mass |
| Surfactant 1 | 4.2 | parts by mass |
| Ultraviolet absorber (the ultraviolet | 0.3 | parts by mass |
| absorber UV4) | | |
| PGMEA | 42.6 | parts by mass |

(Green Composition)

The following components were mixed and stirred, and the obtained mixture was filtered through a nylon filter (manufactured by Pall Corporation) having a pore size of 0.45 μm to prepare a Green composition.

| | | |
|---|---|---|
| Green Pigment Dispersion | 73.7 | parts by mass |
| Resin 4 (40 mass % PGMEA solution) | 0.3 | parts by mass |
| Curable Compound 1 | 1.2 | parts by mass |
| Photopolymerization Initiator 1 | 0.6 | parts by mass |
| Surfactant 1 | 4.2 | parts by mass |
| Ultraviolet absorber (the ultraviolet | 0.5 | parts by mass |
| absorber UV4) | | |
| PGMEA | 19.5 | parts by mass |

(Blue Composition)

The following components were mixed and stirred, and the obtained mixture was filtered through a nylon filter (manufactured by Pall Corporation) having a pore size of 0.45 μm to prepare a Blue composition.

| | | |
|---|---|---|
| Blue Pigment Dispersion | 44.9 | parts by mass |
| Resin 4 (40 mass % PGMEA solution) | 2.1 | parts by mass |
| Curable Compound 1 | 1.5 | parts by mass |
| Curable Compound 4 | 0.7 | parts by mass |
| Photopolymerization Initiator 1 | 0.8 | parts by mass |
| Surfactant 1 | 4.2 | parts by mass |
| Ultraviolet absorber (the ultraviolet | 0.3 | parts by mass |
| absorber UV4) | | |
| PGMEA | 45.8 | parts by mass |

(Preparation of Composition for Forming Infrared Transmitting Filter)

The components having the following compositions were mixed and stirred, and the obtained mixture was filtered through a nylon filter (manufactured by Pall Corporation) having a pore size of 0.45 μm to prepare a composition for forming an infrared transmitting filter.

### (Composition 100)

| | | |
|---|---|---|
| Pigment Dispersion 1-1 | 46.5 | parts by mass |
| Pigment Dispersion 1-2 | 37.1 | parts by mass |
| Curable Compound 5 | 1.8 | parts by mass |
| Resin 4 | 1.1 | parts by mass |
| Photopolymerization Initiator 2 | 0.9 | parts by mass |
| Surfactant 1 | 4.2 | parts by mass |
| Polymerization inhibitor (p-methoxyphenol) | 0.001 | parts by mass |
| Silane coupling agent | 0.6 | parts by mass |
| PGMEA | 7.8 | parts by mass |

Raw materials used in the Red composition, the Green composition, the Blue composition, and the composition for forming an infrared transmitting filter are as follows.

Red Pigment Dispersion

9.6 parts by mass of C.I. Pigment Red 254, 4.3 parts by mass of C.I. Pigment Yellow 139, 6.8 parts by mass of a dispersant (Disperbyk-161, manufactured by BYK Chemie), and 79.3 parts by mass of PGMEA were mixed with each other to obtain a mixed solution, and the mixed solution was mixed and dispersed using a beads mill (zirconia beads; diameter: 0.3 mm) for 3 hours. As a result, a pigment dispersion was prepared. Next, using a high-pressure disperser NANO-3000-10 (manufactured by Nippon BEE Chemical Co., Ltd.) equipped with a pressure reducing mechanism, the pigment dispersion was further dispersed under a pressure of 2000 kg/cm³ at a flow rate of 500 g/min. This dispersing treatment was repeated 10 times. As a result, a Red pigment dispersion was obtained.

Green Pigment Dispersion

6.4 parts by mass of C.I. Pigment Green 36, 5.3 parts by mass of C.I. Pigment Yellow 150, 5.2 parts by mass of a dispersant (Disperbyk-161, manufactured by BYK Chemie), and 83.1 parts by mass of PGMEA were mixed with each other to obtain a mixed solution, and the mixed solution was mixed and dispersed using a beads mill (zirconia beads; diameter: 0.3 mm) for 3 hours. As a result, a pigment dispersion was prepared. Next, using a high-pressure disperser NANO-3000-10 (manufactured by Nippon BEE Chemical Co., Ltd.) equipped with a pressure reducing mechanism, the pigment dispersion was further dispersed under a pressure of 2000 kg/cm³ at a flow rate of 500 g/min. This dispersing treatment was repeated 10 times. As a result, a Green pigment dispersion was obtained.

Blue Pigment Dispersion

9.7 parts by mass of C.I. Pigment Blue 15:6, 2.4 parts by mass of C.I. Pigment Violet 23, 5.5 parts by mass of a dispersant (Disperbyk-161, manufactured by BYK Chemie), 82.4 parts by mass of PGMEA were mixed with each other to obtain a mixed solution, and the mixed solution was mixed and dispersed using a beads mill (zirconia beads; diameter: 0.3 mm) for 3 hours. As a result, a pigment dispersion was prepared. Next, using a high-pressure disperser NANO-3000-10 (manufactured by Nippon BEE Chemical Co., Ltd.) equipped with a pressure reducing mechanism, the pigment dispersion was further dispersed under a pressure of 2000 kg/cm³ at a flow rate of 500 g/min. This dispersing treatment was repeated 10 times. As a result, a Blue pigment dispersion was obtained.

Pigment Dispersion 1-1

A mixed solution having a composition shown below was mixed and dispersed for 3 hours using a beads mill (a high-pressure disperser with a pressure reducing mechanism, NANO-3000-10 (manufactured by Nippon BEE Chemical Co., Ltd.)) in which zirconia beads having a diameter of 0.3 mm were used. As a result, Pigment Dispersion 1-1 was prepared.

| | | |
|---|---|---|
| Mixed pigment including a red pigment | 11.8 | parts by mass |
| (C.I. Pigment Red 254) and a yellow | | |
| pigment (C.I. Pigment Yellow 139) | | |
| Resin (Disperbyk-111, manufactured by | 9.1 | parts by mass |
| BYK Chemie) | | |
| PGMEA | 79.1 | parts by mass |

Pigment Dispersion 1-2

A mixed solution having a composition shown below was mixed and dispersed for 3 hours using a beads mill (a high-pressure disperser with a pressure reducing mechanism, NANO-3000-10 (manufactured by Nippon BEE Chemical Co., Ltd.)) in which zirconia beads having a diameter of 0.3 mm were used. As a result, Pigment Dispersion 1-2 was prepared.

| | |
|---|---|
| •Mixed pigment including a blue pigment (C.I. Pigment Blue 15:6) and a violet pigment | 12.6 parts by mass |
| (C.I. Pigment Violet 23) | |
| •Resin (Disperbyk-111, manufactured by BYK Chemie) | 2.0 parts by mass |
| •Resin A | 3.3 parts by mass |
| •Cyclohexanone | 31.2 parts by mass |
| •PGMEA | 50.9 parts by mass |
| •Resin A: the following structure (Mw = 14,000, a ratio in a structural unit is a molar ratio) | |
| 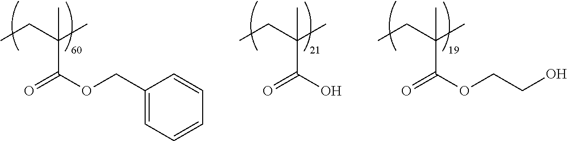 | |

Curable Compound 1: KAYARAD DPHA (manufactured by Nippon Kayaku Co., Ltd.)

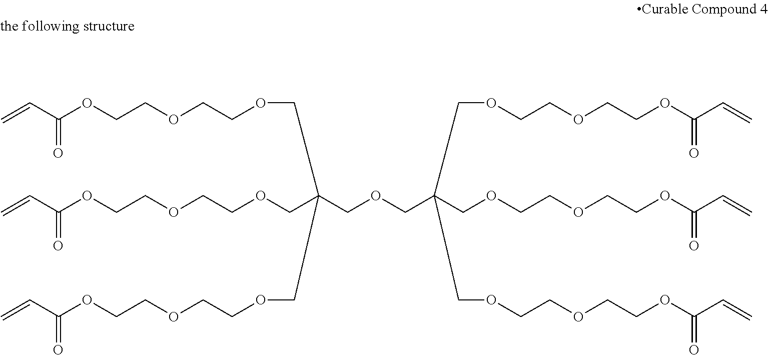 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Curable Compound 5: the following structures (a mixture in which a molar ratio between a left compound and a right compound is 7:3)

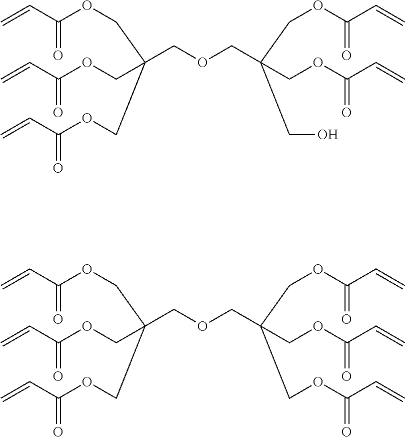

Resin 4: the following structure (acid value: 70 mgKOH/g, Mw=11000; a ratio in a structural unit is a molar ratio)

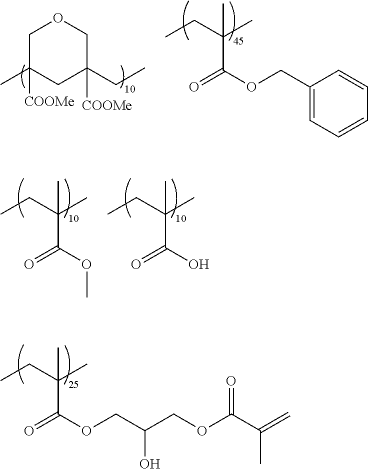

Photopolymerization Initiator 1: IRGACURE-OXE 01 (manufactured by BASF SE)

Photopolymerization initiator 2: the following structure

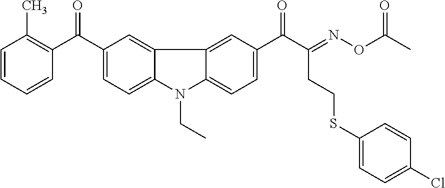 [SMILES: CCn1c2ccc(C(=O)/C(CCSc3ccc(Cl)cc3)=N/OC(C)=O)cc2c2cc(C(=O)c3ccccc3C)ccc21]

Surfactant 1: 1 mass % PGMEA solution of the following mixture (Mw: 14000). In the following expression, “%” representing the proportion of a repeating unit is mass %.

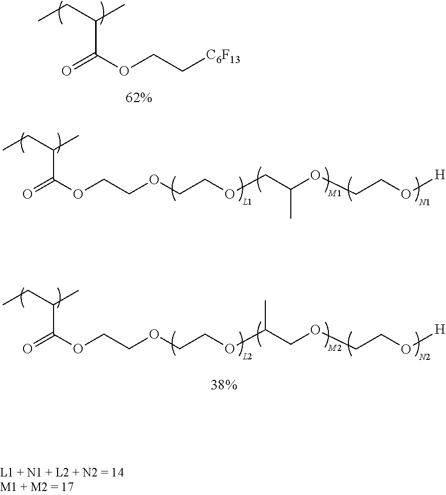

Silane coupling agent: a compound having the following structure. In the following structural formulae, Et represents an ethyl group.

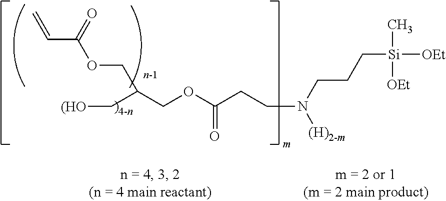

### EXPLANATION OF REFERENCES

110: solid image pickup element

111: near infrared cut filter

112: color filter

114: infrared transmitting filter

115: microlens

116: planarizing layer

What is claimed is:

1. A photosensitive composition comprising:
a near infrared absorber;
a curable compound;
a photoinitiator; and
an ultraviolet absorber,
wherein in thermogravimetry, the ultraviolet absorber has a mass loss percentage of 5% or lower at 150° C. and has a mass loss percentage of 40% or higher at 220° C.

2. The photosensitive composition according to claim 1,
wherein a ratio A365/A400 of an absorbance A365 of the ultraviolet absorber at a wavelength of 365 nm to an absorbance A400 of the ultraviolet absorber at a wavelength of 400 nm is 0.5 or lower.

3. The photosensitive composition according to claim 1,
wherein a ratio A365/A400 of an absorbance A365 of the ultraviolet absorber at a wavelength of 365 nm to an absorbance A400 of the ultraviolet absorber at a wavelength of 400 nm is 0.1 or lower.

4. The photosensitive composition according to claim 1, wherein the ultraviolet absorber is a compound having an absorption maximum in a wavelength range of 300 to 400 nm.

5. The photosensitive composition according to claim 1,
wherein a molar absorption coefficient of the ultraviolet absorber at a wavelength of 365 nm is 4.0×10⁴ to 1.0×10⁵ L·mol⁻¹·cm⁻¹.

6. The photosensitive composition according to claim 1,
wherein the ultraviolet absorber is at least one selected from the group consisting of an aminobutadiene compound and a methyldibenzoyl compound.

7. The photosensitive composition according to claim 1,
wherein the ultraviolet absorber is a compound represented by the following Formula (UV-1); 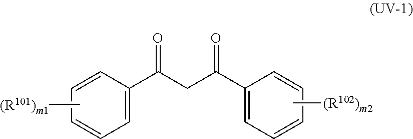
in Formula (UV-1), R¹⁰¹ and R¹⁰² each independently represent a substituent, and m1 and m2 each independently represent 0 to 4.

8. The photosensitive composition according to claim 1,
wherein the curable compound is a radically polymerizable compound, and
the photoinitiator is a photoradical polymerization initiator.

9. The photosensitive composition according to claim 1, further comprising:
an alkali-soluble resin.

10. A cured film which is formed using the photosensitive composition according to claim 1.

11. An optical filter which is obtained using the photosensitive composition according to claim 1.

12. The optical filter according to claim 11,
wherein the optical filter is a near infrared cut filter or an infrared transmitting filter.

13. A laminate comprising:
the cured film according to claim 10; and
a color filter that includes a chromatic colorant.

14. A pattern forming method comprising:
forming a composition layer on a support using the photosensitive composition according to claim 1; and
forming a pattern on the composition layer using a photolithography method.

15. The pattern forming method according to claim 14 further comprising:
forming a photosensitive coloring composition layer on the pattern using a photosensitive coloring composition including a chromatic colorant; and
forming a pattern by exposing the photosensitive coloring composition layer from the photosensitive coloring composition layer side and subsequently developing the exposed photosensitive coloring composition layer.

16. A solid image pickup element comprising:
the cured film according to claim 10.

17. An image display device comprising:
the cured film according to claim 10.

18. An infrared sensor comprising:
the cured film according to claim 10.
